(19) United States
(12) Patent Application Publication
(10) Pub. No.: US 2016/0056054 A1
(43) Pub. Date: Feb. 25, 2016

(54) ETCHING METHOD, ETCHING LIQUID AND ETCHING LIQUID KIT TO BE USED IN SAID METHOD, AND SEMICONDUCTOR SUBSTRATE PRODUCT MANUFACTURING METHOD

(71) Applicant: FUJIFILM Corporation, Tokyo (JP)

(72) Inventors: Satomi TAKAHASHI, Haibara-gun (JP); Tetsuya KAMIMURA, Haibara-gun (JP); Akiko KOYAMA, Haibara-gun (JP); Atsushi MIZUTANI, Haibara-gun (JP); Yasuo SUGISHIMA, Haibara-gun (JP); Satoru MURAYAMA, Haibara-gun (JP)

(73) Assignee: FUJIFILM Corporation, Tokyo (JP)

(21) Appl. No.: 14/927,798

(22) Filed: Oct. 30, 2015

Related U.S. Application Data
(63) Continuation of application No. PCT/JP2014/062071, filed on May 1, 2014.

(30) Foreign Application Priority Data
May 2, 2013 (JP) 2013-097155
Aug. 5, 2013 (JP) 2013-162735
Jan. 27, 2014 (JP) 2014-012587
Feb. 28, 2014 (JP) 2014-038711

(51) Int. Cl. H01L 21/3213; H01L 21/285; C23F 1/44; C23F 1/30; C23F 1/26; H01L 21/324; H01L 21/02

(52) U.S. Cl. CPC H01L 21/32134; H01L 21/324; H01L 21/28518; H01L 21/02068; C23F 1/30; C23F 1/26; C23F 1/44

(57) ABSTRACT

There is provided an etching method of a semiconductor substrate that includes a first layer containing germanium (Ge) and a second layer containing at least one metal element selected from nickel platinum (NiPt), titanium (Ti), nickel (Ni), and cobalt (Co), the method including: bringing an etching liquid which contains a specific acid compound into contact with the second layer and selectively removing the second layer.

### CROSS-REFERENCE TO RELATED APPLICATIONS

This application is a Continuation of PCT International Application No. PCT/JP2014/062071 filed on May 1, 2014, which claims priority under 35 U.S.C. §119 (a) to Japanese Patent Application No. 2013-097155 filed in Japan on May 2, 2013, Japanese Patent Application No. 2013-162735 filed in Japan on Aug. 5, 2013, Japanese Patent Application No. 2014-012587 filed in Japan on Jan. 27, 2014, and Japanese Patent Application No. 2014-038711 filed in Japan on Feb. 28, 2014. Each of the above applications is hereby expressly incorporated by reference, in its entirety, into the present application.

### BACKGROUND OF THE INVENTION

1. Field of the Invention

The present invention relates to an etching method, an etching liquid and an etching liquid kit used in the method, and a semiconductor substrate product manufacturing method.

2. Description of the Related Art

An integrated circuit is manufactured in multi-stages of various processing processes. Specifically, in the manufacturing process, deposition of various materials, lithography of a layer whose necessary portion or entire portion is exposed, or etching of the layer is repeated several times. Among these, the etching of a layer of a metal or a metal compound becomes to be an important process. A metal or the like is selectively etched and other layers are required to remain without corroding. In some cases, it is necessary that only a predetermined layer be removed in the form in which layers formed of similar metals and a layer with high corrosivity remain. A wiring in a semiconductor substrate or the size of an integrated circuit becomes smaller and thus the importance of performing etching on a member to accurately remain without corroding has been increasing.

When an example of a field effect transistor is considered, thinning of a silicide layer to be formed on the upper surface of a source and drain region and development of a new material have been strongly demanded along with rapid miniaturization of the field effect transistor. In a salicide process (salicide: self-aligned silicide) of forming the silicide layer, a part of a source region and a drain region formed of silicon and the like formed on a semiconductor substrate and a metal layer attached to the upper surface thereof are annealed. As a metal layer, tungsten (W), titanium (Ti), or cobalt (Co) is used, and more recently nickel (Ni) is being used. In this manner, a silicide layer with low resistance can be formed on the upper side of a source and drain electrode or the like. Currently, in response to further miniaturization, formation of a NiPt silicide layer to which platinum (Pt) which is a noble metal is added has been suggested.

After the salicide process is performed, the metal layer remaining in the region is removed by etching. The etching is normally performed through wet etching and a mixed solution (aqua regia) of hydrochloric acid and nitric acid is used as a liquid chemical. WO2012/125401A discloses an example of using a liquid chemical to which toluenesulfonic acid is added in addition to nitric acid and hydrochloric acid.

### SUMMARY OF THE INVENTION

An object of the present invention is to provide an etching method which is capable of selectively removing a layer containing a specific metal with respect to a layer containing germanium and exhibits excellent etching characteristics, an etching liquid and an etching liquid kit used in the method, and a semiconductor substrate product manufacturing method.

The above-described problems are solved by the following means.

[1] An etching method of a semiconductor substrate that includes a first layer containing germanium and a second layer containing at least one metal selected from nickel platinum, titanium, nickel, and cobalt, the method including: bringing an etching liquid which contains the following acid compounds into contact with the second layer and selectively removing the second layer.

Acid compounds: at least one compound selected from halogen acid and a salt thereof; hexafluorosilicic acid and a salt thereof; tetrafluoroboric acid and a salt thereof, and hexafluorophosphoric acid and a salt thereof

[2] The etching method according to [1], in which the concentration of germanium of the first layer is 40% by mass or greater.

[3] The etching method according to [1] or [2], further including: applying a heat treatment to at least one of the first layer and the second layer before or after etching with the etching liquid.

[4] The etching method according to any one of [1] to [3], in which the second layer is selectively removed with respect to the first layer and the following third layer.

Third layer: layer containing germanium interposed between the first layer and the second layer and component metals of the second layer

[5] The etching method according to any one of [1] to [4], in which the semiconductor substrate further includes a fourth layer containing at least one of TiN, Al, AlO, W, WOx, HfOx, HfSiOx, SiN, and SiOCN and the second layer is selectively removed also with respect to the fourth layer.

[6] The etching method according to any one of [1] to [5], in which, with respect to removal components of the second layer, a removal aspect I which singly uses the acid compounds and a removal aspect II which combines the acid compounds and an oxidant and uses the combination are selectively used.

[7] The etching method according to any one of [1] to [6], in which the temperature of the etching liquid at the time of being brought into contact with the second layer is in the range of 10° C. to 80° C.

[8] The etching method according to any one of [1] to [7], in which the time required for etching one substrate is in the range of 10 seconds to 300 seconds.

[9] The etching method according to any one of [1] to [8], further including: a step of washing the semiconductor substrate with water at least before or after the etching.

[10] The etching method according to any one of [1] to [9], in which the etching liquid further contains an oxidant, and a first liquid which does not contain the oxidant and a second liquid which contains the oxidant are separated from each other and then stored.

[11] The etching method according to [10], in which the first liquid and the second liquid are mixed with each other at a suitable time when the semiconductor substrate is etched.

[12] The etching method according to any one of [1] to [11], in which the etching liquid further contains the following organic additive.

Organic additive: an additive formed of an organic compound which contains a nitrogen atom, a sulfur atom, a phosphorous atom, or an oxygen atom

[13] The etching method according to [12], in which the organic additive is formed of a compound represented by any of the following Formulae (I) to (XIII), a phosphoric acid compound, a boron-containing acid compound, or a phosphonic acid compound.

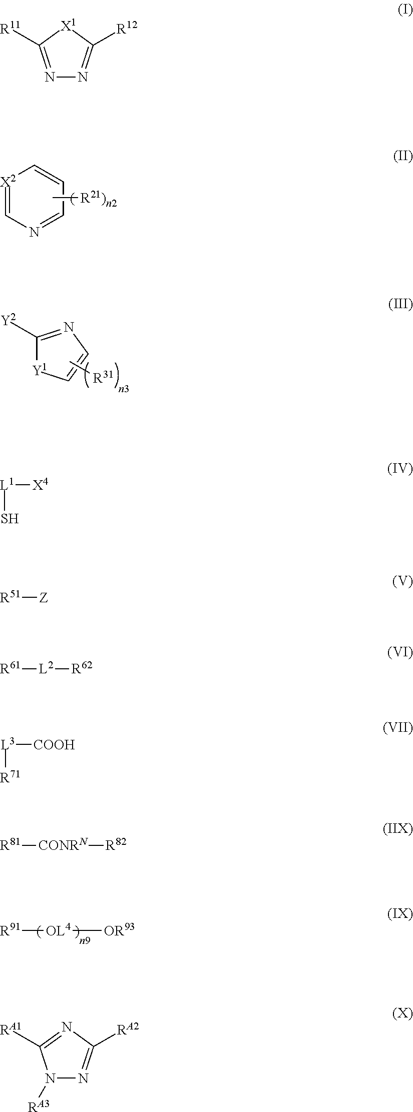

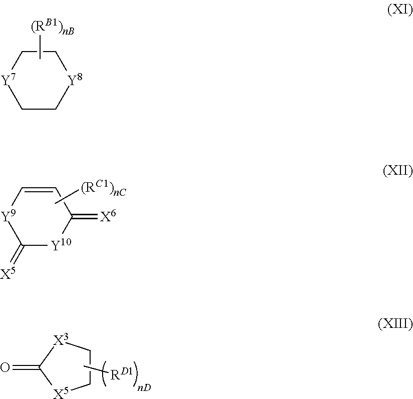

Formula (I): R¹¹ and R¹² each independently represent a hydrogen atom, an alkyl group, an alkenyl group, an alkynyl group, an aryl group, an aralkyl group, a sulfanyl group, a hydroxy group, or an amino group. X¹ represents a methylene group, a sulfur atom, or an oxygen atom.

Formula (II): X² represents a methine group or a nitrogen atom. R²¹ represents a substituent. n2 represents an integer of 0 to 4. When a plurality of R²¹'s are present, R²¹'s may be the same as or different from each other and may be bonded or condensed to each other to form a ring.

Formula (III): Y¹ represents a methylene group, an imino group, or a sulfur atom. Y² represents a hydrogen atom, an alkyl group, an alkenyl group, an alkynyl group, an aryl group, an aralkyl group, an amino group, a hydroxy group, or a sulfanyl group. R³¹ represents a substituent. n3 represents an integer of 0 to 2. When a plurality of R³¹'s are present, R³¹'s may be the same as or different from each other and may be bonded or condensed to each other form a ring.

Formula (IV): L¹ represents an alkylene group, an alkynylene group, an alkenylene group, an arylene group, or an aralkylene group. X⁴ represents a carboxyl group or a hydroxy group.

Formula (V): R⁵¹ represents an alkyl group, an alkenyl group, an alkynyl group, an aryl group, or an aralkyl group. Z represents an amino group, a sulfonic acid group, a sulfuric acid group, a phosphoric acid group, a carboxyl group, a hydroxy group, a sulfanyl group, an onium group, an acyloxy group, or an amine oxide group.

Formula (VI): R⁶¹ and R⁶² each independently represent an alkyl group, an aryl group, an alkoxy group, or an alkylamino group. R⁶¹ and R⁶² may be bonded or condensed to each other to form a ring. L² represents a carbonyl group, a sulfinyl group, or a sulfonyl group.

Formula (VII): R⁷¹ represents an amino group, an ammonium group, or a carboxyl group. L³ represents a hydrogen atom or the same group as that for L¹.

Formula (IIX): R⁸¹ and R⁸² each independently represent an alkyl group, an alkenyl group, an alkynyl group, an aryl group, or an aralkyl group. R^{N} represents a hydrogen atom or a substituent.

Formula (IX): L⁴ represents the same group as that for L¹. R⁹¹ and R⁹³ each independently represent a hydrogen atom, an alkyl group, an alkenyl group, an alkynyl group, an aryl group, an acyl group, or an aralkyl group. n9 represents an integer of 0 to 15. In this case, when n9 represents 0, both of R⁹¹ and R⁹³ do not represent a hydrogen atom.

Formula (X): R^{A3} has the same definition as that for R^{N}. R^{A1} and R^{A2} each independently represent a hydrogen atom, an alkyl group, an alkenyl group, an alkynyl group, an aryl group, an aralkyl group, a sulfanyl group, a hydroxy group, or an amino group.

Formula (XI): Y⁷ and Y⁸ each independently represent an oxygen atom, a sulfur atom, a methylene group, an imino group, or a carbonyl group. R^{B1} represents a substituent. nB represents an integer of 0 to 8.

Formula (XII): Y⁹ and Y¹⁰ each independently represent an oxygen atom, a sulfur atom, a methylene group, an imino group, or a carbonyl group. X⁵ and X⁶ each independently represent a sulfur atom or an oxygen atom. The broken line means that the bond may be a single bond or a double bond. R^{C1} represents a substituent. nC represents an integer of 0 to 2.

Formula (XIII): X³ represents an oxygen atom, a sulfur atom, or an imino group. X⁵ represents an oxygen atom, a sulfur atom, an imino group, or a methylene group. R^{D1} represents a substituent. nD represents an integer of 0 to 4.

[14] The etching method according to any one of [6] to [13], in which an organic additive selected from Formulae (V) to (IX), (XI), and (XIII), a phosphoric acid compound, a boron-containing acid compound, or a phosphonic acid compound is used in the case of the removal aspect I and an organic additive selected from Formulae (I) to (VII), (X), and (XIII) is used in the case of the removal aspect II.

[15] An etching liquid of a semiconductor substrate includes a first layer containing germanium and a second layer containing metals other than germanium, in which the etching liquid is for selectively removing the second layer, and the second layer is removed by bringing the etching liquid containing the following acid compounds and the following organic additive into contact with the second layer.

Acid compounds: at least one compound selected from halogen acid and a salt thereof; hexafluorosilicic acid and a salt thereof; tetrafluoroboric acid and a salt thereof, and hexafluorophosphoric acid and a salt thereof

Organic additive: an additive formed of an organic compound which contains a nitrogen atom, a sulfur atom, a phosphorous atom, or an oxygen atom

[16] The etching liquid according to [15], in which the second layer contains at least one metal selected from nickel platinum, titanium, nickel, and cobalt.

[17] The etching liquid according to [15] or [16], in which the concentration of the acid compound is in the range of 0.01% by mass to 10% by mass.

[18] The etching liquid according to any one of [15] to [17], in which the organic additive is formed of a compound represented by any of the following Formulae (I) to (XIII), a phosphoric acid compound, a boron-containing acid compound, or a phosphonic acid compound.

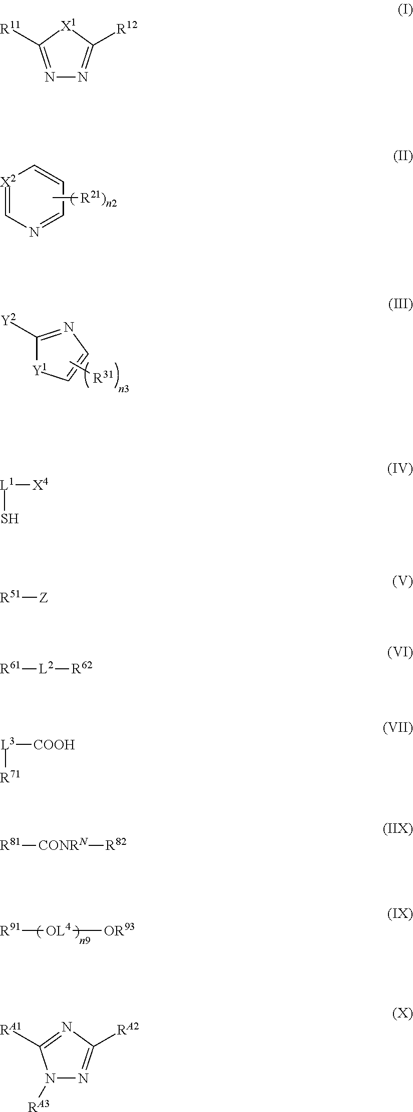

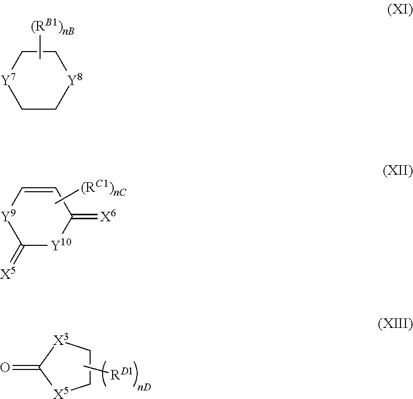

Formula (I): R¹¹ and R¹² each independently represent a hydrogen atom, an alkyl group, an alkenyl group, an alkynyl group, an aryl group, an aralkyl group, a sulfanyl group, a hydroxy group, or an amino group. X¹ represents a methylene group, a sulfur atom, or an oxygen atom.

Formula (II): X² represents a methine group or a nitrogen atom. R²¹ represents a substituent. n2 represents an integer of 0 to 4. When a plurality of R²¹'s are present, R²¹'s may be the same as or different from each other and may be bonded or condensed to each other to form a ring.

Formula (III): Y¹ represents a methylene group, an imino group, or a sulfur atom. Y² represents a hydrogen atom, an alkyl group, an alkenyl group, an alkynyl group, an aryl group, an aralkyl group, an amino group, a hydroxy group, or a sulfanyl group. R³¹ represents a substituent. n3 represents an integer of 0 to 2. When a plurality of R³¹'s are present, R³¹'s may be the same as or different from each other and may be bonded or condensed to each other to form a ring.

Formula (IV): L¹ represents an alkylene group, an alkynylene group, an alkenylene group, an arylene group, or an aralkylene group. X⁴ represents a carboxyl group or a hydroxy group.

Formula (V): R⁵¹ represents an alkyl group, an alkenyl group, an alkynyl group, an aryl group, or an aralkyl group. Z represents an amino group, a sulfonic acid group, a sulfuric acid group, a phosphoric acid group, a carboxyl group, a hydroxy group, a sulfanyl group, an onium group, an acyloxy group, or an amine oxide group.

Formula (VI): R⁶¹ and R⁶² each independently represent an alkyl group, an aryl group, an alkoxy group, or an alkylamino group. R⁶¹ and R⁶² may be bonded or condensed to each other to form a ring. L² represents a carbonyl group, a sulfinyl group, or a sulfonyl group.

Formula (VII): R⁷¹ represents an amino group, an ammonium group, or a carboxyl group. L³ represents a hydrogen atom or the same group as that for L¹.

Formula (IIX): R⁸¹ and R⁸² each independently represent an alkyl group, an alkenyl group, an alkynyl group, an aryl group, or an aralkyl group. R^{N} represents a hydrogen atom or a substituent.

Formula (IX): L⁴ represents the same group as that for L¹. R⁹¹ and R⁹³ each independently represent a hydrogen atom, an alkyl group, an alkenyl group, an alkynyl group, an aryl group, an acyl group, or an aralkyl group. n9 represents an integer of 0 to 15. In this case, when n9 represents 0, both of R⁹¹ and R⁹³ do not represent a hydrogen atom.

Formula (X): R^{A3} has the same definition as that for R^{N}. R^{A1} and R^{A2} each independently represent a hydrogen atom, an alkyl group, an alkenyl group, an alkynyl group, an aryl group, an aralkyl group, a sulfanyl group, a hydroxy group, or an amino group.

Formula (XI): Y⁷ and Y⁸ each independently represent a hydrogen atom, a sulfur atom, a methylene group, an imino group, or a carbonyl group. R^{B1} represents a substituent. nB represents an integer of 0 to 8.

Formula (XII): Y⁹ and Y¹⁰ each independently represent an oxygen atom, a sulfur atom, a methylene group, an imino group, or a carbonyl group. X⁵ and X⁶ each independently represent a sulfur atom or an oxygen atom. The broken line means that the bond may be a single bond or a double bond. R^{C1} represents a substituent. nC represents an integer of 0 to 2.

Formula (XIII): X³ represents an oxygen atom, a sulfur atom, or an imino group. X⁵ represents an oxygen atom, a sulfur atom, an imino group, or a methylene group. R^{D1} represents a substituent. nD represents an integer of 0 to 4.

[19] The etching liquid according to any one of [15] to [18], in which, with respect to removal components of the second layer, a removal aspect I which singly uses the acid compounds and a removal aspect II which combines the acid compounds and an oxidant and uses the combination are selectively used.

[20] The etching liquid according to [19], in which an organic additive selected from Formulae (V) to (IX), (XI), and (XIII), a phosphoric acid compound, a boron-containing acid compound, or a phosphonic acid compound is used in the case of the removal aspect I and an organic additive selected from Formulae (I) to (VII), (X), and (XIII) is used in the case of the removal aspect (II).

[21] The etching liquid according to any one of [15] to [20], in which the organic additive is formed of a compound selected from the following first group or second group.

TABLE A
First group

| | |
|---|---|
| Sulfolane | Sulfolane |
| DMSO | Dimethyl sulfoxide |
| XAN | Cyclohexanone |
| MEK | Methyl ethyl ketone |
| DEGDM | Diethylene glycol dimethyl ether |
| DEGDE | Diethylene glycol diethyl ether |
| ACE | Ethyl acetate |
| MPM | Methyl 3-methoxypropionate |
| γ-BL | γ butyrolactone |
| NMP | N-methylpyrrolidone |
| DMAA | NN-dimethylacetamide |
| DIO | 1,4-dioxane |
| EC | Ethylene carbonate |
| PC | Propylene carbonate |
| MSA | Methanesulfonic acid |
| PPG | Polypropylene glycol |
| HG | Hexylene glycol |
| 13BD | 1,3-butanediol |
| 14BD | 1,4-butanediol |
| MMB | 3-methoxy-3 methyl-1-butanol |
| MMBA | 3-methoxy-3 methyl-butyl acetate |
| 3M1B | 3-methyl-1-butanol |
| PG | Propylene glycol |

TABLE B
Second group

| | |
|---|---|
| AMTAZ | 2-amino-5-mercapto-1,3,4-thiadiazole |
| MTZ | 3-mercapto-1,2,4-triazole |
| AMTZ | 3-amino-5-mercapto-1,2,4-triazole |
| DATZ | 3,5-diamino-1,2,4-triazole |
| MTAZ | 2-mercapto-1,3,4-thiadiazole |
| DMTAZ | 2,5-dimercapto-1,3,4-thiadiazole |
| TIU | Thiouracil |
| ADE | Adenine |
| MP | 6-methoxypurine |
| DAP | 2,6-diaminopurine |
| Mpy | 2-mercaptopyridine |
| Hpy | 2-hydroxypyridine |
| Apy | 2-aminopyridine |
| DAPy | 2,6-diaminopyridine |
| DDT | 1-dodecanethiol |
| DT | 1-decanethiol |
| OT | 1-octanethiol |
| Cs | Cystine |
| CsT | Cysteine |
| ME | Mercaptoethanol |
| MPA | 3-mercaptopropionic acid |
| TS | Thiosalicylic acid |
| MBTz | 2-mercaptobenzothiazole |
| MBIz | 2-mercaptobenzoimidazole |
| MC | Mercaptosuccinic acid |
| DSA | Dodecylbenzenesulfonic acid |
| POEL | Polyoxyethylene lauryl ether sulfate |
| LSA | Lauryl sulfoacetate |
| ANSA | Alkyl naphthalene sulfonic acid |
| DBNA | Dibutyl naphthalene sulfonic acid |
| ADPNA | Alkyl diphenyl ether disulfonic acid |
| DDNA | Dodecyl naphthalene sulfonic acid |
| LPS | Lauryl phosphoric acid |
| LPz | Lauryl pyridinium chloride |
| LTMA | Lauryl trimethyl ammonium |
| LDMAB | Lauryl dimethyl aminoacetic acid betaine |
| LCHIB | 2-lauryl-N-carboxymethyl-N-hydroxyethylimidazolinium |
| | betaine |
| DMLAo | Dimethyl laurylamine oxide |
| DAPAc | 3-dodecylaminopropionic acid |
| MSA | Methanesulfonic acid |
| Lau | Lauric acid |
| Cap | Capric acid |
| Nona | Nonanoic acid |
| Oc | Octanoic acid |
| Ac | Acetic acid |
| γ-H | γ-hexanolactone |
| 1O2P | 1-n-octyl-2-pyrrolidone |
| γ-U | γ-undecanolactone |
| Ox | Oxalic acid |
| SmO | Sorbitan acid ocrylate |
| SmL | Sorbitan acid laurate |
| Dec | Decanoic acid |
| PrP | Phosphoric acid |
| HBF4 | Tetrafluoroboric acid |
| PVP | Polyvinyl phosphonic acid |
| PnP | Phosphonic acid |
| OPnP | Octyl phosphonic acid |
| PPnP | Phenyl phosphonic acid |
| PPrP | Polyphosphoric acid |
| POAS | Polyoxyethylene alkyl ether sulfate |

The formulae only show representative examples.

[22] The etching liquid according to [21], in which the concentration of the organic additive in the etching liquid is in the range of 50% by mass to 99% by mass when the organic additive is included in the first group, and the concentration of the organic additive is in the range of 0.005% by mass to 10% by mass when the organic additive is included in the second group.

[23] The etching liquid according to any one of [15] to [22], in which the pH of the etching liquid is 5 or less.

[24] The etching liquid according to any one of [15] to [23], in which the ion concentration of Na, K, and Ca in the etching liquid is in the range of 1 ppt to 1 ppm.

[25] The etching liquid according to any one of [15] to [24], in which the number of coarse particles whose average particle diameter is 0.5 μm or greater is 100/cm³ or less.

[26] An etching liquid kit of a semiconductor substrate that includes a first layer containing germanium and a second layer containing metals other than germanium, which is for selectively removing the second layer with respect to a first layer, the etching liquid kit being formed by combining an oxidant, the following acid compounds, and the following organic additive, and including: a first liquid which contains at least the oxidant; and a second liquid which does not contain the oxidant.

Acid compounds: at least one compound selected from halogen acid and a salt thereof; hexafluorosilicic acid and a salt thereof; tetrafluoroboric acid and a salt thereof, and hexafluorophosphoric acid and a salt thereof

Organic additive: an additive formed of an organic compound which contains a nitrogen atom, a sulfur atom, a phosphorous atom, or an oxygen atom

[27] A semiconductor substrate product manufacturing method that includes a first layer containing germanium, including: a step of forming at least the first layer and a second layer containing at least one metal selected from nickel platinum, titanium, nickel, and cobalt on the semiconductor substrate; a step of forming a third layer containing components of both layers between the first layer and the second layer by heating the semiconductor substrate; a step of preparing an etching liquid containing the following acid compounds; and a step of bringing the etching liquid into contact with the second layer and selectively removing the second layer with respect to the first layer and the third layer.

Acid compounds: at least one compound selected from halogen acid and a salt thereof; hexafluorosilicic acid and a salt thereof; tetrafluoroboric acid and a salt thereof, and hexafluorophosphoric acid and a salt thereof

[28] An etching liquid which is used for a semiconductor process, containing fluorine ions and an acid assistant.

[29] The etching liquid according to [28], further containing an organic solvent and water.

[30] The etching liquid according to [28] or [29], in which the acid assistant is a boron-containing acid compound, a phosphoric acid compound, a phosphonic acid compound, HBr, or HCl.

[31] The etching liquid according to any one of [28] to [30], in which the pKa of the acid assistant is 4 or less.

[32] The etching liquid according to any one of [29] to [31], in which the organic solvent is a protonic polar organic solvent.

[33] The etching liquid according to any one of [28] to [32], in which the concentration of the fluorine ion is in the range of 0.1% by mass to 20% by mass.

[34] The etching liquid according to any one of [29] to [33], in which the concentration of water is in the range of 0.1% by mass to 50% by mass.

[35] The etching liquid according to any one of [28] to [34], in which the concentration of the acid assistant is in the range of 0.1% by mass to 20% by mass.

[36] The etching liquid according to any one of [29] to [35], in which the concentration of the organic solvent is in the range of 50% by mass to 98% by mass.

[37] The etching liquid according to any one of [28] to [36], further containing a carboxylic acid compound.

[38] The etching liquid according to any one of [28] to [37], which is used for a semiconductor substrate that includes a third layer containing silicon or silicide of germanium and a second layer containing metals other than germanium.

[39] The etching liquid according to [38], in which the second layer is a layer containing titanium.

[40] An etching method, in which an etching liquid containing fluorine ions and an acid assistant is used for a semiconductor substrate.

[41] The etching method according to [40], which is used for a semiconductor substrate that includes a third layer containing silicon or silicide of germanium and a second layer containing metals other than germanium.

[42] The etching method according to [40] or [41], in which the second layer is a layer containing titanium.

[43] A semiconductor substrate product manufacturing method, in which a semiconductor substrate product is manufactured through the etching method according to any one of [40] to [42].

According to the etching method, the etching liquid and the etching liquid kit used in the method, and the semiconductor substrate product manufacturing method of the present invention, a layer containing a specific metal can be selectively removed with respect to a layer containing germanium. Further, the etching liquid and the etching method of the present invention have excellent etching properties such as in-plane uniformity of etching.

The above-described features, other features, and advantages of the present invention will become more apparent from the following description and the accompanying drawings.

### BRIEF DESCRIPTION OF THE DRAWINGS

FIG. 1(a), FIG. 1(b) and FIG. 1(c) each are a sectional view schematically illustrating examples of a process of preparing a semiconductor substrate according to an embodiment of the present invention.

FIG. 2(A), FIG. 2(B), FIG. 2(C), FIG. 2(D) and FIG. 2(E) each are a process view illustrating examples of manufacturing a MOS transistor according to an embodiment of the present invention.

FIG. 3 is a configuration view of a device illustrating a part of a wet etching device according to a preferred embodiment of the present invention.

FIG. 4 is a plan view schematically illustrating a movement trajectory line of a nozzle with respect to a semiconductor substrate according to an embodiment of the present invention.

FIG. 5 is a plan view illustrating measurement points of a wafer of an in-plane uniformity test.

FIG. 6 is a sectional view schematically illustrating a structure of a substrate according to another embodiment of the present invention.

### DESCRIPTION OF THE PREFERRED EMBODIMENTS

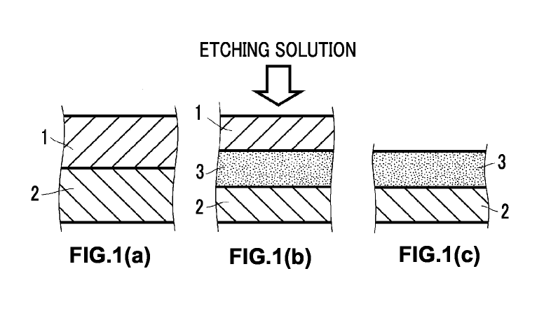

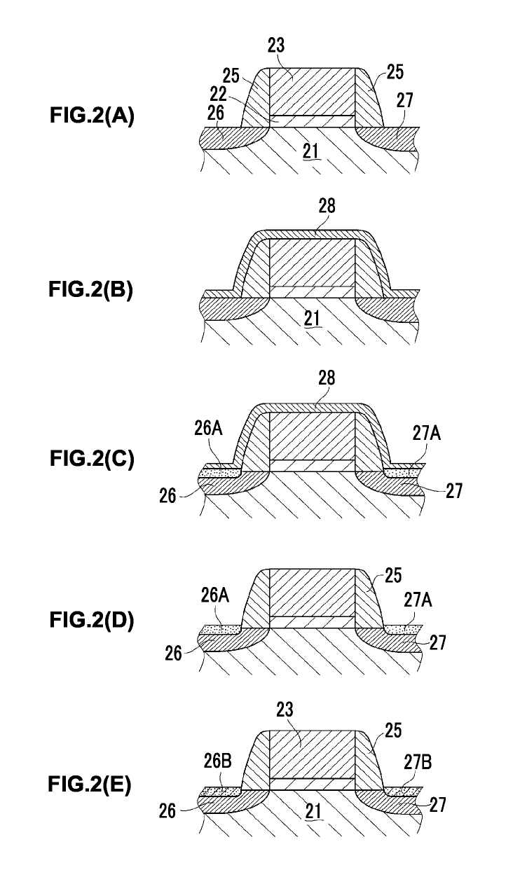

First, preferred embodiments of an etching process according to an etching method of the present invention will be described with reference to FIGS. 1(a) to 1(c) and 2(A) to 2(E).

[Etching Process]

FIG. 1(a), FIG. 1(b) and FIG. 1(c) each are a view illustrating a semiconductor substrate before and after etching is performed. In preparation examples of the present embodiment, a metal layer (second layer) 1 is arranged on the upper surface of a germanium-containing layer (first layer) 2. As the germanium-containing layer (first layer), a SiGe epitaxial layer constituting a source electrode or a drain electrode is used. In the present invention, it is preferable that the germanium-containing layer is a SiGe epitaxial layer or a Ge epitaxial layer in such terms that remarkable effects of the etching liquid are exhibited.

As a constituent material of the metal layer (second layer) 1, a metal (a single metal or a composite metal) such as titanium (Ti), cobalt (Co), nickel (Ni), or nickel platinum (NiPt) is exemplified. In order to form a metal layer, a method normally used for forming such a metal layer can be used. Specifically, a film formation method using chemical vapor deposition (CVD) is exemplified. In this case, the thickness of the metal layer is not particularly limited, but a film whose thickness is in the range of 5 nm to 50 nm is exemplified. In the present invention, it is preferable that a metal layer is a NiPt layer (the content of Pt is preferably in the range of more than 0% by mass to 20% by mass) or a Ni layer (the content of Pt is 0% by mass) in terms such that remarkable effects of the etching liquid are exhibited.

The metal layer may contain other elements other than the metal elements exemplified above. For example, oxygen or nitrogen to be inevitably mixed thereinto may be present. It is preferable that the amount of inevitable impurities is suppressed within the range of 1 ppt to 10 ppm (on a mass basis).

Further, materials which are not desired to be etched are present on the semiconductor substrate in addition to the materials described above. It is possible for the etching liquid of the present invention to minimize corrosion of the materials which are not desired to be etched. As the materials which are not desired to be etched, at least one selected from a group consisting of Al, SiO2, SiN, SiOC, HfO, and TiAlC is exemplified.

After the metal layer 1 is formed on the upper side of the germanium-containing layer 2 in the above-described process (a), annealing (sintering) is performed and a metal-Si reaction film (third layer: germanium silicide layer) is formed on the interface thereof (process (b)). The annealing may be performed under conditions normally used for manufacturing this kind of element, and a treatment performed in a temperature range of 200° C. to 1000° C. is exemplified. In this case, the thickness of the germanium silicide layer 3 is not particularly limited, but a layer whose thickness is 50 nm or less or a layer whose thickness is 10 nm or less is exemplified. The lower limit is not particularly limited, but the lower limit is substantially 1 nm or greater. The germanium silicide layer is used as a low resistance film and functions as a conductive portion that electrically connects a source electrode, a drain electrode positioned in the lower portion thereof and a wiring arranged in the upper portion thereof. Accordingly, conduction is inhibited when defects or corrosion occurs in the germanium silicide layer and this leads to degradation in quality such as malfunction of an element in some cases. Particularly, the structure of an integrated circuit in the inside of a substrate has been miniaturized and thus even a small amount of damage may have a great impact on the performance of the element. Consequently, it is desired to prevent such defects or corrosion as much as possible.

Moreover, in the present specification, the germanium silicide layer is included in the germanium-containing layer of the first layer in a broad sense. Therefore, selective removal of the second layer with respect to the first layer includes an aspect of preferentially removing the second layer (metal layer) with respect to the germanium-containing layer which is not silicided and an aspect of preferentially removing the second layer (metal layer) with respect to the germanium silicide layer. In a narrow sense, when it is necessary to distinguish the germanium-containing layer (excluding the germanium silicide layer) of the first layer from the germanium silicide layer of the third layer, the layers are respectively referred to as the first layer and the third layer.

Next, the remaining metal layer 1 is etched (process (b)→process (c)). In the present embodiment, the etching liquid is used at this time and the metal layer 1 is removed by providing the etching liquid from the upper side of the metal layer 1 to be in contact with the metal layer 1. The provision of the etching liquid will be described below.

The germanium-containing layer 2 is formed of a SiGe epitaxial layer and can be formed through crystal-growth on a silicon substrate having a specific crystallinity according to a chemical vapor deposition (CVD) method. Alternatively, an epitaxial layer formed from a desired crystallinity may be formed according to electron beam epitaxy (MBE).

In order to use the germanium-containing layer as a P type layer, it is preferable that boron (B) whose concentration is in the range of 1×10¹⁴ cm⁻³ to 1×10²¹ cm⁻³ is doped. In order to use the germanium-containing layer as an N type layer, it is preferable that phosphorus (P) whose concentration is in the range of 1×10¹⁴ cm⁻³ to 1×10²¹ cm⁻³ is doped.

The Ge concentration in the SiGe epitaxial layer is preferably 20% by mass or greater and more preferably 40% by mass or greater. The upper limit thereof is preferably 100% by mass or less and more preferably 90% by mass or less. Since the in-plane uniformity of a treated wafer can be improved, it is preferable that the Ge concentration is set to be within the above-described range. The reason why it is preferable that Ge has a relatively high concentration is assumed as follows. In a case where Ge is compared with Si, it is understood that an oxide film SiOx is generated after Si is oxidized and the oxides become a reaction-stop layer without being eluted. For this reason, a difference is generated between a portion in which Ge is eluted and a portion in which the reaction is stopped due to SiOx within the wafer and thus the in-plane uniformity of the wafer is damaged. Meanwhile, it is considered that the influence of inhibition of SiOx according to the above-described mechanism becomes decreased when the Ge concentration becomes greater and thus the in-plane uniformity of the wafer can be secured when a liquid chemical with high removability with respect to the metal layer such as the etching liquid of the present invention is used. In addition, in a case where the concentration of germanium is 100% by mass, a layer formed along with an alloy of the second layer resulting from the annealing contains germanium and specific metal elements of the second layer and does not contain silicon, but is referred to as a germanium silicide layer including the above-described meaning for the sake of convenience in the present specification.

After the silicide process, the germanium silicide layer is formed as a layer containing germanium (Ge) and components (the above-described specific metals) of the second layer between the germanium-containing layer (first layer) and the metal layer (second layer). The germanium silicide layer is included in the first layer in a broad sense, but is referred to as a “third layer” when distinguished from the first layer in a narrow sense. The composition thereof is not particularly limited, but “x+y” is preferably in the range of 0.2 to 0.8 and more preferably in the range of 0.3 to 0.7 in the formula of SixGeyMz (M: metal element) when “x+y+z” is set to 1. In a case of z, z is preferably in the range of 0.2 to 0.8 and more preferably in the range of 0.3 to 0.7. The preferable range of the ratio of x to y is as defined above. In this case, the third layer may contain other elements. This point is the same as that described in the section of the metal layer (second layer).

(Processing of MOS Transistor)

FIG. 2(A), FIG. 2(B), FIG. 2(C), FIG. 2(D) and FIG. 2(E) each are a process view illustrating examples of manufacturing a MOS transistor. FIG. 2(A) illustrates a process of forming the structure of the MOS transistor, FIG. 2(B) illustrates a process of sputtering the metal layer, FIG. 2(C) illustrates a first annealing process, FIG. 2(D) illustrates a process of selectively removing the metal layer, and FIG. 2(E) illustrates a second annealing process.

As illustrated in the figures, a gate electrode 23 is formed through a gate insulating film 22 formed on the surface of a silicon substrate 21. Extension regions may be individually formed on both sides of the gate electrode 23 of the silicon substrate 21. A protective layer (not illustrated) that prevents contact with a NiPt layer may be formed on the upper side of the gate electrode 23. Moreover, a side wall 25 formed of a silicon oxide film or a silicon nitride film is formed and a source electrode 26 and a drain electrode 27 are formed by ion implantation.

Next, as illustrated in the figures, a NiPt film 28 is formed and a rapid annealing treatment is performed. In this manner, elements in the NiPt film 28 are allowed to be diffused into the silicon substrate for silicidation (in the present specification, for the sake of convenience, an alloy resulting from annealing is referred to as silicidation including the case where the concentration of germanium is 100% by mass). As a result, the upper portion of the source electrode 26 and the drain electrode 27 is silicided and a NiPtGeSi source electrode portion 26A and a NiPtSiGe drain electrode portion 27A are formed. At this time, as illustrated in FIG. 2(E), an electrode member can be changed to be in a desired state (an annealed silicide source electrode 26B and an annealed silicide drain electrode 27B) by performing the second annealing if necessary. The temperature of the first annealing or the second annealing is not particularly limited, but the annealing can be performed in a temperature range of, for example, 400° C. to 1100° C.

The NiPt film 28 remaining without contributing to silicidation can be removed using the etching liquid of the present invention (FIGS. 2(C) and 2(D)). At this time, illustration is made in a greatly schematic manner and the NiPt film remaining by being deposited on the upper portion of the silicided layer (26A and 27A) may or may not be present. The semiconductor substrate or the structure of the product is illustrated in a simplified manner and, if necessary, the illustration may be interpreted such that there is a required member.

Preferred examples of the constituent materials are as follows.

Silicon substrate 21: Si, SiGe, and Ge

Gate insulating film 22: HfO₂ (High-k)

Gate electrode 23: Al, W, TiN, or Ta

Side wall 25: SiOCN, SiN, SiO₂ (low-k)

Source electrode 26: SiGe, Ge, and Si

Drain electrode 27: SiGe, Ge, and Si

Metal layer 28: Ni, Pt, Ti, and Co

Cap (not illustrated): TiN

The semiconductor substrate to which the etching method of the present invention is applied is described above, but the etching method of the present invention can be applied to other semiconductor substrates without being limited to the specific example. For example, a semiconductor substrate including a high dielectric film or a metal gate FinFET which has a silicide pattern on the source region and/or the drain region is exemplified.

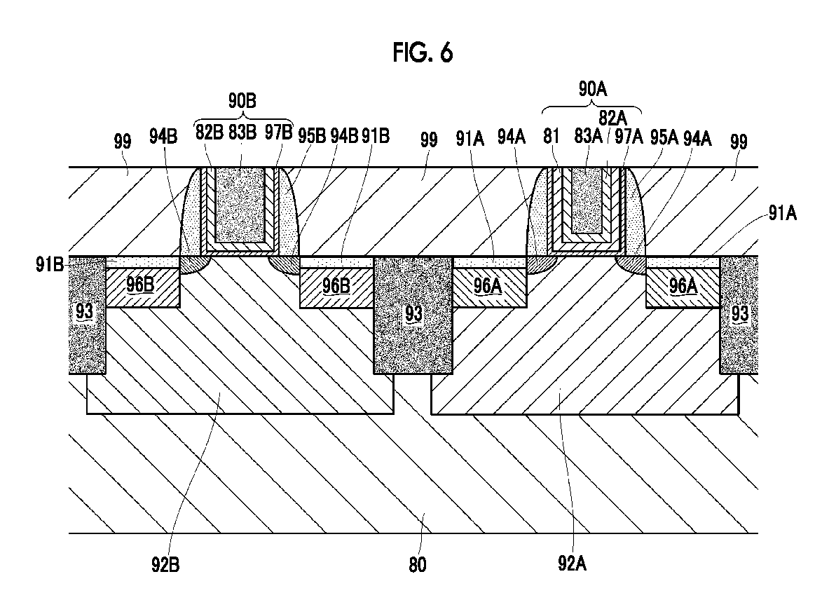

FIG. 6 is a sectional view schematically illustrating a structure of a substrate according to another embodiment of the present invention. The reference numeral 90A indicates a first gate stack positioned in a first device region. The reference numeral 90B indicates a second gate stack positioned in a second element region. Here, the gate stack contains a conductive tantalum alloy layer or TiAlC. When the first gate stack is described, the reference numeral 92A indicates a well. The reference numeral 94A indicates a first source/drain extension region, the reference numeral 96A indicates a first source/drain region, and the reference numeral 91A indicates a first metal semiconductor alloy portion. The reference numeral 95A indicates a first gate spacer. The reference numeral 97A indicates a first gate insulating film, the reference numeral 81 indicates a first work function material layer, and the reference numeral 82A indicates a second work function material layer. The reference numeral 83A indicates a first metal portion which becomes an electrode. The reference numeral 93 indicates a trench structure portion and the reference numeral 99 indicates a flattened dielectric layer. The reference numeral 80 indicates a lower semiconductor layer.

The first gate stack has the same structure as that of the second gate stack and the reference numerals 91B, 92B, 94B, 95B, 96B, 97B, 82B, and 83B respectively correspond to the reference numerals 91A, 92A, 94A, 95A, 96A, 97A, 82A, and 83A of the first gate stack. When a difference between both structures is described, the first gate stack includes the first work function material layer 81, but the second gate stack is not provided with such a layer.

The work function material layer may be any one of a p type work function material layer or an n type work function material layer. The p type work function material indicates a material having a work function between a valence band energy level and a mid-band gap energy level of silicon. That is, the energy level of a conduction band and the valence band energy level are equivalently separated from each other in the energy level of silicon. The n type work function material indicates a material having a work function between the energy level of the conduction band of silicon and the mid-band gap energy level of silicon.

It is preferable that the material of the work function material layer is a conductive tantalum alloy layer or TiAlC. The conductive tantalum alloy layer can contain a material selected from (i) an alloy of tantalum and aluminum, (ii) an alloy of tantalum and carbon, and (iii) an alloy of tantalum, aluminum, and carbon.

(i) TaAl

In the alloy of tantalum and aluminum, the atom concentration of tantalum can be set to be in the range of 10% to 99%. The atom concentration of aluminum can be set to be in the range of 1% to 90%.

(ii) TaC

In the alloy of tantalum and carbon, the atom concentration of tantalum can be set to be in the range of 20% to 80%. The atom concentration of carbon can be set to be in the range of 20% to 80%.

(iii) TaAlC

In the alloy of tantalum, aluminum, and carbon, the atom concentration of tantalum can be set to be in the range of 15% to 80%. The atom concentration of aluminum can be set to be in the range of 1% to 60%. The atom concentration of carbon can be set to be in the range of 15% to 80%.

In another embodiment, the work function material layer can be set to be (iv) a titanium nitride layer substantively formed of titanium nitride or (v) a layer of an alloy of titanium, aluminum, and carbon.

(iv) TiN

In the titanium nitride layer, the atom concentration of titanium can be set to be in the range of 30% to 90%. The atom concentration of nitrogen can be set to be in the range of 10% to 70%.

(v) TiAlC

In the layer of the alloy of titanium, aluminum, and carbon, the atom concentration of titanium can be set to be in the range of 15% to 45%. The atom concentration of aluminum can be set to be in the range of 5% to 40%. The atom concentration of carbon can be set to be in the range of 5% to 50%.

The work function material layer can be formed by atomic layer deposition (ALD), physical vapor deposition (PVD), or chemical vapor deposition (CVD). It is preferable that the work function material layer is formed so as to cover the gate electrode, and the film thickness thereof is preferably 100 nm or less, more preferably 50 nm or less, and still more preferably in the range of 1 nm to 10 nm.

Among these, in the present invention, it is preferable to use a substrate in which a layer of TiAlC is employed from a viewpoint of suitably expressing selectivity of etching.

In the element of the present embodiment, the gate dielectric layer is formed of a high-k material containing a metal and oxygen. A known material can be used as the high-k gate dielectric material. The layer can be allowed to be deposited using a normal method. Examples thereof include chemical vapor deposition (CVD), physical vapor deposition (PVD), molecular beam deposition (MBD), pulsed laser deposition (PLD), liquid raw material mist chemical deposition (LSMCD), and atomic layer deposition (ALD). Examples of the typical high-k dielectric material include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, and Y₂OₓN_{y}. x is in the range of 0.5 to 3 and y is in the range of 0 to 2. The thickness of the gate dielectric layer is preferably in the range of 0.9 nm to 6 nm and more preferably in the range of 1 nm to 3 nm. Among these, it is preferable that the gate dielectric layer is formed of hafnium oxide (HfO₂).

Other members or structures can be formed by a normal method according to appropriate normal materials. Specifically, US2013/0214364A and US2013/0341631A can be referenced and the contents of which are incorporated by reference.

In the etching liquid according to the preferred embodiment of the present invention, even in a case of a substrate whose work function material layer described above is exposed, metals (Ni, Pt, Ti, and the like) of the first layer can be effectively removed while suppressing damage of the layer.

[Etching Liquid]

Next, a preferred embodiment of the etching liquid of the present invention will be described. The etching liquid of the present embodiment contains a specific acid compound and an oxidant and a specific organic additive as needed. Hereinafter, respective components including arbitrary components will be described below.

(Acid Compounds)

The etching liquid according to the present invention contains an acid compound. The acid compound is at least one compound selected from any of halogen acid (hydrochloric acid, hydrofluoric acid, or the like) and a salt thereof; hexafluorosilicic acid and a salt thereof; tetrafluoroboric acid and a salt thereof, and hexafluorophosphoric acid and a salt thereof.

The concentration of the acid compound contained in the etching liquid is preferably 0.01% by mass or greater, more preferably 0.02% by mass, and particularly preferably 0.03% by mass or greater. The upper limit thereof is preferably 20% by mass or less, more preferably 15% by mass or less, still more preferably 10% by mass or less, and particularly preferably 3% by mass or less. It is preferable that the concentration of the acid compound is set to be in the above-described range because damage of the germanium-containing layer (first layer) or the germanium silicide layer (third layer) can be effectively suppressed while excellent etching properties of the metal layer (second layer) are maintained. In regard to identification of components of the etching liquid, it is not necessary for the components thereof to be confirmed as acid compounds. For example, in a case of hydrochloric acid, when chlorine ions (Cl⁻) in an aqueous solution are identified, the presence and the amount thereof are grasped.

Moreover, in the present invention, the acid compounds may be used alone or in combination of two or more kinds thereof. In the case where the acid compounds are used in combination of two or more kinds thereof, the combining ratio is not particularly limited, but the total amount used thereof is preferably in the above-described range of concentration as the sum of two or more kinds of acid compounds.

(Oxidant)

It is preferable that the etching liquid according to the present embodiment contains an oxidant. Preferred examples of the oxidant include nitric acid and hydrogen peroxide.

The concentration of the oxidant contained in the etching liquid is preferably 0.1% by mass or greater, more preferably 1% by mass or greater, and particularly preferably 2% by mass or greater. The upper limit thereof is preferably 20% by mass or less, more preferably 10% by mass or less, still more preferably 5% by mass or less, and particularly preferably 3% by mass or less. The concentration thereof is preferably 10 parts by mass or greater, more preferably 30 parts by mass or greater, and particularly preferably 50 parts by mass or greater based on 100 parts by mass of the acid compound. The upper limit thereof is preferably 1000 parts by mass or less, more preferably 600 parts by mass or less, and particularly preferably 200 parts by mass or less.

It is preferable that the concentration of the oxidant is set to be in the above-described range because damage of the germanium-containing layer (first layer) or the germanium silicide layer (third layer) can be effectively suppressed while excellent etching properties of the metal layer (second layer) are maintained. In regard to identification of components of the etching liquid, it is not necessary for the components thereof to be confirmed as nitric acid. For example, when nitric acid ions (NO₃⁻) in an aqueous solution are identified, the presence and the amount thereof are grasped. Moreover, the oxidant may be used alone or in combination of two or more kinds thereof.

(Specific Organic Additive)

It is preferable that the etching liquid according to the present embodiment contains a specific organic additive. The organic additive is formed of an organic compound containing a nitrogen atom, a sulfur atom, a phosphorous atom, or an oxygen atom. Among these, it is preferable that the organic additive is a compound including a substituent or a linking group selected from an amino group (—NR^{N}₂) or a salt thereof, an imino group (—NR^{N}—) or a salt thereof, a sulfanyl group (—SH), a hydroxy group (—OH), a carbonyl group (—CO—), a sulfonic acid group (—SO₃H) or a salt thereof, a phosphoric acid group (—PO₄H₂) or a salt thereof, an onium group or a salt thereof, a sulfinyl group (—SO—), a sulfonyl group (SO₂), an ether group (—O—), an amine oxide group, and a thioether group (—S—). Further, it is also preferable that the organic additive is an aprotic dissociable organic compound (an alcohol compound, an ether compound, an ester compound, or a carbonate compound), an azole compound, a betaine compound, a sulfonic acid compound, an amide compound, an onium compound, an amino acid compound, a phosphoric acid compound, or a sulfoxide compound.

R^{N} is a hydrogen atom or a substituent. As the substituent, an alkyl group (the number of carbon atoms is preferably in the range of 1 to 24, more preferably in the range of 1 to 12, still more preferably in the range of 1 to 6, and particularly preferably in the range of 1 to 3), an alkenyl group (the number of carbon atoms is preferably in the range of 2 to 24, more preferably in the range of 2 to 12, still more preferably in the range of 2 to 6, and particularly preferably in the range of 2 or 3), an alkynyl group (the number of carbon atoms is preferably in the range of 2 to 24, more preferably in the range of 2 to 12, still more preferably in the range of 2 to 6, and particularly preferably in the range of 2 or 3), an aryl group having 6 to 10 carbon atoms, or an aralkyl group having 7 to 11 carbon atoms is preferable.

It is particularly preferable that the specific organic additive is formed of a compound, a phosphoric acid compound, a boron-containing acid compound, or a phosphonic acid compound represented by the following Formulae (I) to (XIII).

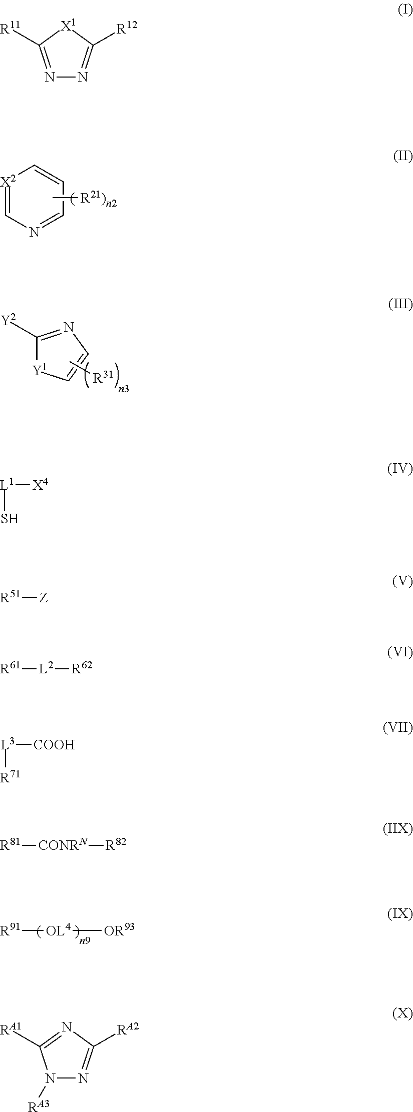

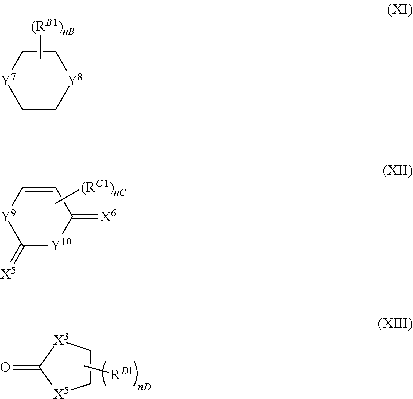

Formula (I): R¹¹ and R¹² each independently represent a hydrogen atom, an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), an aralkyl group (the number of carbon atoms is preferably in the range of 7 to 23 and more preferably in the range of 7 to 15), a sulfanyl group (SH), a hydroxy group (OH), or an amino group (—NR^{N}₂). In this case, it is preferable that at least one of R¹¹ and R¹² is a sulfanyl group, a hydroxy group, or an amino group (the number of carbon atoms is preferably in the range of 0 to 6 and more preferably in the range of 0 to 3). Further, when the above-described substituents further include other substituents (an alkyl group, an alkenyl group, and an aryl group), an arbitrary substituent T may be further included. The same applies to a substituent or a linking group described below.

X¹ represents a methylene group (CR^{C}₂), a sulfur atom (S), or an oxygen atom (0). Among these, a sulfur atom is preferable. R^{C} represents a hydrogen atom or a substituent (the substituent T described below is preferable).

Formula (II): X² represents a methine group (═CR^{C}—) or a nitrogen atom (N). R²¹ represents a substituent (the substituent T described below is preferable). Among these, a sulfanyl group (SH), a hydroxy group (OH), or an amino group (NR^{N}₂) is preferable.

n2 represents an integer of 0 to 4.

When a plurality of R²¹'s are present, R²¹'s may be the same as or different from each other and may be bonded or condensed to each other to form a ring. As the ring to be formed, a nitrogen-containing heterocycle is preferable and an unsaturated 5- or 6-membered nitrogen-containing heterocycle is more preferable.

Formula (III): Y¹ represents a methylene group, an imino group (NR^{N}), or a sulfur atom (S).

Y² represents a hydrogen atom, an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), an aralkyl group (the number of carbon atoms is preferably in the range of 7 to 23 and more preferably in the range of 7 to 15), an amino group (the number of carbon atoms is preferably in the range of 0 to 6 and more preferably in the range of 0 to 3), a hydroxy group, or a sulfanyl group.

R³¹ represents a substituent (the substituent T described below is preferable). Among these substituents, a sulfanyl group (SH), a hydroxy group (OH), or an amino group (NR^{N}₂) is preferable.

n3 represents an integer of 0 to 2.

When a plurality of R³¹'s are present, R³¹'s may be the same as or different from each other and may be bonded or condensed to each other to form a ring. As the ring to be formed, a 6-membered ring is preferable and examples thereof include rings having a benzene structure or a 6-membered heteroaryl structure (among these structures, a pyridine structure or a pyrimidine structure is preferable).

It is preferable that Formula (III) is Formula (III-1) below.

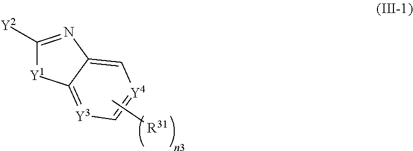

Y³ and Y⁴ each independently represent a methine group (═CR^{C}—) or a nitrogen atom (N).

Y¹, Y², R³¹, and n3 have the same definitions as those described above. The positions of Y³ and Y⁴ may be different in a 6-membered ring.

Formula (IV): L¹ represents an alkylene group (the number of carbon atoms is preferably in the range of 1 to 12, more preferably in the range of 1 to 6, and particularly preferably in the range of 1 to 3), an alkynylene group (the number of carbon atoms is preferably in the range of 2 to 12 and more preferably in the range of 2 to 6), an alkenylene group (the number of carbon atoms is preferably in the range of 2 to 12 and more preferably in the range of 2 to 6), an arylene group (the number of carbon atoms is preferably 6 to 22 and more preferably in the range of 6 to 14), or an aralkylene group (the number of carbon atoms is preferably in the range of 7 to 23 and more preferably in the range of 7 to 15).

X⁴ represents a carboxyl group or a hydroxy group.

A SH group in the formula may be a dimer by being disulfidated.

Formula (V): R⁵¹ represents an alkyl group (the number of carbon atoms is preferably in the range of 1 to 24, more preferably in the range of 1 to 12, still more preferably in the range of 1 to 6, and particularly preferably in the range of 1 to 3), an alkenyl group (the number of carbon atoms is preferably in the range of 2 to 24, more preferably in the range of 2 to 12, and still more preferably in the range of 2 to 6), an alkynyl group (the number of carbon atoms is preferably in the range of 2 to 24, more preferably in the range of 2 to 12, and still more preferably in the range of 2 to 6), an aryl group (the number of carbon atoms is preferably in the range of 6 to 22 and more preferably in the range of 6 to 14), or an aralkyl group (the number of carbon atoms is preferably in the range of 7 to 23 and more preferably in the range of 7 to 15).

When R⁵¹ represents an aryl group, it is preferable that an alkyl group having 1 to 20 carbon atoms, an alkenyl group having 2 to 20 carbon atoms, an alkynyl group having 2 to 20 carbon atoms, an alkoxy group having 1 to 20 carbon atoms, an aryl group having 6 to 14 carbon atoms, or an aryloxy group having 6 to 14 carbon atoms is substituted therewith.

When R⁵¹ represents an alkyl group, the structure thereof may be as follows.

*—R⁵²—(R⁵³—Y⁵³)ₙ₅—R⁵⁴

R⁵² is a single bond or a linking group which has the same definition as that for L¹. R⁵³ is a linking group which has the same definition as that for L¹. Y⁵³ represents an oxygen atom (O), a sulfur atom (S), a carbonyl group (CO), or an imino group (NR^{N}). Alternatively, Y⁵³ may represent a combination of an oxygen atom (O), a sulfur atom (S), a carbonyl group (CO), and an imino group (NR^{N}), and examples thereof include (C═O)O and O(C═O). R⁵⁴ represents an alkyl group (the number of carbon atoms is preferably in the range of 1 to 24, more preferably in the range of 1 to 12, still more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), or an aralkyl group (the number of carbon atoms is preferably in the range of 7 to 23 and more preferably in the range of 7 to 15).

n5 represents an integer of 0 to 8.

R⁵¹ may further include a substituent T and, among these, a sulfanyl group (SH), a hydroxy group (OH), or an amino group (NR^{N}₂) is preferable.

Z represents an amino group (NR^{N}₂) (the number of carbon atoms is preferably in the range of 0 to 6 and more preferably in the range of 0 to 3), a sulfonic acid group (SO₃H), a sulfuric acid group (SO₄H), a phosphoric acid group (PO₄H₂), a carboxyl group, a hydroxy group, a sulfanyl group (SH), an onium group (the number of carbon atoms is preferably in the range of 3 to 12), an acyloxy group, or an amine oxide group (—NR^{N}₂⁺O⁻).

In the present invention, an amino group, a sulfonic acid group, a phosphoric acid group, or a carboxyl group may form an acid ester (for example, in a case of an alkyl ester, the number of carbon atoms is in the range of 1 to 24, more preferably in the range of 1 to 12, and still more preferably in the range of 1 to 6) unless otherwise noted in a case of a salt or an acid thereof. An alkyl group forming a carboxylic acid ester may further include a substituent T and examples thereof include an alkyl group having a hydroxy group. At this time, the alkyl group may form a ring structure with a group (for example, O, S, CO, or NR^{N}) containing a heteroatom. As the alkyl group having a ring structure which includes a hydroxy group, a sorbitan residue is exemplified. That is, a sorbitan fatty acid ester (the number of carbon atoms is preferably in the range of 7 to 40 and more preferably in the range of 8 to 24) can be suitably used.

An arbitrary linking group may be included between R⁵¹ and Z in Formula (V) within the range in which the linking group exhibits desired effects. As the arbitrary linking group, the examples of L¹ or the examples of Y⁵³ can be exemplified.

When Formula (V) represents a carboxylic acid, it is preferable that R⁵¹ represents an alkyl group. In this case, the number of carbon atoms is preferably in the range of 1 to 24, more preferably in the range of 3 to 20, still more preferably in the range of 6 to 18, and particularly preferably in the range of 8 to 16. The alkyl group may further include a substituent T and this is the same as those described above. When Formula (V) is a fatty acid, it is preferable that the number of carbon atoms is relatively low as described above. It is considered that this is because protection properties of germanium and the silicide layer are more effectively exhibited when appropriate hydrophobicity is imparted to the additive.

Preferred examples of the compound having an onium group include a compound (R⁵¹—NR^{N}₃⁺M⁻) having an ammonium group, a compound (C₅R^{N}₅N⁺—R⁵¹.M⁻) having a pyridinium group, or an imidazolinium group (C₃N₂RN—R⁵¹.M⁻). R^{N} has the same definition as that described above. M⁻ is an anion (for example, OH⁻) which becomes a pair.

Specific examples of the compound having an onium group further include compounds represented by the following formulae.

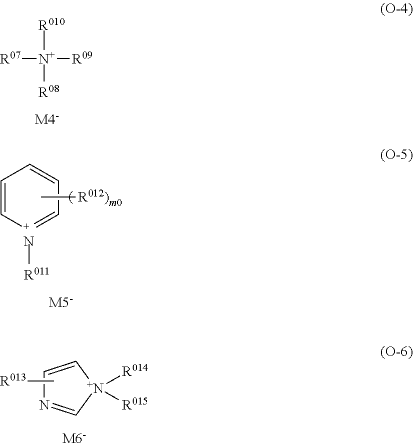

In the formulae, R⁰⁷ to R⁰¹⁰ each independently represent an alkyl group having 1 to 24 carbon atoms, an alkenyl group having 2 to 24 carbon atoms, an alkynyl group having 2 to 24 carbon atoms, an aryl group having 6 to 14 carbon atoms, an aralkyl group having 7 to 14 carbon atoms, and a group represented by the following Formula (y). In this case, at least one of R⁰⁷ to R⁰¹⁰ has preferably 6 or more carbon atoms and more preferably 8 or more carbon atoms.

Y1-(Ry1-Y2)my-Ry2-* (y)

Y1 represents a hydrogen atom, an alkyl group having 1 to 12 carbon atoms, an alkenyl group having 2 to 12 carbon atoms, an alkynyl group having 2 to 12 carbon atoms, an aralkyl group having 7 to 14 carbon atoms, an aryl group having 6 to 14 carbon atoms, a hydroxy group, or an alkoxy group having 1 to 4 carbon atoms. Y2 represents O, S, CO, or NR^{N}. Ry1 and Ry2 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these. my represents an integer of 0 to 6. When my is 2 or greater, a plurality of Ry1's and Y2's may be different from each other. Ry1 and Ry2 may further include a substituent T. The symbol “*” indicates an atomic bond.

R⁰¹¹ represents a group which is the same as that for R⁰⁷. The number of carbon atoms is preferably 6 or greater and more preferably 8 or greater. R⁰¹² represents a substituent T. mO represents an integer of 0 to 5.

M4⁻ and M5⁻ are counterions and examples thereof include a hydroxide ion.

R⁰¹³ represents a group which is the same as that for Y1. R⁰¹⁴ and R⁰¹⁵ represent the same group represented by Formula (y). It is preferable that at least one Y1 in R⁰¹⁴ and R⁰¹⁵ represents a carboxyl group and preferably constitutes betaine.

When a compound (organic onium) having an onium group is employed as an organic additive, it is preferable that halogen acid and a salt thereof, an oxidant (for example, nitric acid), and a sulfonic acid compound (for example, methanesulfonic acid) are used by being combined with each other. It is more preferable that the organic onium is organic ammonium. Specifically, the organic onium is preferably organic ammonium having 5 or more carbon atoms and more preferably organic ammonium having 8 or more carbon atoms. The upper limit of the number of the carbon atoms is substantively 35 or less.

It is considered that an organic cation acts in a system in the following manner although an assumption is included. In the etching liquid of the present invention, it is understood that halogen ions and nitric acid ions mainly show an etching action of the metal layer (second layer). It is understood that a sulfonic acid compound plays a role of decreasing the solubility of germanium and suppressing the elution. For this reason, a substantial amount of a sulfonic acid compound is preferably used. In this manner, selectivity of the germanium-containing layer (first layer) and the metal layer (second layer) is increased, but it is not sufficient. In the present embodiment, when an organic cation is allowed to coexist in the layer, the organic cation is adsorbed on the surface of the germanium-containing layer and thus an effective anticorrosive surface is formed. In this manner, the selectivity of etching is markedly expressed along with the effect of suppressing elution of germanium done by the sulfonic acid compound. At this time, when the number of carbon atoms of the organic cation is increased (for example, 5 or more carbon atoms), the dissolution of germanium can be more markedly suppressed. From a viewpoint of such an action, a small amount of organic cation may be present in the system and, particularly preferably, the appropriate amount and the kind which may enhance a cooperative action with the sulfonic acid compound is selected.

Examples of the organic onium include a nitrogen-containing onium (quaternary ammonium or the like), a phosphorus-containing onium (quaternary phosphonium or the like), a sulfur-containing onium (for example, SRy₃⁺: Ry represents an alkyl group having 1 to 6 carbon atoms). Among these, a nitrogen-containing onium (quaternary ammonium, pyridinium, pyrazolium, imidazolium, or the like) is preferable. It is preferable that the organic cation is quaternary ammonium from among those described above.

As the organic onium, an ion represented by the following Formula (Q-1) is exemplified.

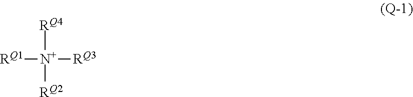

In the formula, R^{Q1} to R^{Q4} each independently represent an alkyl group having 1 to 35 carbon atoms, an alkenyl group having 2 to 35 carbon atoms, an alkynyl group having 2 to 35 carbon atoms, an aryl group having 6 to 14 carbon atoms, an aralkyl group having 7 to 15 carbon atoms, or a group represented by the following Formula (yq). In this case, the total number of carbon atoms of R^{Q1} to R^{Q4} is preferably 5 or more and more preferably 8 or more.

Y3-(Ry3-Y4)ny-Ry4-* (yq)

Y3 represents an alkyl group having 1 to 12 carbon atoms, an alkenyl group having 2 to 12 carbon atoms, an alkynyl group having 2 to 12 carbon atoms, an aralkyl group having 7 to 14 carbon atoms, an aryl group having 6 to 14 carbon atoms, a hydroxyl group, a sulfanyl group, an alkoxy group having 1 to 4 carbon atoms, or a thioalkoxy group having 1 to 4 carbon atoms. Y4 represents O, S, CO, or NR^{N} (R^{N} has the same definition as that described above). Ry3 and Ry4 each independently represent an alkylene group having 1 to 6 carbon atoms, an alkenylene group having 2 to 6 carbon atoms, an alkynylene group having 2 to 6 carbon atoms, an arylene group having 6 to 10 carbon atoms, or a combination of these. ny represents an integer of 0 to 6. When ny is 2 or greater, a plurality of Ry3's and Y4's may be different from each other. Ry3 and Ry4 may further include a substituent T. The symbol “*” indicates an atomic bond.

It is preferable that the organic cation is at least one selected from a group consisting of an alkyl ammonium cation, an aryl ammonium cation, and an alkyl-aryl ammonium cation.

Specifically, tetraalkyl ammonium (the number of carbon atoms is preferably in the range of 5 to 35, more preferably in the range of 8 to 25, and particularly preferably in the range of 10 to 25) is preferable. At this time, an alkyl group may be substituted with an arbitrary substituent (for example, a hydroxyl group, an allyl group, or an aryl group) within a range not damaging the effects of the present invention. Further, the alkyl group may be linear, branched, or cyclic. Specific examples thereof include tetramethyl ammonium (TMA), tetraethyl ammonium (TEA), benzyl trimethyl ammonium, ethyl trimethyl ammonium, 2-hydroxy ethyl trimethyl ammonium, benzyl triethyl ammonium, hexadecyl trimethyl ammonium, tetrabutyl ammonium (TBA), tetrahexyl ammonium (THA), tetrapropyl ammonium (TPA), trimethyl benzyl ammonium, lauryl pyridinium, cetyl pyridinium, lauryl trimethyl ammonium, hexadecyl trimethyl ammonium, octadecyl trimethyl ammonium, didecyl dimethyl ammonium, dilauryl dimethyl ammonium, distearyl dimethyl ammonium, dioleyl dimethyl ammonium, lauryl dimethyl benzyl ammonium, and cetyl trimethyl ammonium.

A supply source of the organic cation, which is not particularly limited, may be added as a salt with the halogen ion or a salt of a hydroxide ion.

It is preferable that the compound represented by Formula (V) is any one of compounds represented by the following Formulae (V-1) to (V-3). In the formulae, Z¹ and Z² represent a sulfonic acid group with a linking group L interposed therebetween. R⁵⁶ represents a substituent T and, among the examples described above, an alkyl group is preferable. n⁵¹ and n⁵⁶ represent an integer of 0 to 5. n⁵³ represents an integer of 0 to 4. The maximum values of n⁵¹, n⁵³, and n⁵⁶ are increased or decreased according to the number of Z¹ or Z² in the same ring. n⁵² represents an integer of 1 to 6 and is preferably 1 or 2. n⁵⁴ and n⁵⁵ each independently represent an integer of 0 to 4 and n⁵⁴+n⁵⁵ is 1 or greater. n⁵⁴+n⁵⁵ is preferably 1 or 2. n⁵⁷ and n⁵⁸ each independently represent an integer of 0 to 5 and n⁵⁷+n⁵⁸ is 1 or greater. n⁵⁷+n⁵⁸ is preferably 1 or 2. A plurality of R⁵⁶'s may be the same as or different from each other. A linking group L is preferably L¹, L², or a combination of these and more preferably L¹.

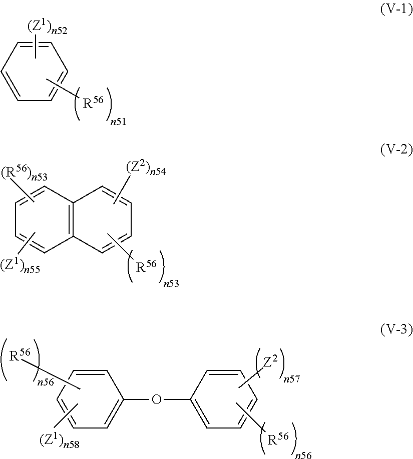

Formula (VI): R⁶¹ and R⁶² each independently represent an alkyl group (the number of carbon atoms is preferably in the range of 1 to 12, more preferably in the range of 1 to 6, and particularly preferably in the range of 1 to 3), an aryl group (the number of carbon atoms is preferably in the range of 6 to 22 and more preferably in the range of 6 to 14), an alkoxy group (the number of carbon atoms is preferably in the range of 1 to 12, more preferably in the range of 1 to 6, and particularly preferably in the range of 1 to 3), or an alkylamino group (the number of carbon atoms is preferably in the range of 1 to 12, more preferably in the range of 1 to 6, and particularly preferably in the range of 1 to 3). R⁶¹ and R⁶² may be bonded or condensed to each other to form a ring. When R⁶¹ or R⁶² represents an alkyl group, the alkyl group may be a group represented by *-R⁵²—(R⁵³—Y⁵³)—R⁵⁴.

L² represents a carbonyl group, a sulfinyl group (SO), or a sulfonyl group (SO₂).

The compound represented by Formula (VI) is preferably a compound represented by any of the following Formulae (VI-1) to (VI-3). In the formulae, R⁶¹ and R⁶² have the same definitions as those described above. Q⁶ is a 3- to 8-membered ring, preferably a 5- or 6-membered ring, more preferably a saturated 5- or 6-membered ring, and particularly preferably a 5- or 6-membered ring of saturated hydrocarbon. In this case, Q⁶ may include an arbitrary substituent T.

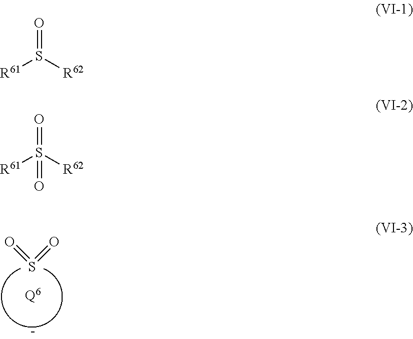

Formula (VII): R⁷¹ represents an amino group (—NR^{N}₂), an ammonium group (—NR^{N}₃⁺.M⁻), or a carboxyl group.

L³ represents a single bond or the same group as that for L¹. Among these, preferably, L³ represents a methylene group, an ethylene group, a propylene group, or (-L³¹(SR^{S})p-). L³¹ represents an alkylene group having 1 to 6 carbon atoms. R^{S} may form a disulfide group at a hydrogen atom or at this site to be dimerized.

When R⁷¹ represents a carboxyl group, the compound becomes a dicarboxylic acid compound. Examples of the dicarboxylic acid compound include oxalic acid, malonic acid, succinic acid, glutaric acid, adipic acid, pimelic acid, suberic acid, azelaic acid, sebacic acid, phthalic acid, isophthalic acid, and terephthalic acid. Among these, oxalic acid is preferable.

Formula (IIX): R⁸¹ and R⁸² each independently represent an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), or an aralkyl group (the number of carbon atoms is preferably in the range of 7 to 23 and more preferably in the range of 7 to 15).

Formula (IX): L⁴ represents the same group as that for L¹.

R⁹¹ and R⁹³ each independently represent a hydrogen atom, an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), an acyl group (the number of carbon atoms is preferably in the range of 2 to 12 and more preferably in the range of 2 to 6), or an aralkyl group (the number of carbon atoms is preferably in the range of 7 to 23 and more preferably in the range of 7 to 15). In this case, when n9 represents 0, both of R⁹¹ and R⁹³ do not represent a hydrogen atom.

n9 represents an integer of 0 to 100, is preferably in the range of 0 to 50, more preferably in the range of 0 to 25, still more preferably in the range of 0 to 15, even still more preferably in the range of 0 to 10, and particularly preferably in the range of 0 to 5.

The compound represented by Formula (IX) is more preferably a compound represented by the following Formula (IX-1).

R⁹¹—(OL⁴¹)—(OL⁴)ₙ₉₁-OR⁹³ (IX-1)

It is preferable that L⁴¹ represents an alkylene group having 2 or more carbon atoms and the number of carbon atoms is preferably in the range of 2 to 6. Due to the setting of the carbon atoms of the alkylene group, it is assumed that a specific adsorption state with a metal (for example, Ti) is not formed and the removal thereof is not inhibited. Further, it is assumed that a binding component of a metal and a fluorine atom behaves in a hydrophilic or hydrophobic manner and a compound which connects oxygen atoms and has 2 or 3 carbon atoms suitably acts. From this viewpoint, the number of carbon atoms of L⁴¹ is preferably 3 or greater, preferably in the range of 3 to 6, and particularly preferably 3 or 4. Moreover, in regard to the number of carbon atoms of L⁴¹, the carbon atoms included in a branch are excluded and the number of linked carbon atoms is preferably 2 or greater in a case of the alkylene group of a branch. For example, the number of linked carbon atoms in a 2,2-propanediyl group is 1. That is, the number of carbon atoms connecting O—O is referred to as the number of linked carbon atoms and a group having 2 or more linked carbon atoms is preferable. When an adsorption action with the above-described metals is considered, the number of linked carbon atoms is preferably 3 or greater, more preferably in the range of 3 to 6, and particularly preferably in the range of 3 to 4.

The number of linked carbon atoms of n91 is the same as that of n9.

When the present compound is a compound having two or more hydroxy groups of hydrogen atoms in R⁹¹ and R⁹³, it is preferable that the structure thereof is represented by the following Formula (IX-2).

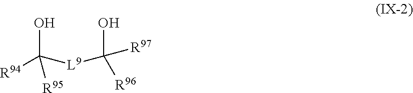

R⁹⁴ to R⁹⁷ in the formula have the same definitions as those for R⁹¹. R⁹⁴ to R⁹⁷ may further include a substituent T and, for example, may include a hydroxy group. L⁹ represents an alkylene group, and the number of carbon atoms thereof is preferably in the range of 1 to 6 and more preferably in the range of 1 to 4. Specific examples of the compound represented by Formula (IX-2) include hexylene glycol, 1,3-butanediol, and 1,4-butanediol.

From a viewpoint of hydrophilicity and hydrophobicity, it is preferable that a compound whose CLogP value is in a desired range is used as the compound represented by Formula (IX). The CLogP value of the compound represented by Formula (IX) is preferably −0.4 or greater and more preferably −0.2 or greater. The upper limit thereof is preferably 2 or less and more preferably 1.5 or less.

Clog P

An octanol/water partition coefficient (log P value) can be normally measured using a flask immersion method described in JIS Japanese Industrial Standards Z7260-107 (2000). Further, the octanol/water partition coefficient (log P value) can be estimated by a calculating chemical method or an empirical method instead of actual measurement. It is known that a Crippen's fragmentation method (J. Chem. Inf. Comput. Sci., 27, 21 (1987)), a Viswanadhan's fragmentation method (J. Chem. Inf. Comput. Sci., 29, 163 (1989)), Broto's fragmentation method (Eur. J. Med. Chem.-Chim. Theor., 19, 71 (1984)), or the like is used as the calculation method thereof. In the present invention, the Crippen's fragmentation method (J. Chem. Inf. Comput. Sci., 27, 21 (1987)) is used.

The Clog P value is obtained by calculating a common logarithm log P of a partition coefficient P to 1-octanol and water. A known method or known software can be used for calculating the Clog P value, but, unless otherwise noted, a system from Daylight Chemical Information System, Inc. and a Clog P program incorporated in PCModels are used in the present invention.

Formula (X): R^{A3} has the same definition as that for R^{N}. R^{A1} and R^{A2} each independently represent a hydrogen atom, an alkyl group (the number of carbon atoms is preferably in the range of 1 to 12, more preferably in the range of 1 to 6, and particularly preferably in the range of 1 to 3), an alkenyl group (the number of carbon atoms is preferably in the range of 2 to 12 and more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), an aralkyl group (the number of carbon atoms is preferably in the range of 7 to 23 and more preferably in the range of 7 to 15), a sulfanyl group, a hydroxy group, or an amino group. In this case, it is preferable that at least one of R^{A1} and R^{A2} is a sulfanyl group, a hydroxy group, or an amino group (the number of carbon atoms is preferably in the range of 0 to 6 and more preferably in the range of 0 to 3).

Formula (XI): Y⁷ and Y⁸ each independently represent an oxygen atom, a sulfur atom, an imino group (NR^{N}), or a carbonyl group. R^{B1} represents a substituent (hereinafter, a substituent T is preferable). nB represents an integer of 0 to 8. However, any one of Y⁷ and Y⁸ may be a methylene group (CR^{C}₂).

Formula (XII): Y⁹ and Y¹⁰ each independently represent an oxygen atom, a sulfur atom, a methylene group (CR^{C}₂), an imino group (NR^{N}), or a carbonyl group. The positions of Y⁹ and Y¹⁰ may be different in a 6-membered ring.

X⁵ and X⁶ each independently represent a sulfur atom or an oxygen atom. The broken line means that the bond may be a single bond or a double bond. R^{C1} represents a substituent (hereinafter, a substituent T is preferable). nC represents an integer of 0 to 2.

When a plurality of R^{C1}'s are present, the plurality of R^{C1}'s may be the same as or different from each other and may be bonded or condensed to each other to form a ring.

Formula (XIII): X³ represents an oxygen atom, a sulfur atom, or an imino group (NR^{M}). R^{M} represents a hydrogen atom or an alkyl group having 1 to 24 carbon atoms, and is preferably an alkyl group having 2 to 20 carbon atoms, more preferably an alkyl group having 4 to 16 carbon atoms, and particularly preferably an alkyl group having 6 to 12 carbon atoms.

X⁵ represents an oxygen atom, a sulfur atom, an imino group (NR^{M}), or a methylene group (CR^{C}₂).

R^{D1} represents a substituent and is preferably a substituent T described below. Among examples of R^{D1}, R^{D1} is preferably an alkyl group having 1 to 24 carbon atoms and more preferably an alkyl group having 1 to 12 carbon atoms.

nD represents an integer of 0 to 6 and is preferably an integer of 0 to 2 and particularly preferably 1.

It is preferable that X³—CO—X⁵ in the formula is NR^{N}—CO—CR^{C}₂ or O—CO—OO—CO—CR^{C}₂.

Examples of the phosphoric acid compound include phosphoric acid, polyphosphoric acid, metaphosphoric acid, ultraphosphoric acid, phosphorous acid, phosphorus pentoxide, hypophosphorous acid, and salts thereof. In the case of polyphosphoric acid, the number of repeating structures is preferably in the range of 2 to 5. In the case of metaphosphoric acid, the number of repeating structures is preferably in the range of 3 to 5.

Examples of the phosphonic acid compound include alkylphosphonic acid (the number of carbon atoms is preferably in the range of 1 to 30, more preferably in the range of 3 to 24, and particularly preferably in the range of 4 to 18), arylphosphonic acid (the number of carbon atoms is preferably in the range of 6 to 22, more preferably in the range of 6 to 14, and particularly preferably in the range of 6 to 10), and aralkylphosphonic acid (the number of carbon atoms is preferably in the range of 7 to 23, more preferably in the range of 7 to 15, and particularly preferably in the range of 7 to 11). Alternatively, the phosphonic acid compound may be polyvinyl phosphonic acid. The molecular weight thereof may be appropriately selected, but is preferably in the range of 3,000 to 50,000.

Examples of the boron-containing acid compound include boric acid, boronic acid, and tetrafluoroboric acid. As the boronic acid, boronic acid having 1 to 24 carbon atoms is preferable and boronic acid having 1 to 12 carbon atoms is more preferable. Specifically, phenylboronic acid or methylboronic acid is exemplified.

When these acids form salts, examples of the counterions thereof, which are not particularly limited, include an alkali metal cation and an organic cation.

It is particularly preferable that the specific organic additive is formed of compounds included in a first group or a second group of Examples described below. Among the specific organic additives, the concentration of a compound belonging to the first group, in the etching liquid, is preferably 50% by mass or greater, more preferably 55% by mass or greater, still more preferably 60% by mass or greater, and particularly preferably 70% by mass or greater. The upper limit thereof is preferably 99% by mass or less, more preferably 95% by mass or less, and particularly preferably 90% by mass or less.

Among the specific organic additives, the concentration of a compound belonging to the second group, in the etching liquid, is preferably 0.005% by mass or greater, more preferably 0.01% by mass or greater, still more preferably 0.03% by mass or greater, and particularly preferably 0.05% by mass or greater. The upper limit thereof is preferably 10% by mass or less, more preferably 7% by mass or less, and particularly preferably 5% by mass or less.

It is preferable that the addition amount thereof is defined because damage of the germanium-containing layer (first layer) or the germanium silicide layer (third layer) can be effectively suppressed while excellent etching properties of the metal layer (second layer) are maintained.

Here, the reason why the preferred ranges of the concentration of additives of the first group and the second group are different from each other is considered as follows from a difference of the action mechanism. That is, dissolution of the first layer containing germanium (Ge) is made in three different routes:

(1) Oxidation of the first layer containing germanium (Ge);

(2) Complexation of the first layer containing oxidized germanium (Ge); and

(3) Elution of the first layer containing complexed germanium (Ge). Here, it is considered that the first group is operated as a prime solvent in a treatment solution and shows an inhibitory action on the route (3). It is understood that compounds generated through complexation with acid compounds have low solubility in a compound solvent of the first group and elution is unlikely to proceed. As a result, it is considered that elution of Ge is unlikely to proceed (the first layer containing germanium (Ge) is not eluted and, accordingly, not damaged). That is, since the first group is operated as a prime solvent in a liquid and exhibits the effects, the concentration thereof is preferably high as described above. In this case, in a case where the first group is excessively added, the elution of the second layer is inhibited and thus it is desirable that the concentration thereof is not excessive.

Meanwhile, it is considered that an additive belonging to the second group shows an action of inhibiting damage of Ge in the routes of (1), (2), or both of (1) and (2) described above. That is, it is understood that these compound groups are adsorbed on the surface of the first layer containing germanium (Ge) and form a protective layer on the surface thereof. It is considered that progress of the elution can be prevented because oxidation or complexation of the first layer containing germanium (Ge) is suppressed by the protective layer (the first layer containing germanium (Ge) is not eluted and, accordingly, not damaged). From a viewpoint of such an action mechanism, the addition amount thereof is preferably sufficient enough to protect the first layer containing germanium (Ge) and also preferably relatively small as described above. In this case, in regard to the addition amount thereof, since elution of the second layer is inhibited when the addition amount thereof is excessive, the concentration thereof is not excessively high, which is desirable.

In regard to the respective formulae described above and distinguishing the first group from the second group, it is preferable that compounds related to Formula (V) or part of Formula (V) and Formulae (VI), (IIX), (IX), and (XI) belong to the first group and compounds related to other formulae, Formula (V), or part of Formula (V), a phosphoric acid compound, a boron-containing acid compound, and a phosphonic acid compound belong to the second group.

In the present invention, the specific organic additive may be used alone or in combination of two or more kinds thereof. The expression of the “combination of two or more kinds” includes not only a case in which a compound corresponding to Formula (I) and a compound corresponding to Formula (II) are combined to each other but also a case in which two compounds corresponding to Formula (I) are combined with each other (for example, two compounds in which at least one of atomic groups R¹¹, R¹², and X¹ is different from each other even though both of the compounds are represented by Formula (I)). In the case where two or more kinds are combined with each other, the combination ratio thereof is not particularly limited, but the total amount used thereof is preferably in the above-described range of concentration as the sum of two or more kinds of specific organic additives.

When the embodiment of the present invention is described through classification, the embodiment is largely divided into the following removal aspects (I) and (II). From a viewpoint of removal components of the second layer, the embodiment can be divided into a case in which the above-described acid component is used alone (removal aspect (I)) and a case in which the above-described acid component and an oxidant are used in combination (removal aspect (II)).

Preferred examples of the acid compound of the removal aspect (I) include hydrofluoric acid or hydrochloric acid and hydrofluoric acid is more preferable.

Preferred examples of the acid compound of the removal aspect (II) include hydrofluoric acid or hydrochloric acid and hydrochloric acid is more preferable. That is, a combination of hydrochloric acid and an oxidant is preferable.

An organic additive selected from a phosphoric acid compound, a boron-containing acid compound, or a phosphonic acid compound represented by Formulae (V) to (IX), (XI), and (XIII) is used in the case of the removal aspect (I) and an organic additive selected from Formula (I) to (VII), (X), and (XIII) is used in the case of the removal aspect (II).

It is preferable to suitably select an organic additive when further selective etching with aluminum becomes necessary. Specifically, it is preferable to use at least an organic additive in the first group and more preferable to use a combination of an organic additive in the first group and an organic additive of the second group. Further, it is preferable to use an organic additive in the first group, an organic additive in the second group, and a sulfonic acid compound (a compound in which Z of Formula (V) represents sulfonic acid) (organic additive in the third group). The preferred ranges of the respective blending amounts are the same as those described above, and a relatively large amount of the organic additive in the first group is preferably used as described above. Meanwhile, a relatively small amount of the organic additive in the second group is preferably used as described above. The concentration of the sulfonic acid compound (third group) in the etching liquid is preferably 0.5% by mass or greater, more preferably 1% by mass or greater, still more preferably 3% by mass or greater, and particularly preferably 5% by mass or greater. The upper limit thereof is preferably 50% by mass or less, 40% by mass or less, and particularly preferably 30% by mass or less.

Further, the organic additive may be independently added to the inside of the system as a compound different from halogen acid or a salt thereof. As the example of the organic ammonium, the organic additive may be supplied as a salt of halogen acid. In other words, when halogen ions and ions of an organic additive are detected in the system, the detected ions are included in the range of the technique of the present invention.

The display of compounds in the present specification (for example, when a compound is referred to by being added at the end of the compound) is used to include the compound itself, a salt thereof, and an ion thereof. Further, the display thereof includes a derivative which is partially changed by being esterified or introducing a substituent within a range in which desired effects can be exhibited.

A substituent (the same applies to a linking group) in which substitution or unsubstitution is not specified in the present specification means that an arbitrary substituent may be included in the group. The same applies to a compound in which substitution or unsubstitution is not specified. As a preferred substituent, the substituent T described below is exemplified.

Examples of the substituent T include the followings.

An alkyl group (preferably an alkyl group having 1 to 20 carbon atoms such as methyl, ethyl, isopropyl, t-butyl, pentyl, heptyl, decyl, dodecyl, 1-ethylpentyl, benzyl, 2-ethoxyethyl, or 1-carboxymethyl), an alkenyl group (preferably, an alkenyl group having 2 to 20 carbon atoms such as vinyl, allyl, or oleyl), an alkynyl group (preferably an alkynyl group having 2 to 20 carbon atoms such as ethynyl, butadiynyl, or phenylethynyl), a cycloalkyl group (preferably a cycloalkyl group having 3 to 20 carbon atoms such as cyclopropyl, cyclopentyl, cyclohexyl, or 4-methylcyclohexyl), an aryl group (preferably an aryl group having 6 to 26 carbon atoms such as phenyl, 1-naphthyl, 4-methoxyphenyl, 2-chlorophenyl, or 3-methylphenyl), a heterocyclic group (preferably a heterocyclic group having 2 to 20 carbon atoms or preferably a heterocycle of a 5- or 6-membered ring having at least one of an oxygen atom, a sulfur atom and a nitrogen atom such as 2-pyridyl, 4-pyridyl, 2-imidazolyl, 2-benzimidazolyl, 2-thiazolyl, or 2-oxazolyl), an alkoxy group (preferably an alkoxy group having 1 to 20 carbon atoms such as methoxy, ethoxy, isopropyloxy, or benzyloxy), an aryloxy group (preferably an aryloxy group having 6 to 26 carbon atoms such as phenoxy, 1-naphthyloxy, 3-methylphenoxy, or 4-methoxyphenoxy), an alkoxycarbonyl group (preferably an alkoxycarbonyl group having 2 to 20 carbon atoms such as ethoxycarbonyl or 2-ethylhexyloxycarbonyl), an amino group (preferably an amino group having 0 to 20 carbon atoms, an alkylamino group having 0 to 20 carbon atoms, or an arylamino group having 0 to 20 carbon atoms such as amino, N,N-dimethylamino, N,N-diethylamino, N-ethylamino, or anilino), a sulfamoyl group (preferably a sulfamoyl group having 0 to 20 carbon atoms such as N,N-dimethylsulfamoyl or N-phenylsulfamoyl), an acyl group (preferably an acyl group having 1 to 20 carbon atoms such as acetyl, propionyl, butyryl, or benzoyl), an acyloxy group (preferably an acyloxy group having 1 to 20 carbon atoms such as acetyloxy or benzoyloxy), a carbamoyl group (preferably a carbamoyl group having 1 to 20 carbon atoms such as N,N-dimethylcarbamoyl or N-phenylcarbamoyl), an acylamino group (preferably an acylamino group having 1 to 20 carbon atoms such as acetylamino or benzoylamino), a sulfonamide group (preferably a sulfamoyl group having 0 to 20 carbon atoms such as methane sulfonamide, benzene sulfonamide, N-methylmethanesulfonamide, or N-ethylbenzenesulfonamide), an alkylthio group (preferably an alkylthio group having 1 to 20 carbon atoms such as methylthio, ethylthio, isopropylthio, or benzylthio), an arylthio group (preferably an arylthio group having 6 to 26 carbon atoms such as phenylthio, 1-naphthylthio, 3-methylphenylthio, or 4-methoxyphenylthio), alkyl or an arylsulfonyl group (preferably alkyl or an arylsulfonyl group having 1 to 20 carbon atoms such as methylsulfonyl, ethylsulfonyl, or benzenesulfonyl), a hydroxy group, a sulfanyl group, a cyano group, and a halogen atom (such as a fluorine atom, a chlorine atom, a bromine atom, or an iodine atom). Among these, an alkyl group, an alkenyl group, an aryl group, a heterocyclic group, an alkoxy group, an aryloxy group, an alkoxycarbonyl group, an amino group, an acylamino group, a hydroxygroup or a halogen atom is more preferable. Further, an alkyl group, an alkenyl group, a heterocyclic group, an alkoxy group, an alkoxycarbonyl group, an amino group, an acylamino group, or a hydroxy group is particularly preferable.

Moreover, respective groups exemplified in these substituents T may be further substituted with the above-described substituents T.

When a compound or a substituent and a linking group include an alkyl group/an alkylene group, an alkenyl group/an alkenylene group, or an alkynyl group/an alkynylene group, these may be cyclic, chain-like, linear, or branched and may be substituted or unsubstituted as described above. At this time, an alkyl group/an alkylene group, an alkenyl group/an alkenylene group, and an alkynyl group/an alkynylene group may form a ring structure along with a group (such as O, S, CO, or NR^{N}) including a heteroatom. Moreover, when an aryl group and a heterocyclic group are included, these may be a single ring or a condensed ring and may be substituted or unsubstituted.

In the present specification, respective technical matters such as selection of substituents or linking groups of compounds, the temperature, and the thickness can be combined with each other even when the lists thereof are respectively and independently described.

(Aqueous Medium)

In the embodiment, it is preferable that water (aqueous medium) is used as a medium of the etching liquid of the present invention. An aqueous medium containing dissolved components within a range not damaging the effects of the present invention may be used as water (aqueous medium) or water may contain a small amount of inevitable mixing components. Among these, water subjected to a purification treatment such as distilled water, ion-exchange water, or ultrapure water is preferable and ultrapure water to be used for manufacturing a semiconductor is particularly preferable.

(pH)

In the present invention, the pH (25° C.) of the etching liquid is preferably 5 or less, more preferably 4 or less, and particularly preferably 2 or less. When defined according to the above-described classification, the pH of the first group is preferably in the range of 1 to 6 and more preferably in the range of 2 to 5. The pH of the second group is preferably in the range of −1 to 4 and more preferably in the range of 0 to 3. It is preferable that the pH is set to be in the above-described range because the etching rate of the second layer is sufficiently secured and damage of the first layer or the third layer is effectively prevented. Further, since it is preferable that a compound in the first group is added as a prime solvent described above, the pH thereof tends to be decreased compared to a case where only water is used as a solvent. Meanwhile, since the amount of a compound in the second group to be added is small compared to that of a compound in the first group, the pH thereof becomes more acidic.

### ANOTHER EMBODIMENT

Another preferred embodiment of an etching liquid of the present invention will be described. The etching liquid of the present embodiment contains fluorine ions and an acid assistant. Hereinafter, respective components will be described.

(Fluorine Ion)

The etching liquid of the present embodiment contains fluorine ions. The fluorine ions in the etching liquid become a ligand (complexing agent) of a metal (Ti or the like) of a second layer and play a role of promoting dissolution.

The concentration of the fluorine ions in the etching liquid is preferably 0.1% by mass or greater, more preferably 0.5% by mass or greater, and particularly preferably 1% by mass or greater. The upper limit thereof is preferably 20% by mass or less, more preferably 10% by mass or less, still more preferably 5% by mass or less, and particularly preferably 2% by mass or less. When fluorine ions at the above-described concentration are used, excellent etching of a metal layer is realized and a silicide layer can be effectively protected.

Further, when the blending amount is confirmed, the amount of fluorine ions may be specified by quantifying the amount of fluorine compound (salt) at the time of manufacture.

As a supply source of fluorine ions, a fluorine compound such as HF is exemplified.

(Acid Assistant)

It is preferable that the etching liquid of the present embodiment contains an acid whose pKa is 4 or less. The pKa thereof is preferably 3 or less, more preferably 2 or less, still more preferably 1.5 or less, even still more preferably 1 or less, and particularly preferably 0.5 or less. The lower limit of the pKa is substantively −20 or greater. The acid assistant in the etching liquid plays a role of accelerating oxidation of a metal (Ti or the like) of the second layer even in formulation of the water content being small. From this viewpoint, when the pKa exceeds the above-described range, dissolution of a (unoxidized) metal such as Ti does not proceed in some cases.

Preferred examples of the acid assistant include HBF₄, HBr, HCl, HI, H₂SO₄, F₃CCOOH, Cl₃CCOOH, the phosphoric acid compound, the boron-containing acid compound, and the phosphonic acid compound. Among these, an inorganic acid is preferable and an inorganic acid containing a halogen atom is more preferable. Alternatively, the phosphoric acid compound, the boron-containing acid compound, and the phosphonic acid compound are preferable. The reason why the acid assistant of the present embodiment exhibits effects is not clear, but it is understood that an anion of the acid assistant exhibits unique effects because of the relationship of etching with time dependence described below.

The pKa is one of indices used for quantitatively showing the acid strength and has the same definition as that of an acidity constant. In consideration of a dissociation reaction of hydrogen ions being released from an acid, an equilibrium constant Ka thereof is shown by a negative common logarithm pKa thereof. The acid strength becomes higher as the pKa thereof becomes smaller. For example, a value calculated using ACD/Labs (manufactured by Advanced Chemistry Development, Inc.) can be used. Calculation examples of representative substituents are described below. When the acid assistant has a multi-stage dissociation constant, an evaluation is made using the smallest dissociation constant.

HBF₄: −0.4

HBr: −9.0

HCl: −7.0

MSA: −1.8 (methanesulfonic acid)

TSA: −2.8 (p-toluenesulfonic acid)

The concentration of the acid assistant in the etching liquid is preferably 0.1% by mass or greater, more preferably 0.5% by mass or greater, and particularly preferably 1% by mass or greater. The upper limit thereof is preferably 20% by mass or less, more preferably 10% by mass or less, still more preferably 5% by mass or less, and particularly preferably 3% by mass or less. The concentration thereof is preferably 10 parts by mass or greater, more preferably 30 parts by mass or greater, and particularly preferably 50 parts by mass based on 100 parts by mass of hydrofluoric acid. The upper limit thereof is preferably 1000 parts by mass or less, more preferably 600 parts by mass or less, and particularly preferably 200 parts by mass or less.

It is preferable that the concentration of the acid assistant is set to be in the above-described range because excellent etching properties of a metal layer (second layer) are maintained and damage of a silicon- or germanium-containing layer (first layer) or a silicide layer (third layer) can be effectively suppressed. Further, in regard to identification of components of the etching liquid, the components thereof are not necessarily confirmed as hydrobromic acid and the presence and the amount of ions may be determined by identifying ions in an aqueous solution. In addition, the acid assistant may be used alone or in combination of two or more kinds thereof.

Moreover, a carboxylic acid compound having 4 or more carbon atoms and oxalic acid are set to be not included in the acid assistant.

(Organic Solvent)

The etching liquid of the present embodiment may contain an organic solvent. Among organic solvents, a protic polar organic solvent is preferable. Preferred examples of the protic polar organic solvent include an alcohol compound (including a polyol compound), an ether compound, and a carboxylic acid compound. The organic solvent in the etching liquid plays a role of decreasing the dissolution rate of a metal or an insulating film which is required to be selectively treated by relatively reducing the water content in a liquid chemical.

In the organic solvent, for example, the δh (hydrogen binding energy) of a Hansen parameter is preferably 5 or greater and particularly preferably 10 or greater. The upper limit of the δh (hydrogen binding energy) is preferably 30 or less.

The viscosity thereof is preferably 40 mPa·s (20° C.) or less, more preferably 35 mPa·s or less, and particularly preferably 10 mPa·s or less. The lower limit thereof is substantively 0.5 mPa·s or greater.

Alcohol Compound

An alcohol compound includes carbons and hydrogens and broadly contains compounds having one or more hydroxyl groups. Here, even in a case of an ether compound, a compound having a hydroxyl group is set to be an alcohol compound. The number of carbon atoms of the alcohol compound is preferably 1 or greater, more preferably 2 or greater, still more preferably 3 or greater, even still more preferably 4 or greater, even still more preferably 5 or greater, and particularly preferably 6 or greater. The upper limit of the number of carbon atoms is preferably 24 or less, more preferably 12 or less, and particularly preferably 8 or less.

Examples thereof include an ether group-non-containing alcohol compound such as methyl alcohol, ethyl alcohol, 1-propyl alcohol, 2-propyl alcohol, 2-butanol, ethylene glycol, propylene glycol, glycerin, hexylene glycol [HG], 1,6-hexanediol, cyclohexanediol, sorbitol, xylitol, 2-methyl-2,4-pentanediol, 1,3-butanediol, 1,4-butanediol[14BD], 3-methyl-1-butanol [3M1B], methylpentanediol, cyclohexanol, ethylhexanol, benzylalcohol, or phenylethanol; and an ether group-containing alcohol compound including alkylene glycol alkyl ether (ethylene glycol monomethyl ether, ethylene glycol monobutyl ether, dipropylene glycol, propylene glycol monomethyl ether, diethylene glycol monomethyl ether, triethylene glycol, polyethylene glycol, propylene glycol monoethyl ether, dipropylene glycol monomethyl ether, tripropylene glycol monomethyl ether, diethylene glycol monoethyl ether, diethylene glycol monobutyl ether [DEGBE]), phenoxy ethanol, and methoxy methyl butanol.

It is preferable that the alcohol compound is a compound represented by the following Formula (O-1).

R⁰¹—(—O—R⁰²—)ₙ—OH (O-1)

R⁰¹

R⁰¹ represents a hydrogen atom, an alkyl group having 1 to 12 carbon atoms (preferably 1 to 6, more preferably 1 to 4, and still more preferably 1 to 3), an aryl group having 6 to 14 carbon atoms (preferably 6 to 10), or an aralkyl group having 7 to 15 carbon atoms (preferably 7 to 11).

R⁰²

R⁰² represents a linear or branched alkylene chain having 1 to 12 carbon atoms. When a plurality of R⁰²'s are present, R⁰²'s may be different from each other. The number of carbon atoms of R⁰² is preferably in the range of 2 to 10 and more preferably in the range of 2 to 6.

n

n represents an integer of 0 to 12, is preferably an integer of 1 to 12, and preferably an integer of 1 to 6. When n is 2 or greater, the plurality of R⁰²'s may be different from each other. In this case, when n is 0, R⁰¹ does not represent a hydrogen atom.

It is preferable that the alcohol compound is a compound represented by the following Formula (O-2) or (O-3).

R⁰³-L⁰¹-R⁰⁴—OH (O-2)

R⁰³-(L⁰¹-R⁰⁴)n-OH (O-3)

It is preferable that R⁰³ represents a cyclic structure group which may have a substituent. The cyclic structure group may be an aromatic ring, a heteroaromatic ring, an aliphatic ring, or a heteroaliphatic ring. As the aromatic ring, an aryl group having 6 to 14 carbon atoms is exemplified (an aryl group having 6 to 10 carbon atoms is preferable and a phenyl group is more preferable). As the aliphatic ring, a cyclic alkyl group having 3 to 14 carbon atoms is exemplified (a cyclic alkyl group having 3 to 10 carbon atoms is preferable and a cyclohexyl group is more preferable). As a heterocycle, a heterocyclic group having 2 to 20 carbon atoms is exemplified and a heterocyclic group of a 5- or 6-membered ring having at least one of an oxygen atom, a sulfur atom, and a nitrogen atom is preferable. Examples thereof include 2-pyridyl, 4-pyridyl, 2-imidazolyl, 2-benzimidazolyl, 2-thiazolyl, and 2-oxazolyl. The cyclic structure group may suitably include an arbitrary substituent.

L⁰¹ represents a single bond, O, CO, NR^{N}, S, or a combination of these. Among these, a single bond, CO, or O is preferable and a single bond or O is more preferable. R^{N} has the same definition as that described above.

R⁰⁴ represents an alkylene group (the number of carbon atoms is preferably in the range of 1 to 12, more preferably in the range of 1 to 6, and particularly preferably in the range of 1 to 3), an arylene group (the number of carbon atoms is preferably in the range of 6 to 14 and more preferably in the range of 6 to 10), or an aralkylene group (the number of carbon atoms is preferably in the range of 7 to 15 and more preferably in the range of 7 to 11).

n has the same definition as that described above.

It is preferable that the ether compound is a compound represented by the following Formula (E-1).

R^{E1}—(—O—R^{E2})ₘ—R^{E3} (E-1)

R^{E1}

R^{E1} represents an alkyl group having 1 to 12 carbon atoms (preferably 1 to 6, more preferably 1 to 4, and still more preferably 1 to 3), an aryl group having 6 to 14 carbon atoms (preferably 6 to 10), or an aralkyl group having 7 to 15 carbon atoms (preferably 7 to 11).

R^{E2} has the same definition as that for R⁰².

R^{E3} has the same definition as that for R⁰¹.

m represents an integer of 1 to 12 and more preferably an integer of 1 to 6. When m represents an integer of 2 or greater, a plurality of R^{E2}'s may be different from each other.

The concentration of the organic solvent in the etching liquid is preferably 50% by mass or greater, more preferably 60% by mass or greater, and particularly preferably 70% by mass or greater. The upper limit thereof is preferably 98% by mass or less, more preferably 95% by mass or less, and particularly preferably 90% by mass or less. It is preferable that the concentration of the organic solvent is in the above-described range because the concentration of water is decreased and excellent etching properties of the metal layer (second layer) can be maintained by being combined with the acid assistant while damage of the germanium silicide layer or another metal layer which needs to be protected is effectively suppressed.

Further, in the present embodiment, the organic solvent may be used alone or in combination of two or more kinds thereof. In the case where a combination of two or more kinds thereof is used, the combination ratio thereof is not particularly limited, but the total amount used thereof is preferably in the above-described range of concentration as the sum of two or more kinds thereof.

(Carboxylic Acid Compound)

The etching liquid of the present embodiment may include a carboxylic acid compound having 4 or more carbon atoms. It is preferable that the carboxylic acid compound is an organic compound which has 4 or more carbon atoms and includes a carboxylic acid. The carboxylic acid compound may include a carboxylic acid in a molecule and may be a compound with a low molecular weight or a high molecular compound. When the carboxylic acid compound is a low molecular compound, the number of carbon atoms is preferably in the range of 4 to 48, more preferably in the range of 4 to 36, and particularly preferably in the range of 6 to 24. The carboxylic acid compound plays a role of accelerating dissolution of an oxide (titanium oxide or the like) of a metal of the second layer in the etching liquid as a complexing agent.

It is preferable that the carboxylic acid compound is a compound represented by R¹—COOH. R¹ represents an alkyl group (the number of carbon atoms is preferably in the range of 1 to 48, more preferably in the range of 4 to 48, still more preferably in the range of 4 to 36, and particularly preferably in the range of 6 to 24), an alkenyl group (the number of carbon atoms is preferably in the range of 2 to 48, more preferably in the range of 4 to 48, still more preferably in the range of 4 to 36, and even still more preferably in the range of 6 to 24), an alkynyl group (the number of carbon atoms is preferably in the range of 2 to 48, more preferably in the range of 4 to 48, still more preferably in the range of 4 to 36, and even still more preferably in the range of 6 to 24), an aryl group (the number of carbon atoms is preferably in the range of 6 to 22 and more preferably in the range of 6 to 14), or an aralkyl group (the number of carbon atoms is preferably in the range of 7 to 23 and more preferably in the range of 7 to 15). When R¹ represents an aryl group, the aryl group may be substituted with an alkyl group having 1 to 20 carbon atoms, an alkenyl group having 2 to 20 carbon atoms, or an alkynyl group having 2 to 20 carbon atoms. When R¹ represents an alkyl group, the alkyl group may have the following structure.

*—R²—(R³—Y)ₙ—R⁴

R² represents a single bond, an alkylene group (the number of carbon atoms is preferably in the range of 1 to 12, more preferably in the range of 1 to 6, and particularly preferably in the range of 1 to 3), an alkynylene group (the number of carbon atoms is preferably in the range of 2 to 12 and more preferably in the range of 2 to 6), an alkenylene group (the number of carbon atoms is preferably in the range of 2 to 12 and more preferably in the range of 2 to 6), an arylene group (the number of carbon atoms is preferably in the range of 6 to 22 and more preferably in the range of 6 to 14), or an aralkylene group (the number of carbon atoms is preferably in the range of 7 to 23 and more preferably in the range of 7 to 15).

R³ has the same definition as that for a linking group of R².

Y represents an oxygen atom (O), a sulfur atom (S), a carbonyl group (CO), or an imino group (NR^{N}). R⁴ represents an alkyl group (the number of carbon atoms is preferably in the range of 1 to 12, more preferably in the range of 1 to 6, and still more preferably in the range of 2 to 6), an alkynyl group (the number of carbon atoms is preferably in the range of 2 to 12 and more preferably in the range of 2 to 6), an aryl group (the number of carbon atoms is preferably in the range of 6 to 22 and more preferably in the range of 6 to 14), or an aralkyl group (the number of carbon atoms is preferably in the range of 7 to 23 and more preferably in the range of 7 to 15).

n represents an integer of 0 to 8.

R¹ may further include a substituent. Among substituents, a sulfanyl group (SH), a hydroxyl group (OH), or an amino group (NR^{N}₂) is preferable.

The concentration of the carboxylic acid compound in the etching liquid is preferably 0.01% by mass or greater, more preferably 0.05% by mass or greater, and particularly preferably 0.1% by mass or greater. The upper limit thereof is preferably 10% by mass or less, more preferably 3% by mass or less, and particularly preferably 1% by mass or less. The concentration thereof is preferably 1 part by mass or greater, more preferably 3 parts by mass or greater, and particularly preferably 5 parts by mass or greater based on 100 parts by mass of hydrofluoric acid. The upper limit thereof is preferably 50 parts by mass or less, more preferably 30 parts by mass or less, and particularly preferably 20 parts by mass or less.

(Oxalic Acid)

Among the above-described carboxylic acid compounds, oxalic acid may be contained in the etching liquid as a different kind of additive. The oxalic acid plays a role as a complexing agent in the etching liquid.

The concentration of the oxalic acid in the etching liquid is preferably 0.1% by mass or greater, more preferably 0.5% by mass or greater, and particularly preferably 1% by mass or greater. The upper limit thereof is preferably 20% by mass or less, more preferably 10% by mass or less, still more preferably 5% by mass or less, and particularly preferably 3% by mass or less. The concentration thereof is preferably 10 parts by mass or greater, more preferably 30 parts by mass or greater, and particularly preferably 50 parts by mass or greater based on 100 parts by mass of hydrofluoric acid. The upper limit thereof is preferably 1000 parts by mass or less, more preferably 600 parts by mass or less, and particularly preferably 200 parts by mass or less.

(Saccharides)

The etching liquid of the present embodiment may contain saccharides. An acid whose pKa is 2 or greater plays a role of preventing corrosion of the silicide layer in the etching liquid.

The saccharides, which are not particularly limited, may be formed of a monosaccharide or a polysaccharide, but a monosaccharide is preferable. Examples of the monosaccharide broadly include hexose and pentose. Examples of the structure thereof include ketose, aldose, pyranose, and furanose. Examples of hexose include allose, altrose, glucose, mannose, gulose, idose, galactose, talose, psicose, fructose, sorbose, and tagatose. Examples of pentose include ribose, arabinose, xylose, lyxose, ribulose, and xylulose. Examples of furanose include thorofuranose, threofuranose, ribofuranose, arabinofuranose, xylofuranose, and lyxofuranose. Examples of pyranose include ribopyranose, arabinopyranose, xylopyranose, lyxopyranose, allopyranose, altropyranose, glucopyranose, mannopyranose, gulopyranose, idopyranose, galactopyranose, and taropyranose.

The concentration of the saccharides in the etching liquid is preferably 0.01% by mass or greater, more preferably 0.05% by mass or greater, and particularly preferably 0.1% by mass or greater. The upper limit thereof is preferably 10% by mass or less, more preferably 3% by mass or less, and particularly preferably 1% by mass or less. The concentration thereof is preferably 1 part by mass or greater, more preferably 3 parts by mass or greater, and particularly preferably 5 parts by mass or greater based on 100 parts by mass of hydrofluoric acid. The upper limit thereof is preferably 50 parts by mass or less, more preferably 30 parts by mass or less, and particularly preferably 20 parts by mass or less.

(Water)

It is preferable that the etching liquid for a semiconductor process of the present embodiment contains water (aqueous medium). An aqueous medium containing dissolved components within a range not damaging the effects of the present embodiment may be used as water (aqueous medium) or water may contain a small amount of inevitable mixing components. Among these, water subjected to a purification treatment such as distilled water, ion-exchange water, or ultrapure water is preferable and ultrapure water to be used for manufacturing a semiconductor is particularly preferable. The concentration of water, which is not particularly limited, is preferably 0.1% by mass or greater, more preferably 1% by mass or greater, and particularly preferably 5% by mass or greater. The upper limit thereof is preferably 50% by mass or less, more preferably 40% by mass or less, still more preferably 25% by mass or less, still more preferably 20% by mass or less, still more preferably 15% by mass or less, and particularly preferably 10% by mass or less.

In the present embodiment, it is preferable that the concentration of water of the etching liquid is regulated to be in a predetermined range. In a state in which water is not present, the etching action of the metal layer is not sufficiently shown in some cases. From this viewpoint, preferably, water is used, but damage of the silicide layer or another metal layer which needs to be protected is suppressed by setting the amount of water to be small. Moreover, in the present embodiment, the etching properties of the metal layer are improved by supplying protons into the system using an acid assistant. At this time, etching with higher selectivity becomes possible by selecting an acid assistant with less damage to the silicide layer.

The reason why excellent etching of the metal layer is achieved after an unconventional germanium silicide layer is protected is assumed as follows. First, in dissolution of a second metal layer such as titanium, it is considered that water plays a role of oxidizing the second metal and also plays a role of dissolving a complex formed by HF. In the present embodiment, the above-described actions are more effectively realized by (1) selecting a proton supply source for oxidizing Ti or the like and (2) selecting an organic solvent that promotes formation of solvation of a complex such as Ti, as means for not dropping the dissolution rate of Ti or the like even when the water content is reduced. Particularly, in regard to (1), the time dependence of the Ti dissolution rate may vary due to solubility of salts formed by an anion portion of a strong acid and a metal. For this reason, it is considered that damage of the silicide layer can be suppressed by selecting a H⁺ source with less time dependence even when the time for treatment is prolonged.

(Specific Organic Additive)

It is preferable that the etching liquid according to the present embodiment contains a specific organic additive. As the organic additive, an additive employed in another embodiment described above can be suitably employed.

(Kit)

The etching liquid in the present invention may be used for a kit obtained by dividing the raw material of the etching liquid into plural parts. For example, an aspect in which a liquid composition containing the above-described acid compound in water as a first liquid is prepared and a liquid composition containing the above-described specific organic additive in an aqueous medium as a second liquid is prepared is exemplified. At this time, the components of another oxidant and the like can be separately contained or can be contained together in a first liquid, a second liquid, or another third liquid. The preferable aspect is a kit of the first liquid containing an acid compound and a specific organic compound and the second liquid containing an oxidant.

As the usage example, an aspect of preparing an etching liquid by mixing both of the liquids and then using the etching liquid for the etching treatment at a suitable time is preferable. In this manner, deterioration of liquid performance due to decomposition of respective components is not caused and a desired etching action can be effectively exhibited. Here, the term “suitable time” after mixing both of the liquids indicates a period during which a desired action is lost after the mixing, and, specifically, the period is preferably within 60 minutes, more preferably within 30 minutes, still more preferably within 10 minutes, and particularly preferably within 1 minute. The lower limit thereof, which is not particularly limited, is substantively 1 second or longer.

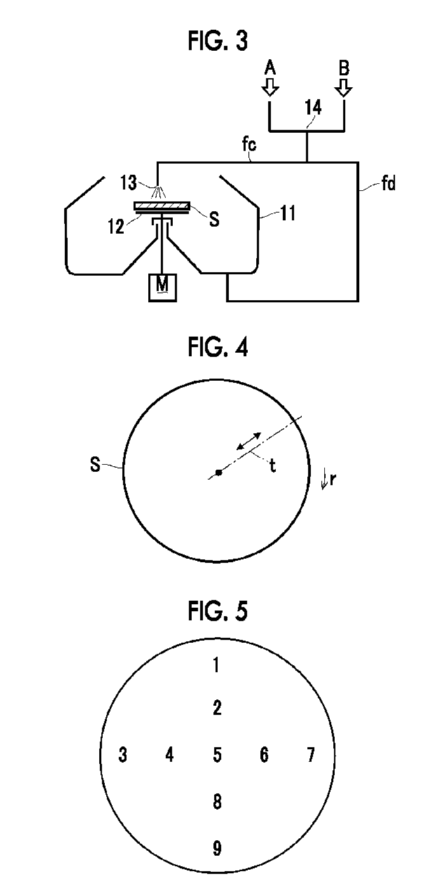

The manner of mixing the first liquid and the second liquid is not particularly limited, but the mixing is preferably performed by circulating the first liquid and the second liquid in different channels and merging both of the liquids at a junction point. Subsequently, both of the liquids are circulated through the channels, an etching liquid obtained after both of the liquids are merged is ejected or sprayed from an ejection opening, and the etching liquid is brought into contact with a semiconductor substrate. In the embodiment, it is preferable that the process from which both of the liquids are merged and mixed with each other at the junction point to which the liquid is brought into contact with the semiconductor substrate is performed at the suitable time described above. When this process is described with reference to FIG. 3, the prepared etching liquid is sprayed from an ejection opening 13 and then applied to the upper surface of a semiconductor substrate S in a treatment container (treatment tank) 11. In the embodiment shown in the same figure, two liquids of A and B are supplied to be merged with each other at a junction point 14 and then the liquids are transitioned to the ejection opening 13 through a channel fc. A channel fd indicates a returning path for reusing a liquid chemical. It is preferable that the semiconductor substrate S is on a rotary table 12 and rotates along with the rotary table by a rotation driving unit M. In addition, in the embodiment in which such a substrate rotation type device is used, the same applies to a treatment using the etching liquid which is not used for a kit.

Moreover, in the etching liquid of the present invention, it is preferable that the amount of impurities in the liquid, for example, metals, is small when the usage of the etching liquid is considered. Particularly, the ion concentration of Na, K, and Ca in the liquid is preferably in the range of 1 ppt to 1 ppm (on a mass basis). Further, in the etching liquid, the number of coarse particles having an average particle diameter of 0.5 μm or greater is preferably 100/cm³ or less and more preferably 50/cm³ or less.

(Container)

The etching liquid of the present invention fills an arbitrary container to be stored, transported, and then used as long as corrosion resistance is not a problem (regardless of the container being a kit or not). Further, a container whose cleanliness is high and in which the amount of impurities to be eluted is small is preferable for the purpose of using the container for a semiconductor. As a usable container, “Clean bottle” series (manufactured by ACELLO CORPORATION) or “Pure bottle” (manufactured by KODAMA PLASTICS Co., Ltd.) is exemplified, but the examples are not limited thereto.

[Etching Conditions]

In an etching method of the present invention, it is preferable to use a sheet type device. Specifically, a sheet type device which has a treatment tack and in which the semiconductor substrate is transported or rotated in the treatment tank, the etching liquid is provided (ejection, spray, falling, dropping, or the like) in the treatment tank, and the etching liquid is brought into contact with the semiconductor substrate is preferable.

Advantages of the sheet type device are as follows: (i) a fresh etching liquid is constantly supplied and thus reproducibility is excellent and (ii) in-plane uniformity is high. Further, a kit obtained by dividing the etching liquid into plural parts is easily used and, for example, a method of mixing the first and second liquids with each other in line and ejecting the liquid is suitably employed. At this time, a method of mixing the liquids with each other in line and ejecting the mixed solution after the temperature of both of the first liquid and the second liquid is adjusted or the temperature of one of the first liquid and the second liquid is adjusted is preferable. Between the two, adjusting the temperature of both liquids is more preferable. It is preferable that the managed control at the time of adjusting the temperature of the line is set to be in the same range as that of the treatment temperature described below.

The sheet type device is preferably provided with a nozzle in the treatment tank thereof and a method of ejecting the etching liquid to the semiconductor substrate by swinging the nozzle in the plane direction of the semiconductor substrate is preferable. In this manner, deterioration of the liquid can be prevented, which is preferable. Further, the liquid is separated into two or more liquids after the kit is prepared and thus gas or the like is unlikely to be generated, which is preferable.

In the etching liquid of the present invention, it is particularly preferable that the etching liquid contains an oxidant because the elution selection ratio of the first layer containing germanium (Ge) and the second layer is improved using a sheet type washing device. The reason therefor is not clear, but it is assumed that active species (for example, F₂ gas in HF+H₂O₂ and NOCl in HCl and HNO₃) to be purified by an oxidant and an acid component being mixed with each other are largely generated in the liquid over time in a bath/tank type washing device. In this manner, as described above, the generated active species oxidize the first layer containing germanium (Ge) and the elution thereof is excessively promoted. Meanwhile, it is considered that active species that promote oxidation of the first layer containing germanium (Ge) as described above are not practically generated because a fresh etching liquid is constantly supplied in the sheet type device and is mixed immediately before use. It is considered that the elution selection ratio of the first layer containing germanium (Ge) and the second layer is improved for this reason.

The treatment temperature of performing etching is preferably 10° C. or higher and more preferably 20° C. or higher. The upper limit thereof is preferably 80° C. or lower, more preferably 70° C. or lower, still more preferably 60° C. or lower, even still more preferably 50° C. or lower, and particularly preferably 40° C. or lower. It is preferable that the temperature is set to be higher than or equal to the lower limit because the etching rate with respect to the second layer can be sufficiently secured. It is preferable that the temperature thereof is set to be lower than or equal to the upper limit thereof because stability over time for the rate of the etching treatment can be maintained. In addition, when the etching treatment is carried out at around room temperature, this leads to a reduction of energy consumption.

In addition, the treatment temperature of etching is based on the temperature used for the substrate in a temperature measuring method shown in Examples below. However, the treatment temperature may be set by the temperature in the tank thereof in a case where the treatment temperature is managed by a storage temperature or a batch treatment and the treatment temperature may be set by the temperature in a circulation channel in a case where the treatment temperature is managed by a circulatory system.

In the treatment temperature, an extremely high temperature or an extremely low temperature is not normally preferable, and the preferable range thereof is 40° C. to 60° C. for the purpose of securing etching selectivity. However, in the present invention, as described above, it is considered that a temperature increase accelerates generation of active species excessively oxidizing the first layer containing germanium (Ge) and this leads to deterioration of the selection ratio. This mechanism becomes particularly significant in a case where an oxidant is included. From this viewpoint, a temperature range of 20° C. to 40° C. which is lower than the temperature range normally used for etching is particularly preferable.

The rate of supplying the etching liquid, which is not particularly limited, is preferably in the range of 0.05 L/min to 5 L/min and more preferably in the range of 0.1 L/min to 3 L/min. It is preferable that the rate thereof is set to be greater than or equal to the lower limit because the in-plane uniformity of etching can be more excellently secured. It is preferable that the rate thereof is set to be less than or equal to the upper limit because the performance stabilized at the time of performing a treatment continuously can be secured. The rotation of the semiconductor substrate also depends on the size thereof and the semiconductor substrate rotates preferably at 50 rpm to 1000 rpm from the same viewpoint described above.

In sheet type etching according to the preferred embodiment of the present invention, it is preferable that the semiconductor substrate is transported or rotated in a predetermined direction and an etching liquid is brought into contact with the semiconductor substrate by spraying the etching liquid to the space of the semiconductor substrate. The rate of supplying the etching liquid and the rotation rate of the substrate are the same as those described above.

In the configuration of the sheet type device according to the preferred embodiment of the present invention, it is preferable that the etching liquid is provided while the ejection opening (nozzle) is moved as illustrated in FIG. 4. Specifically, in the present embodiment, the substrate is rotated in an r direction when the etching liquid is applied to the semiconductor substrate S. Further, the ejection opening is set to move along a movement locus line t extending to the end portion from the central portion of the semiconductor substrate. In this manner, the rotation direction of the substrate and the movement direction of the ejection opening are set to be different from each other in the present embodiment and thus both directions are set to be relatively moved. As a result, the etching liquid can be evenly provided for the entire surface of the semiconductor substrate and the uniformity of etching is suitably secured.

The moving speed of the ejection opening (nozzle), which is not particularly limited, is preferably 0.1 cm/s or greater and more preferably 1 cm/s or greater. The upper limit thereof is preferably 30 cm/s or less and more preferably 15 cm/s or less. The movement locus line may be linear or curved (for example, ark-shaped). In both cases, the movement speed can be calculated from the distance of an actual locus line and the time spent for the movement thereof. The time required for etching one sheet of substrate is preferably in the range of 10 seconds to 300 seconds.

It is preferable that the metal layer is etched at a high etching rate. An etching rate [R2] of the second layer (metal layer), which is not particularly limited, is preferably 20 Å/min or greater, more preferably 100 Å/min or greater, and particularly preferably 200 Å/min or greater in terms of productivity. The upper limit, which is not particularly limited, is substantively 1200 Å/min or less.

The exposure width of the metal layer, which is not particularly limited, is preferably 2 nm or greater and more preferably 4 nm or greater from a viewpoint that the advantages of the present invention become remarkable. The upper limit thereof is substantively 1000 nm or less, preferably 100 nm or less, and more preferably 20 nm or less from a viewpoint that the effects thereof become significant in the same manner.

An etching rate [R1] of the layer (first layer) containing germanium or the germanium silicide layer (third layer) is not particularly limited, but it is preferable that the layer is not excessively removed. The etching rate thereof is preferably 200 Å/min or less, more preferably 100 Å/min or less, still more preferably 50 Å/min, even still more preferably 20 Å/min or less, and particularly preferably 10 Å/min or less. The lower limit thereof, which is not particularly limited, is substantively 0.1 Å/min or greater when the measurement limit is considered.

In the selective etching of the second layer, the ratio of the etching rate ([R2]/[R1]), which is not particularly limited, is preferably 2 or greater, more preferably 10 or greater, and still more preferably 20 or greater from a viewpoint of elements which need high selectivity. The upper limit thereof, which is not particularly limited, is preferred as the value becomes larger, but the upper limit thereof is substantively 5000 or less. Further, the etching conditions of the germanium silicide layer (third layer) are the same as those of the germanium-containing layer (first layer) in a broad sense and are in common with a layer (for example, a layer of SiGe or Ge) before annealing is applied thereto. Accordingly, the germanium silicide layer can be substituted with the germanium-containing layer or the layer before annealing is applied thereto according to the etching rate thereof.

Further, since damages of a metal electrode layer such as Al, Cu, Ti, or W and an insulating film layer such as HfO, HfSiO, WO, AlOₓ, SiO, SiOC, SiON, TiN, SiN, or TiAlC (these are collectively referred to as a fourth layer in some cases) can be suitably suppressed, the etching liquid according to the preferred embodiment of the present invention is preferably used for a semiconductor substrate including these layers. Further, in the present specification, in a case where the composition of a metal compound is mentioned by the combination of the elements, this means that metal compounds with arbitrary compositions are broadly included. For example, SiOC (SiON) does not mean that the ratio of the amounts thereof is 1:1:1 but means that Si, O, and C (N) coexist. The same applies throughout the present specification and also to other metal compounds.

The time required for etching one substrate is preferably 10 seconds or longer and more preferably 50 seconds or longer. The upper limit thereof is 300 seconds or shorter and more preferably 200 seconds or shorter.

[Manufacturer of Semiconductor Substrate Product (Semiconductor Process)]

In the present embodiment, it is preferable that a semiconductor substrate product having a desired structure is manufactured through a process of preparing a semiconductor substrate on which the silicon layer and the metal layer are formed, a process of annealing (heat treatment) the semiconductor substrate, and a process of providing the etching liquid for the semiconductor substrate such that the etching liquid is brought into contact with the metal layer and selectively removing the metal layer. At this time, the specific etching liquid is used for etching. The order of the processes is not limited and other processes may be further included between respective processes.

The size of a wafer is not particularly limited, but a wafer whose diameter is 8 inches, 12 inches, or 14 inches is preferably used (1 inch=25.4 mm).

In addition, the term “preparation” in the present specification means that a specific material is included through synthesis or a mixture or a predetermined product is provided by purchase. Moreover, in the present specification, use of the etching liquid so as to perform etching respective materials of the semiconductor substrate is referred to as “application,” but the embodiment thereof is not particularly limited. For example, the application broadly includes the etching liquid being brought into contact with the substrate. Specifically, the etching may be performed by immersing a batch type device or performed through ejection using a sheet type device.

### EXAMPLES

Hereinafter, the present invention will be specifically described with reference to Examples, but the present invention is not limited to Examples described below. Further, “%” or “part” shown as the formulation or the blending amount in Examples is on a mass basis unless otherwise noted.

### Example 1 and Comparative Example 1

### Preparation of Test Substrate

SiGe was epitaxially grown to be formed to have a film thickness of 500 Å on a commercially available silicon substrate (diameter: 12 inches). In the same manner, blank wafers created by CVD or the like were prepared for other films. At this time, the SiGe epitaxial layer contained 50% by mass to 60% by mass of germanium. In tests results shown in Tables below, the etching rates of respective layers were calculated using these blank wafers. Further, the etching rate written as “Ge” does not mean SiGe but means the result of a portion having 100% by mass of germanium.

In the tests results shown in Tables 14 and 15, test substrates were prepared by the following procedures and provided for the tests. SiGe was epitaxially grown on a commercially available silicon substrate (diameter: 12 inches) and a Pt/Ni metal layer (thickness: 20 nm, ratio of Pt/Ni: 10/90 (on a mass basis)) was subsequently formed. At this time, the SiGe epitaxial layer contained 50% by mass to 60% by mass of germanium. The layer was annealed at 800° C. for 10 seconds and a silicide layer was formed to be used as a test substrate. The thickness of the annealed silicide layer was 15 nm and the thickness of the metal layer was 5 nm.

(Etching Test)

The etching was performed under the following conditions in a sheet type device (POLOS (trade name), manufactured by SPS-Europe B. V.) with respect to the blank wafer and the substrate for a test and an evaluation test was carried out.
Treatment temperature: listed in Tables
Ejection amount: 1 L/min.
Wafer rotation speed: 500 rpm
Nozzle movement speed: listed in Tables

Further, the etching liquid was supplied by being separated into two liquids as described below to be line mixed (see FIG. 3). A supply line fc was heated such that the temperature thereof was adjusted to 60° C. It does not take much time from the mixture of two liquids to provision of the mixed solution for the substrate and this means that the mixed solution is provided for the substrate immediately after the mixing.

First liquid (A): acid compound, specific compound, and water

Second liquid (B): oxidant and water

The ratio of the first liquid to the second liquid was set such that the amounts thereof were substantially the same as each other in terms of the volume. According to the formulation, when an acid compound was singly used, a treatment using only one liquid was carried out in this case.

(Method of Measuring Treatment Temperature)

A radiation thermometer IT-550F (trade name, manufactured by HORIBA, Ltd.) was fixed to a position having a height of 30 cm on a wafer in the sheet type device. The thermometer was directed to the surface of the wafer outside from the center thereof by a distance of 2 cm and the temperature was measured while circulating a liquid chemical. The temperature was continuously recorded using a computer through digital output from the radiation thermometer. Among these, a value obtained by averaging the recorded values of the temperature for 10 seconds at the time when the temperature thereof was stabilized was set as a temperature on the wafer.

(pH)

The pH was measured at room temperature (25° C.) using F-51 (trade name, manufactured by HORIBA, Ltd.).

(Etching Rate)

The etching rate (ER) was calculated by measuring the film thickness before or after the etching treatment using Ellipsometry (VASE Spectroscopic ellipsometer was used, J. A. Woollam, Japan). The average value of five points was adopted (measurement conditions measurement range: 1.2 eV to 2.5 eV, measuring angles: 70 degrees and 75 degrees).

(Evaluation of In-Plane Uniformity)

Conditions were set by changing the time with respect to the etching depth in the center of a circular substrate (diameter: 12 inches) and the time at which the etching depth of the germanium-containing layer became 300 Å was confirmed. Subsequently, the etching depth at a position spaced apart from the periphery of the substrate by 30 mm in the center direction was measured at the time when the entire substrate was etched again and an evaluation was made that the in-plane uniformity was higher as the depth thereof was closer to 300 Å. Specific criteria are as follows. The measurement positions at this time were set to nine places in FIG. 5 and the evaluation was made using the average value thereof.

AAA: ±0.1 to less than 5 Å

AA: ±5 to less than 10 Å

A: ±10 to less than 30 Å

B: ±30 to less than 50 Å

C: ±50 or greater

(Ge Concentration)

In the substrate of the first layer containing germanium (Ge), a depth direction of 0 nm to 30 nm was analyzed using etching ESCA (Quantera, manufactured by ULVAC-PHI, INC.) and the average value of the Ge concentration in the analysis results at 3 nm to 15 nm was set as the Ge concentration (% by mass).

(Measurement of Content of Particles)

The number of coarse particles having an average particle diameter of 0.5 μm or greater in the etching liquid was confirmed by measuring the number of particles having a measurement particle diameter of 0.5 μm or greater contained in the liquid using a sensor for particles in a liquid, KS42A (manufactured by RION Co., Ltd.).

(Measurement of Concentration of Alkali Metal Ions)

The concentration of Na, K, and Ca ions were measured by ICPM-8500 (manufactured by Shimadzu Corporation) using an evaluation stock solution.

(Residue after Treatment [Table 5])

The presence of residues after the above-described treatment was observed and confirmed using a scanning electron microscope. It was evaluated as “OK” when residues were not found and evaluated as “NG” when residues were found.

(Electrical Resistance after Specific Substrate Treatment [Table 13] to [Table 15])

The sheet resistance was measured using a four-terminal method in conformity with JIS K7194. The results were evaluated based on the following criteria.

Sheet resistance measuring device:

Manufacturer: Hitachi Kokusai Electric Inc.

Model number: main body VR-120S

Four-point probe: KS-TC-200-MT-200 g

The voltage was measured when 30 mA of a current was made to flow.

A: The metal layer was completely removed and the electrical resistance was increased, but the value had no practical problems.

AA: The metal layer was completely removed and the value of electrical resistance was not nearly increased, which was excellent.

AAA: The metal layer was completely removed. The value of electrical resistance was not increased at all, which was extremely excellent.

TABLE 1

| | | | | | | | | Ge |
|---|---|---|---|---|---|---|---|---|
| | Acid | | | | | | | concen- |
| | compound | Oxidant | | Treatment | | Washing | Nozzle | tration |
| | (concen- | (concen- | | temperature | Treatment | with | movement | (% by |
| Test | tration) | tration) | pH | (° C.) | time (s) | water | speed | mass) |
| 101 | HF(1.0%) | | 4 | 25 | 60 | Yes | 7 | 55 |
| 102 | HCl(1.0%) | | 1 | 25 | 60 | Yes | 7 | 55 |
| 103 | HBr(1.0%) | | 1 | 25 | 60 | Yes | 7 | 55 |
| 104 | HI(1.0%) | | 1 | 25 | 60 | Yes | 7 | 55 |
| 105 | HF(1.0%) | HNO₃(1.0%) | <0 | 25 | 60 | Yes | 7 | 55 |
| 106 | HF(1.0%) | H₂O₂(2.0%) | 3 | 25 | 60 | Yes | 7 | 55 |
| 107 | HCl(1.0%) | | 1 | 25 | 60 | Yes | 7 | 55 |
| 108 | HCl(1.0%) | H₂O₂(2.0%) | <0 | 25 | 60 | Yes | 7 | 55 |
| 109 | HCl(1.0%) | HNO₃(1.0%) | 1 | 25 | 60 | Yes | 7 | 55 |

| | In-plane | SiGe ER | Ge ER | NiPt ER | Ni ER | Ti ER | Co ER |
|---|---|---|---|---|---|---|---|
| Test | uniformity | (Å/min) | (Å/min) | (Å/min)*Pt % | (Å/min) | (Å/min) | (Å/min) |
| 101 | AAA | 3 | 5 | — | 35 | 1500 | 100 |
| 102 | AAA | 6 | 9 | 52*1% | 150 | — | 250 |
| 103 | AA | 7 | 13 | — | 203 | — | 210 |
| 104 | AA | 13 | 20 | — | 210 | — | 222 |
| 105 | AAA | 14 | 25 | — | 290 | 751 | 191 |
| 106 | AA | 21 | 52 | — | 311 | 350 | 210 |
| 107 | AA | 16 | 37 | 486*10% | 652 | — | 293 |
| 108 | AAA | 27 | 105 | 351*10% | 526 | — | 390 |
| 109 | AA | 16 | 37 | 486*10% | 408 | — | 293 |

TABLE 2

| | | | | | | | | Ge | |
|---|---|---|---|---|---|---|---|---|---|
| | Acid | | | | | | | concen- | |
| | compound | Oxidant | | Treatment | | Washing | Nozzle | tration | |
| | (concen- | (concen- | | temperature | Treatment | with | movement | (% by | In-plane |
| Test | tration) | tration) | pH | (° C.) | time (s) | water | speed | mass) | uniformity |
| 201 | HF(1.0%) | | 4 | 25 | 60 | Yes | 0 | 55 | A |
| 202 | HF(1.0%) | | 4 | 25 | 60 | Yes | 1 | 55 | AA |
| 203 | HF(1.0%) | | 4 | 25 | 60 | Yes | 3 | 55 | AA |
| 204 | HF(1.0%) | | 4 | 25 | 60 | Yes | 5 | 55 | AAA |
| 205 | HF(1.0%) | | 4 | 25 | 60 | Yes | 7 | 55 | AAA |
| 206 | HF(1.0%) | | 4 | 25 | 60 | Yes | 15 | 55 | AAA |
| 207 | HCl(1.0%) | HNO₃(1.0%) | <0 | 25 | 60 | Yes | 0 | 55 | A |
| 208 | HCl(1.0%) | HNO₃(1.0%) | <0 | 25 | 60 | Yes | 1 | 55 | AA |
| 209 | HCl(1.0%) | HNO₃(1.0%) | <0 | 25 | 60 | Yes | 3 | 55 | AA |
| 210 | HCl(1.0%) | HNO₃(1.0%) | <0 | 25 | 60 | Yes | 5 | 55 | AAA |
| 211 | HCl(1.0%) | HNO₃(1.0%) | <0 | 25 | 60 | Yes | 7 | 55 | AAA |
| 212 | HCl(1.0%) | HNO₃(1.0%) | <0 | 25 | 60 | Yes | 15 | 55 | AAA |

TABLE 3

| | | | | | | | | Ge |
|---|---|---|---|---|---|---|---|---|
| | Acid | | | | | | | concen- |
| | compound | Oxidant | | Treatment | | Washing | Nozzle | tration |
| | (concen- | (concen- | | temperature | Treatment | with | movement | (% by |
| Test | tration) | tration) | pH | (° C.) | time (s) | water | speed | mass) |
| 301 | HF(1.0%) | | 4 | 25 | 60 | Yes | 7 | 55 |
| 302 | HF(1.0%) | | 4 | 35 | 60 | Yes | 7 | 55 |
| 303 | HF(1.0%) | | 4 | 45 | 60 | Yes | 7 | 55 |
| 304 | HF(1.0%) | | 4 | 65 | 60 | Yes | 7 | 55 |
| 305 | HF(1.0%) | | 4 | 75 | 60 | Yes | 7 | 55 |
| 306 | HCl(1.0%) | HNO₃(1.0%) | 1 | 25 | 60 | Yes | 7 | 55 |
| 307 | HCl(1.0%) | HNO₃(1.0%) | 1 | 35 | 60 | Yes | 7 | 55 |
| 308 | HCl(1.0%) | HNO₃(1.0%) | 1 | 45 | 60 | Yes | 7 | 55 |
| 309 | HCl(1.0%) | HNO₃(1.0%) | 1 | 65 | 60 | Yes | 7 | 55 |
| 310 | HCl(1.0%) | HNO₃(1.0%) | 1 | 75 | 60 | Yes | 7 | 55 |

| | In-plane | SiGe ER | Ge ER | NiPt ER | Ni ER | Ti ER | Co ER |
|---|---|---|---|---|---|---|---|
| Test | uniformity | (Å/min) | (Å/min) | (Å/min)*Pt % | (Å/min) | (Å/min) | (Å/min) |
| 301 | AAA | 3 | 5 | — | 35 | 1500 | 100 |
| 302 | AAA | 6 | 9 | — | 48 | >2000 | 158 |
| 303 | AAA | 11 | 15 | — | 63 | >2000 | 234 |
| 304 | AA | 17 | 25 | — | 87 | >2000 | 351 |
| 305 | A | 21 | 41 | — | 119 | >2000 | 549 |
| 306 | AA | 16 | 37 | 486*10% | 652 | — | 293 |
| 307 | AA | 19 | 53 | 652*10% | 842 | — | 413 |
| 308 | AA | 29 | 81 | 952*10% | 1056 | — | 621 |
| 309 | A | 45 | 125 | 1256*10% | 1354 | — | 842 |
| 310 | B | 68 | 159 | 1654*10% | 1751 | — | 1064 |

TABLE 4

| | | | | | | | | Ge | |
|---|---|---|---|---|---|---|---|---|---|
| | Acid | | | | | | | concen- | |
| | compound | Oxidant | | Treatment | | Washing | Nozzle | tration | |
| | (concen- | (concen- | | temperature | Treatment | with | movement | (% by | In-plane |
| Test | tration) | tration) | pH | (° C.) | time (s) | water | speed | mass) | uniformity |
| 401 | HF(1.0%) | | 4 | 25 | 60 | Yes | 7 | 55 | AAA |
| 402 | HF(1.0%) | | 4 | 25 | 20 | Yes | 7 | 55 | AA |
| 403 | HF(1.0%) | | 4 | 25 | 40 | Yes | 7 | 55 | AAA |
| 404 | HF(1.0%) | | 4 | 25 | 150 | Yes | 7 | 55 | AA |
| 405 | HF(1.0%) | | 4 | 25 | 200 | Yes | 7 | 55 | A |
| 406 | HCl(1.0%) | HNO₃(1.0%) | 1 | 25 | 60 | Yes | 7 | 55 | AA |
| 407 | HCl(1.0%) | HNO₃(1.0%) | 1 | 25 | 20 | Yes | 7 | 55 | A |
| 408 | HCl(1.0%) | HNO₃(1.0%) | 1 | 25 | 40 | Yes | 7 | 55 | AA |
| 409 | HCl(1.0%) | HNO₃(1.0%) | 1 | 25 | 150 | Yes | 7 | 55 | A |
| 410 | HCl(1.0%) | HNO₃(1.0%) | 1 | 25 | 200 | Yes | 7 | 55 | B |

TABLE 5

| | | | | | | | | Ge | | | | |
|---|---|---|---|---|---|---|---|---|---|---|---|---|
| | Acid | | | | | | | concen- | | | | |
| | compound | Oxidant | | Treatment | | Washing | Nozzle | tration | | | | Residue |
| | (concen- | (concen- | | temperature | Treatment | with | movement | (% by | In-plane | SiGe ER | Ge ER | after |
| Test | tration) | tration) | pH | (° C.) | time (s) | water | speed | mass) | uniformity | (Å/min) | (Å/min) | treatment |
| 501 | HF(1.0%) | | 4 | 25 | 60 | Yes | 7 | 55 | AAA | 3 | 5 | OK |
| 502 | HF(1.0%) | | 4 | 25 | 60 | No | 7 | 55 | AAA | 3 | 5 | NG |
| 503 | HCl(1.0%) | HNO₃(1.0%) | 1 | 25 | 60 | Yes | 7 | 55 | AA | 16 | 37 | OK |
| 504 | HCl(1.0%) | HNO₃(1.0%) | 1 | 25 | 60 | No | 7 | 55 | AA | 16 | 37 | NG |

TABLE 6

| | | | | | | | | Ge | | | |
|---|---|---|---|---|---|---|---|---|---|---|---|
| | Acid | | | | | | | concen- | | | |
| | compound | Oxidant | | Treatment | | Washing | Nozzle | tration | | | |
| | (concen- | (concen- | | temperature | Treatment | with | movement | (% by | In-plane | SiGe ER | Ge ER |
| Test | tration) | tration) | pH | (° C.) | time (s) | water | speed | mass) | uniformity | (Å/min) | (Å/min) |
| 601 | HF(1.0%) | | 4 | 25 | 60 | Yes | 7 | 55 | AAA | 3 | — |
| 602 | HF(1.0%) | | 4 | 25 | 60 | Yes | 7 | 20 | A | 2 | — |
| 603 | HF(1.0%) | | 4 | 25 | 60 | Yes | 7 | 75 | AAA | 3 | — |
| 604 | HF(1.0%) | | 4 | 25 | 60 | Yes | 7 | 85 | AAA | 4 | — |
| 605 | HF(1.0%) | | 4 | 25 | 60 | Yes | 7 | 100 | AAA | — | 5 |
| 606 | HCl(1.0%) | HNO₃(1.0%) | 1 | 25 | 60 | Yes | 7 | 55 | AA | 16 | — |
| 607 | HCl(1.0%) | HNO₃(1.0%) | 1 | 25 | 60 | Yes | 7 | 20 | A | 12 | — |
| 608 | HCl(1.0%) | HNO₃(1.0%) | 1 | 25 | 60 | Yes | 7 | 75 | AAA | 21 | — |
| 609 | HCl(1.0%) | HNO₃(1.0%) | 1 | 25 | 60 | Yes | 7 | 85 | AAA | 30 | — |
| 610 | HCl(1.0%) | HNO₃(1.0%) | 1 | 25 | 60 | Yes | 7 | 100 | AAA | — | 37 |

TABLE 7

| | Acid | | Specific | | | | | |
|---|---|---|---|---|---|---|---|---|
| | compound | Oxidant | compound | | Treatment | | Washing | Nozzle |
| | concen- | (concen- | (concen- | | temperature | Treatment | with | movement |
| Test | tration) | tration) | tration) | pH | (° C.) | time (s) | water | speed |
| 701 | HF(1.0%) | | | 4 | 25 | 60 | Yes | 7 |
| 702 | HF(1.0%) | | Sulfolane | 4 | 25 | 60 | Yes | 7 |
| | | | (80%) | | | | | |
| 703 | H₂SiF₆(2.0%) | | Sulfolane | 2 | 25 | 60 | Yes | 7 |
| | | | (80%) | | | | | |
| 704 | HBF₄(2.0%) | | Sulfolane | 1 | 25 | 60 | Yes | 7 |
| | | | (80%) | | | | | |
| 705 | HPF₆(2.0%) | | Sulfolane | 1 | 25 | 60 | Yes | 7 |
| | | | (80%) | | | | | |
| 706 | HCl(1.0%) | | | 1 | 25 | 60 | Yes | 7 |
| 707 | HCl(1.0%) | | Sulfolane | 1 | 25 | 60 | Yes | 7 |
| | | | (80%) | | | | | |
| 708 | HF(1.0%) | HNO₃(1.0%) | | <0 | 25 | 60 | Yes | 7 |
| 709 | HF(1.0%) | HNO₃(1.0%) | AMTAZ (0.1%) | <0 | 25 | 60 | Yes | 7 |
| 710 | H₂SiF₆(2.0%) | HNO₃(1.0%) | AMTAZ (0.1%) | <0 | 25 | 60 | Yes | 7 |
| 711 | HBF₄(2.0%) | HNO₃(1.0%) | AMTAZ (0.1%) | <0 | 25 | 60 | Yes | 7 |
| 712 | HPF₆(2.0%) | HNO₃(1.0%) | AMTAZ (0.1%) | <0 | 25 | 60 | Yes | 7 |
| 713 | HCl(1.0%) | HNO₃(1.0%) | | 1 | 25 | 60 | Yes | 7 |
| 714 | HCl(1.0%) | HNO₃(1.0%) | AMTAZ (0.1%) | 1 | 25 | 60 | Yes | 7 |
| 715 | HCl(1.0%) | H₂O₂(2.0%) | | <0 | 25 | 60 | Yes | 7 |
| 716 | HCl(1.0%) | H₂O₂(2.0%) | AMTAZ (0.1%) | <0 | 25 | 60 | Yes | 7 |

| | Ge | | | | | | | |
|---|---|---|---|---|---|---|---|---|
| | concen- | | | | | | | |
| | tration | | | | | | | |
| | % by | In-plane | SiGe ER | Ge ER | NiPt ER | Ni ER | Ti ER | Co ER |
| Test | mass) | uniformity | (Å/min) | (Å/min) | (Å/min)*Pt % | (Å/min) | (Å/min) | (Å/min) |
| 701 | 55 | AAA | 3 | 5 | — | 35 | 1500 | 100 |
| 702 | 55 | AAA | <1 | <1 | — | 19 | 521 | 38 |
| 703 | 55 | AAA | <1 | <1 | — | 12 | 216 | 21 |
| 704 | 55 | AAA | <1 | <1 | — | 15 | 289 | 29 |
| 705 | 55 | AAA | <1 | <1 | — | 16 | 245 | 25 |
| 706 | 55 | AAA | 6 | 9 | 52*1% | 150 | — | 250 |
| 707 | 55 | AAA | <1 | <1 | 29*1% | 78 | — | 161 |
| 708 | 55 | AA | 14 | 25 | — | 290 | 751 | 191 |
| 709 | 55 | AAA | 6 | 10 | — | 265 | 514 | 171 |
| 710 | 55 | AAA | 5 | 9 | — | 185 | 369 | 98 |
| 711 | 55 | AAA | 5 | 11 | — | 195 | 421 | 152 |
| 712 | 55 | AAA | 6 | 10 | — | 178 | 411 | 172 |
| 713 | 55 | AA | 16 | 37 | 486*10% | 652 | — | 293 |
| 714 | 55 | AAA | 5 | 19 | 254*10% | 485 | — | 251 |
| 715 | 55 | AA | 27 | 105 | 351*10% | 526 | — | 390 |
| 716 | 55 | AAA | 11 | 53 | 175*10% | 352 | — | 313 |

TABLE 8

| | Acid | | Specific | | | | | |
|---|---|---|---|---|---|---|---|---|
| | compound | Oxidant | compound | | Treatment | | Washing | Nozzle |
| | (concen- | (concen- | (concen- | | temperature | Treatment | with | movement |
| Test | tration) | tration) | tration) | pH | (° C.) | time (s) | water | speed |
| 801 | HF(1.0%) | | Sulfolane | 4 | 25 | 60 | Yes | 7 |
| | | | (80%) | | | | | |
| 802 | HF(0.1%) | | Sulfolane | 4 | 25 | 60 | Yes | 7 |
| | | | (80%) | | | | | |
| 803 | HF(0.5%) | | Sulfolane | 4 | 25 | 60 | Yes | 7 |
| | | | (80%) | | | | | |
| 804 | HF(5%) | | Sulfolane | 4 | 25 | 60 | Yes | 7 |
| | | | (80%) | | | | | |
| 805 | HF(10.0%) | | Sulfolane | 4 | 25 | 60 | Yes | 7 |
| | | | (80%) | | | | | |
| 806 | HCl(1.0%) | HNO₃(1.0%) | AMTAZ(0.1%) | 1 | 25 | 60 | Yes | 7 |
| 807 | HCl(0.1%) | HNO₃(1.0%) | AMTAZ(0.1%) | 1 | 25 | 60 | Yes | 7 |
| 808 | HCl(0.5%) | HNO₃(1.0%) | AMTAZ(0.1%) | 1 | 25 | 60 | Yes | 7 |
| 809 | HCl(5%) | HNO₃(1.0%) | AMTAZ(0.1%) | 1 | 25 | 60 | Yes | 7 |
| 810 | HCl(10.0%) | HNO₃(1.0%) | AMTAZ(0.1%) | 1 | 25 | 60 | Yes | 7 |

| | Ge | | | | | | | |
|---|---|---|---|---|---|---|---|---|
| | concen- | | | | | | | |
| | tration | | | | | | | |
| | (% by | In-plane | SiGe ER | Ge ER | NiPt ER | Ni ER | Ti ER | Co ER |
| Test | mass) | uniformity | (Å/min) | (Å/min) | (Å/min)*Pt % | (Å/min) | (Å/min) | (Å/min) |
| 801 | 55 | AAA | <1 | <1 | — | 19 | 521 | 38 |
| 802 | 55 | AA | <1 | <1 | — | 9 | 152 | 12 |
| 803 | 55 | AAA | <1 | <1 | — | 16 | 452 | 21 |
| 804 | 55 | AAA | 2 | 5 | — | 31 | >2000 | 65 |
| 805 | 55 | A | 5 | 11 | — | 54 | >2000 | 114 |
| 806 | 55 | AAA | 5 | 19 | 254*10% | 485 | — | 251 |
| 807 | 55 | AA | <1 | 7 | 185*10% | 214 | — | 156 |
| 808 | 55 | AAA | <1 | 11 | 359*10% | 395 | — | 211 |
| 809 | 55 | AAA | 7 | 25 | 154*10% | 681 | — | 351 |
| 810 | 55 | A | 11 | 37 | 114*10% | 1012 | — | 512 |

TABLE 9

| | Acid | | Specific | | | | | |
|---|---|---|---|---|---|---|---|---|
| | compound | Oxidant | compound | | Treatment | | Washing | Nozzle |
| | (concen- | (concen- | (concen- | | temperature | Treatment | with | movement |
| Test | tration) | tration) | tration) | pH | (° C.) | time (s) | water | speed |
| 901 | HCl(1.0%) | HNO₃(1.0%) | AMTAZ(0.1%) | 1 | 25 | 60 | Yes | 7 |
| 902 | HCl(1.0%) | HNO₃(0.5%) | AMTAZ(0.1%) | 1 | 25 | 60 | Yes | 7 |
| 903 | HCl(1.0%) | HNO₃(3.0%) | AMTAZ(0.1%) | 1 | 25 | 60 | Yes | 7 |
| 904 | HCl(1.0%) | HNO₃(5.0%) | AMTAZ(0.1%) | 1 | 25 | 60 | Yes | 7 |
| 905 | HCl(1.0%) | HNO₃(10.0%) | AMTAZ(0.1%) | 1 | 25 | 60 | Yes | 7 |

| | Ge | | | | | | | |
|---|---|---|---|---|---|---|---|---|
| | concen- | | | | | | | |
| | tration | | | | | | | |
| | (% by | In-plane | SiGe ER | Ge ER | NiPt ER | Ni ER | Ti ER | Co ER |
| Test | mass) | uniformity | (Å/min) | (Å/min) | (Å/min)*Pt % | (Å/min) | (Å/min) | (Å/min) |
| 901 | 55 | AAA | 5 | 19 | 254*10% | 485 | — | 251 |
| 902 | 55 | AAA | <1 | 6 | 165*10% | 215 | — | 126 |
| 903 | 55 | AA | <1 | 29 | 6511*10% | 1256 | — | 561 |
| 904 | 55 | AA | 11 | 41 | 754*10% | >2000 | — | 1054 |
| 905 | 55 | A | 21 | 58 | 789*10% | >2000 | — | 1893 |

TABLE 10

| | Acid | | Specific | | | | | |
|---|---|---|---|---|---|---|---|---|
| | compound | Oxidant | compound | | | | | |
| | (concen- | (concen- | (concen- | | | | | 0.5 μm LPC |
| Test | tration) | tration) | tration) | pH | Na(ppb) | K(ppb) | Ca(ppb) | (number) |
| A01 | HF(1.0%) | | Sulfolane | 4 | 156 | 35 | 214 | 9 |
| | | | (80%) | | | | | |
| A02 | HCl(1.0%) | HNO₃(1.0%) | AMTAZ(0.1%) | 1 | 315 | 54 | 365 | 16 |

TABLE 11-1

| | Acid | | Specific | | | | | |
|---|---|---|---|---|---|---|---|---|
| | compound | Oxidant | compound | | Treatment | | Washing | Nozzle |
| | (concen- | (concen- | (concen- | | temperature | Treatment | with | movement |
| Test | tration) | tration) | tration) | pH | (° C.) | time (s) | water | speed |
| B01 | HF(1.0%) | | | 4 | 25 | 60 | Yes | 7 |
| B02 | HF(1.0%) | | Sulfolane | 4 | 25 | 60 | Yes | 7 |
| | | | (80%) | | | | | |
| B03 | HF(1.0%) | | DMSO (80%) | 4 | 25 | 60 | Yes | 7 |
| B04 | HF(1.0%) | | XAN (80%) | 4 | 25 | 60 | Yes | 7 |
| B05 | HF(1.0%) | | MEK (80%) | 4 | 25 | 60 | Yes | 7 |
| B06 | HF(1.0%) | | DEGDM (80%) | 4 | 25 | 60 | Yes | 7 |
| B07 | HF(1.0%) | | DEGDE (80%) | 4 | 25 | 60 | Yes | 7 |
| B08 | HF(1.0%) | | ACE (80%) | 4 | 25 | 60 | Yes | 7 |
| B09 | HF(1.0%) | | MPM (80%) | 4 | 25 | 60 | Yes | 7 |
| B10 | HF(1.0%) | | γ-BL (80%) | 4 | 25 | 60 | Yes | 7 |
| B11 | HF(1.0%) | | NMP (80%) | 4 | 25 | 60 | Yes | 7 |
| B12 | HF(1.0%) | | DMAA (80%) | 4 | 25 | 60 | Yes | 7 |
| B13 | HF(1.0%) | | DIO (80%) | 4 | 25 | 60 | Yes | 7 |
| B14 | HF(1.0%) | | EC (80%) | 4 | 25 | 60 | Yes | 7 |
| B15 | HF(1.0%) | | PC (80%) | 4 | 25 | 60 | Yes | 7 |
| B16 | HCl(1.0%) | HNO₃(1.0%) | | 1 | 25 | 60 | Yes | 7 |
| B17 | HCl(1.0%) | HNO₃(1.0%) | AMTAZ(0.1%) | 1 | 25 | 60 | Yes | 7 |
| B18 | HCl(1.0%) | HNO₃(1.0%) | MTZ(0.1%) | 1 | 25 | 60 | Yes | 7 |
| B19 | HCl(1.0%) | HNO₃(1.0%) | AMTZ(0.1%) | 1 | 25 | 60 | Yes | 7 |
| B20 | HCl(1.0%) | HNO₃(1.0%) | DATZ(0.1%) | 1 | 25 | 60 | Yes | 7 |

| | Ge | | | | | | | |
|---|---|---|---|---|---|---|---|---|
| | concen- | | SiGe ER | Ge ER | NiPt ER | Ni ER | Ti ER | Co ER |
| | tration | In-plane | (Å/ | (Å/ | (Å/ | (Å/ | (Å/ | (Å/ |
| Test | (% by mass) | uniformity | min) | min) | min)*Pt % | min) | min) | min) |
| B01 | 55 | AAA | 3 | 5 | — | 35 | 1500 | 100 |
| B02 | 55 | AAA | <1 | <1 | — | 19 | 521 | 38 |
| B03 | 55 | AAA | <1 | <1 | — | 18 | 489 | 39 |
| B04 | 55 | AAA | <1 | <1 | — | 17 | 421 | 40 |
| B05 | 55 | AAA | 2 | 4 | — | 25 | 786 | 49 |
| B06 | 55 | AAA | <1 | <1 | — | 19 | 514 | 41 |
| B07 | 55 | AAA | 2 | 3 | — | 17 | 687 | 31 |
| B08 | 55 | AAA | <1 | <1 | — | 18 | 509 | 35 |
| B09 | 55 | AAA | <1 | <1 | — | 19 | 514 | 34 |
| B10 | 55 | AAA | 2 | 2 | — | 20 | 512 | 59 |
| B11 | 55 | AAA | <1 | <1 | — | 15 | 497 | 42 |
| B12 | 55 | AAA | <1 | <1 | — | 16 | 547 | 41 |
| B13 | 55 | AAA | <1 | 2 | — | 17 | 513 | 47 |
| B14 | 55 | AAA | <1 | <1 | — | 15 | 514 | 34 |
| B15 | 55 | AAA | <1 | <1 | — | 13 | 521 | 32 |
| B16 | 55 | AA | 16 | 37 | 486*10% | 652 | — | 293 |
| B17 | 55 | AAA | <1 | 11 | 359*10% | 395 | — | 211 |
| B18 | 55 | AAA | 4 | 19 | 436*10% | 447 | — | 227.5 |
| B19 | 55 | AAA | 1 | 16 | 394*10% | 419 | — | 219 |
| B20 | 55 | AAA | 9 | 21 | 485*10% | 480 | — | 238 |

TABLE 11-2

| | Acid | | Specific | | | | | |
|---|---|---|---|---|---|---|---|---|
| | compound | Oxidant | compound | | Treatment | | Washing | Nozzle |
| | (concen- | (concen- | (concen- | | temperature | Treatment | with | movement |
| Test | tration) | tration) | tration) | pH | (° C.) | time (s) | water | speed |
| B21 | HCl(1.0%) | HNO₃(1.0%) | MTAZ(0.1%) | 1 | 25 | 60 | Yes | 7 |
| B22 | HCl(1.0%) | HNO₃(1.0%) | DMTAZ(0.1%) | 1 | 25 | 60 | Yes | 7 |
| B23 | HCl(1.0%) | HNO₃(1.0%) | TIU(0.1%) | 1 | 25 | 60 | Yes | 7 |
| B24 | HCl(1.0%) | HNO₃(1.0%) | ADE(0.1%) | 1 | 25 | 60 | Yes | 7 |
| B25 | HCl(1.0%) | HNO₃(1.0%) | MP(0.1%) | 1 | 25 | 60 | Yes | 7 |
| B26 | HCl(1.0%) | HNO₃(1.0%) | DAP(0.1%) | 1 | 25 | 60 | Yes | 7 |
| B27 | HCl(1.0%) | HNO₃(1.0%) | Mpy(0.1%) | 1 | 25 | 60 | Yes | 7 |
| B28 | HCl(1.0%) | HNO₃(1.0%) | Hpy(0.1%) | 1 | 25 | 60 | Yes | 7 |
| B29 | HCl(1.0%) | HNO₃(1.0%) | Apy(0.1%) | 1 | 25 | 60 | Yes | 7 |
| B30 | HCl(1.0%) | HNO₃(1.0%) | DAPy(0.1%) | 1 | 25 | 60 | Yes | 7 |
| B31 | HCl(1.0%) | HNO₃(1.0%) | DDT(0.1%) | 1 | 25 | 60 | Yes | 7 |
| B32 | HCl(1.0%) | HNO₃(1.0%) | DT(0.1%) | 1 | 25 | 60 | Yes | 7 |
| B33 | HCl(1.0%) | HNO₃(1.0%) | OT(0.1%) | 1 | 25 | 60 | Yes | 7 |
| B34 | HCl(1.0%) | HNO₃(1.0%) | Cs(0.1%) | 1 | 25 | 60 | Yes | 7 |
| B35 | HCl(1.0%) | HNO₃(1.0%) | CsT(0.1%) | 1 | 25 | 60 | Yes | 7 |
| B36 | HCl(1.0%) | HNO₃(1.0%) | ME(0.1%) | 1 | 25 | 60 | Yes | 7 |
| B37 | HCl(1.0%) | HNO₃(1.0%) | MPA(0.1%) | 1 | 25 | 60 | Yes | 7 |
| B38 | HCl(1.0%) | HNO₃(1.0%) | TS(0.1%) | 1 | 25 | 60 | Yes | 7 |
| B39 | HCl(1.0%) | HNO₃(1.0%) | MBTz(0.1%) | 1 | 25 | 60 | Yes | 7 |
| B40 | HCl(1.0%) | HNO₃(1.0%) | MBIz(0.1%) | 1 | 25 | 60 | Yes | 7 |

| | Ge | | | | | | | |
|---|---|---|---|---|---|---|---|---|
| | concen- | | SiGe ER | Ge ER | NiPt ER | Ni ER | Ti ER | Co ER |
| | tration | In-plane | (Å/ | (Å/ | (Å/ | (Å/ | (Å/ | (Å/ |
| Test | (% by mass) | uniformity | min) | min) | min)*Pt % | min) | min) | min) |
| B21 | 55 | AAA | 5 | 21 | 457*10% | 461 | — | 232 |
| B22 | 55 | AAA | 3 | 17 | 415*10% | 433 | — | 223 |
| B23 | 55 | AAA | 8 | 24 | 499*10% | 489 | — | 241 |
| B24 | 55 | AAA | 9 | 26 | 520*10% | 503 | — | 246 |
| B25 | 55 | AAA | 10 | 24 | 513*10% | 498 | — | 244 |
| B26 | 55 | AAA | 13 | 28 | 562*10% | 531 | — | 255 |
| B27 | 55 | AAA | 7 | 21 | 471*10% | 470 | — | 235 |
| B28 | 55 | AAA | 9 | 23 | 499*10% | 489 | — | 241 |
| B29 | 55 | AAA | 8 | 22 | 485*10% | 480 | — | 238 |
| B30 | 55 | AAA | 7 | 20 | 464*10% | 466 | — | 234 |
| B31 | 55 | AAA | 10 | 25 | 520*10% | 503 | — | 246 |
| B32 | 55 | AAA | 11 | 27 | 541*10% | 517 | — | 250 |
| B33 | 55 | AAA | 12 | 29 | 562*10% | 531 | — | 255 |
| B34 | 55 | AAA | 9 | 22 | 492*10% | 484 | — | 240 |
| B35 | 55 | AAA | 7 | 25 | 499*10% | 489 | — | 241 |
| B36 | 55 | AAA | 13 | 28 | 562*10% | 531 | — | 255 |
| B37 | 55 | AAA | 7 | 23 | 485*10% | 480 | — | 238 |
| B38 | 55 | AAA | 8 | 22 | 485*10% | 480 | — | 238 |
| B39 | 55 | AAA | 13 | 27 | 555*10% | 527 | — | 253 |
| B40 | 55 | AAA | 12 | 26 | 541*10% | 517 | — | 250 |

TABLE 11-3

| | Acid | | Specific | | | | | |
|---|---|---|---|---|---|---|---|---|
| | compound | Oxidant | compound | | Treatment | | Washing | Nozzle |
| | (concen- | (concen- | (concen- | | temperature | Treatment | with | movement |
| Test | tration) | tration) | tration) | pH | (° C.) | time (s) | water | speed |
| B41 | HCl(1.0%) | HNO₃(1.0%) | MC(0.1%) | 1 | 25 | 60 | Yes | 7 |
| B42 | HCl(1.0%) | HNO₃(1.0%) | DSA(0.1%) | 1 | 25 | 60 | Yes | 7 |
| B43 | HCl(1.0%) | HNO₃(1.0%) | POEL(0.1%) | 1 | 25 | 60 | Yes | 7 |
| B44 | HCl(1.0%) | HNO₃(1.0%) | LSA(0.1%) | 1 | 25 | 60 | Yes | 7 |
| B45 | HCl(1.0%) | HNO₃(1.0%) | ANSA(0.1%) | 1 | 25 | 60 | Yes | 7 |
| B46 | HCl(1.0%) | HNO₃(1.0%) | DBNA(0.1%) | 1 | 25 | 60 | Yes | 7 |
| B47 | HCl(1.0%) | HNO₃(1.0%) | ADPNA(0.1%) | 1 | 25 | 60 | Yes | 7 |
| B48 | HCl(1.0%) | HNO₃(1.0%) | DDNA(0.1%) | 1 | 25 | 60 | Yes | 7 |
| B49 | HCl(1.0%) | HNO₃(1.0%) | LPS(0.1%) | 1 | 25 | 60 | Yes | 7 |
| B50 | HCl(1.0%) | HNO₃(1.0%) | LPz(0.1%) | 1 | 25 | 60 | Yes | 7 |
| B51 | HCl(1.0%) | HNO₃(1.0%) | LTMA(0.1%) | 1 | 25 | 60 | Yes | 7 |
| B52 | HCl(1.0%) | HNO₃(1.0%) | LDMAB(0.1%) | 1 | 25 | 60 | Yes | 7 |
| B53 | HCl(1.0%) | HNO₃(1.0%) | LCHIB(0.1%) | 1 | 25 | 60 | Yes | 7 |
| B54 | HCl(1.0%) | HNO₃(1.0%) | DMLAo(0.1%) | 1 | 25 | 60 | Yes | 7 |
| B55 | HCl(1.0%) | HNO₃(1.0%) | DAPAc(0.1%) | 1 | 25 | 60 | Yes | 7 |

| | Ge | | | | | | | |
|---|---|---|---|---|---|---|---|---|
| | concen- | | SiGe ER | Ge ER | NiPt ER | Ni ER | Ti ER | Co ER |
| | tration | In-plane | (Å/ | (Å/ | (Å/ | (Å/ | (Å/ | (Å/ |
| Test | (% by mass) | uniformity | min) | min) | min)*Pt % | min) | min) | min) |
| B41 | 55 | AAA | 11 | 26 | 534*10% | 513 | — | 249 |
| B42 | 55 | AAA | 8 | 24 | 499*10% | 489 | — | 241 |
| B43 | 55 | AAA | 14 | 30 | 583*10% | 545 | — | 259 |
| B44 | 55 | AAA | 13 | 27 | 555*10% | 527 | — | 253 |
| B45 | 55 | AAA | 12 | 28 | 555*10% | 527 | — | 253 |
| B46 | 55 | AAA | 11 | 25 | 527*10% | 508 | — | 247 |
| B47 | 55 | AAA | 14 | 30 | 583*10% | 545 | — | 259 |
| B48 | 55 | AAA | 12 | 26 | 541*10% | 517 | — | 250 |
| B49 | 55 | AAA | 11 | 28 | 548*10% | 522 | — | 252 |
| B50 | 55 | AAA | 13 | 24 | 534*10% | 513 | — | 249 |
| B51 | 55 | AAA | 14 | 27 | 562*10% | 531 | — | 255 |
| B52 | 55 | AAA | 15 | 28 | 576*10% | 541 | — | 258 |
| B53 | 55 | AAA | 12 | 24 | 527*10% | 508 | — | 247 |
| B54 | 55 | AAA | 11 | 25 | 527*10% | 508 | — | 247 |
| B55 | 55 | AAA | 13 | 27 | 555*10% | 527 | — | 253 |

TABLE 12-1

| | Acid | | Specific | | | | | |
|---|---|---|---|---|---|---|---|---|
| | compound | Oxidant | compound | | Treatment | | Washing | Nozzle |
| | (concen- | (concen- | (concen- | | temperature | Treatment | with | movement |
| Test | tration) | tration) | tration) | pH | (° C.) | time (s) | water | speed |
| C01 | HF(1.0%) | | | 4 | 25 | 60 | Yes | 7 |
| C02 | HF(1.0%) | | Sulfolane | 4 | 25 | 60 | Yes | 7 |
| | | | (80%) | | | | | |
| C03 | HF(1.0%) | | Sulfolane | 4 | 25 | 60 | Yes | 7 |
| | | | (40%) | | | | | |
| C04 | HF(1.0%) | | Sulfolane | 4 | 25 | 60 | Yes | 7 |
| | | | (70%) | | | | | |
| C05 | HF(1.0%) | | Sulfolane | 4 | 25 | 60 | Yes | 7 |
| | | | (95%) | | | | | |
| C06 | HCl(1.0%) | HNO₃(1.0%) | | 1 | 25 | 60 | Yes | 7 |
| C07 | HCl(1.0%) | HNO₃(1.0%) | AMTAZ(0.1%) | 1 | 25 | 60 | Yes | 7 |
| C08 | HCl(1.0%) | HNO₃(1.0%) | AMTAZ(0.01%) | 1 | 25 | 60 | Yes | 7 |
| C09 | HCl(1.0%) | HNO₃(1.0%) | AMTAZ(1%) | 1 | 25 | 60 | Yes | 7 |
| C10 | HCl(1.0%) | HNO₃(1.0%) | AMTAZ(5%) | 1 | 25 | 60 | Yes | 7 |
| C11 | HCl(1.0%) | HNO₃(1.0%) | AMTAZ(0.1%) | 1 | 25 | 60 | Yes | 7 |
| C12 | HCl(1.0%) | HNO₃(1.0%) | AMTAZ(0.1%) | 1 | 25 | 60 | Yes | 7 |
| C13 | HCl(1.0%) | HNO₃(1.0%) | AMTAZ(0.1%) | 1 | 25 | 60 | Yes | 7 |

| | Ge | | | | | |
|---|---|---|---|---|---|---|
| | concen- | | Other | SiGe ER | Ge ER | NiPt ER |
| | tration | In-plane | (concen- | (Å/ | (Å/ | (Å/ |
| Test | (% by mass) | uniformity | tration) | min) | min) | min)*Pt % |
| C01 | 55 | AAA | | 3 | 5 | — |
| C02 | 55 | AAA | | <1 | <1 | — |
| C03 | 55 | AAA | | 2 | 4 | — |
| C04 | 55 | AAA | | 1 | 2 | — |
| C05 | 55 | AAA | | <1 | <1 | — |
| C06 | 55 | AA | | 16 | 37 | 486*10% |
| C07 | 55 | AAA | | <1 | 11 | 359*10% |
| C08 | 55 | AAA | | <1 | 19 | 451*10% |
| C09 | 55 | AAA | | <1 | 13 | 312*10% |
| C10 | 55 | AAA | | <1 | 9 | 248*10% |
| C11 | 55 | AAA | MSA(40%) | <1 | 12 | 412*10% |
| C12 | 55 | AAA | MSA(70%) | <1 | 4 | 289*10% |
| C13 | 55 | AAA | MSA(70%) | <1 | <1 | 251*10% |
| | | | PPG(0.1%) | | | |

TABLE 12-2

| | Acid | | Specific | | | | |
|---|---|---|---|---|---|---|---|
| | compound | Oxidant | compound | Ni ER | Ti ER | Co ER | TiN ER |
| | (concen- | (concen- | (concen- | (Å/ | (Å/ | (Å/ | (Å/ |
| Test | tration) | tration) | tration) | min) | min) | min) | min) |
| C01 | HF(1.0%) | | | 35 | 1500 | 100 | <1 |
| C02 | HF(1.0%) | | Sulfolane | 19 | 521 | 38 | <1 |
| | | | (80%) | | | | |
| C03 | HF(1.0%) | | Sulfolane | 28 | 984 | 38 | <1 |
| | | | (40%) | | | | |
| C04 | HF(1.0%) | | Sulfolane | 22 | 721 | 38 | <1 |
| | | | (70%) | | | | |
| C05 | HF(1.0%) | | Sulfolane | 15 | 421 | 38 | <1 |
| | | | (95%) | | | | |
| C06 | HCl(1.0%) | HNO₃(1.0%) | | 652 | — | 293 | <1 |
| C07 | HCl(1.0%) | HNO₃(1.0%) | AMTAZ(0.1%) | 395 | — | 211 | <1 |
| C08 | HCl(1.0%) | HNO₃(1.0%) | AMTAZ(0.01%) | 512 | — | 287 | <1 |
| C09 | HCl(1.0%) | HNO₃(1.0%) | AMTAZ(1%) | 210 | — | 251 | <1 |
| C10 | HCl(1.0%) | HNO₃(1.0%) | AMTAZ(5%) | 151 | — | 189 | <1 |
| C11 | HCl(1.0%) | HNO₃(1.0%) | AMTAZ(0.1%) | 912 | — | 562 | <1 |
| C12 | HCl(1.0%) | HNO₃(1.0%) | AMTAZ(0.1%) | 874 | — | 413 | <1 |
| C13 | HCl(1.0%) | HNO₃(1.0%) | AMTAZ(0.1%) | 811 | — | 397 | <1 |

| | Al ER | AlOx ER | W ER | WOx ER | HfOx | HfSiOx |
|---|---|---|---|---|---|---|
| | (Å/ | (Å/ | (Å/ | (Å/ | (Å/ | (Å/ |
| Test | min) | min) | min) | min) | min) | min) |
| C01 | 215 | 297 | <1 | <1 | >30 | 12 |
| C02 | 9 | 10 | <1 | <1 | 13 | 3 |
| C03 | 29 | 37 | <1 | <1 | 19 | 6 |
| C04 | 11 | 16 | <1 | <1 | 15 | 4 |
| C05 | 7 | 10 | <1 | <1 | 11 | <1 |
| C06 | 152 | 215 | <1 | <1 | <1 | <1 |
| C07 | 82 | 112 | <1 | <1 | <1 | <1 |
| C08 | 101 | 135 | <1 | <1 | <1 | <1 |
| C09 | 54 | 79 | <1 | <1 | <1 | <1 |
| C10 | 48 | 75 | <1 | <1 | <1 | <1 |
| C11 | 102 | 121 | <1 | <1 | <1 | <1 |
| C12 | 13 | 15 | <1 | <1 | <1 | <1 |
| C13 | <1 | <1 | <1 | <1 | <1 | <1 |

TABLE 13

| | | | | | | | | | | | Electrical |
|---|---|---|---|---|---|---|---|---|---|---|---|
| | | | | | | | | | Ge | | resistance |
| | Acid | | Specific | | | | | | concen- | | after |
| | compound | Oxidant | compound | | Treatment | | Washing | Nozzle | tration | Other | treatment |
| | (concen- | (concen- | (concen- | | temperature | Treatment | with | movement | (% by | (concen- | on specific |
| Test | tration) | tration) | tration) | pH | (° C.) | time (s) | water | speed | mass) | tration) | substrate |
| D01 | HF(1.0%) | | | 4 | 25 | 60 | Yes | 7 | 55 | | A |
| D02 | HF(1.0%) | | Sulfolane | 4 | 25 | 60 | Yes | 7 | 55 | | AA |
| | | | (80%) | | | | | | | | |
| D03 | HF(1.0%) | | Sulfolane | 4 | 25 | 60 | Yes | 7 | 55 | | AA |
| | | | (40%) | | | | | | | | |
| D04 | HF(1.0%) | | Sulfolane | 4 | 25 | 60 | Yes | 7 | 55 | | AAA |
| | | | (70%) | | | | | | | | |
| D05 | HF(1.0%) | | Sulfolane | 4 | 25 | 60 | Yes | 7 | 55 | | AAA |
| | | | (95%) | | | | | | | | |
| D06 | HCl(1.0%) | HNO₃(1.0%) | | 1 | 25 | 60 | Yes | 7 | 55 | | A |
| D07 | HCl(1.0%) | HNO₃(1.0%) | AMTAZ(0.1%) | 1 | 25 | 60 | Yes | 7 | 55 | | AA |
| D08 | HCl(1.0%) | HNO₃(1.0%) | AMTAZ(0.01%) | 1 | 25 | 60 | Yes | 7 | 55 | | AA |
| D09 | HCl(1.0%) | HNO₃(1.0%) | AMTAZ(1%) | 1 | 25 | 60 | Yes | 7 | 55 | | AA |
| D10 | HCl(1.0%) | HNO₃(1.0%) | AMTAZ(5%) | 1 | 25 | 60 | Yes | 7 | 55 | | A |
| D11 | HCl(1.0%) | HNO₃(1.0%) | AMTAZ(0.1%) | 1 | 25 | 60 | Yes | 7 | 55 | MSA(40%) | AAA |
| D12 | HCl(1.0%) | HNO₃(1.0%) | AMTAZ(0.1%) | 1 | 25 | 60 | Yes | 7 | 55 | MSA(70%) | AAA |
| D13 | HCl(1.0%) | HNO₃(1.0%) | AMTAZ(0.1%) | 1 | 25 | 60 | Yes | 7 | 55 | MSA(70%) | AAA |
| | | | | | | | | | | PPG(0.1%) | |

TABLE A

| First group | | Formula |
|---|---|---|
| Sulfolane | Sulfolane | VI |
| DMSO | Dimethyl sulfoxide | VI |
| XAN | Cyclohexanone | VI, XI |
| MEK | Methyl ethyl ketone | VI |
| DEGDM | Diethylene glycol dimethyl ether | IX |
| DEGDE | Diethylene glycol diethyl ether | IX |
| ACE | Ethyl acetate | V |
| MPM | Methyl 3-methoxypropionate | V |
| γ-BL | γ butyrolactone | VI, XIII |
| NMP | N-methylpyrrolidone | IIX, XIII |
| DMAA | NN-dimethylacetamide | IIX |
| DIO | 1,4-dioxane | XI |
| EC | Ethylene carbonate | VI, XIII |
| PC | Propylene carbonate | VI, XIII |
| MSA | Methanesulfonic acid | V |
| PPG | Polypropylene glycol | IX |
| HG | Hexylene glycol | IX |
| 13BD | 1,3-butanediol | IX |
| 14BD | 1,4-butanediol | IX |
| MMB | 3-methoxy-3 methyl-1-butanol | IX |
| MMBA | 3-methoxy-3 methyl-butyl acetate | IIX |
| 3M1B | 3-methyl-1-butanol | IX |
| PG | Propylene glycol | IX |

The formulae only show representative examples.

TABLE B

| Second group | | Formula |
|---|---|---|
| AMTAZ | 2-amino-5-mercapto-1,3,4-thiadiazole | I |
| MTZ | 3-mercapto-1,2,4-triazole | X |
| AMTZ | 3-amino-5-mercapto-1,2,4-triazole | X |
| DATZ | 3,5-diamino-1,2,4-triazole | X |
| MTAZ | 2-mercapto-1,3,4-thiadiazole | I |
| DMTAZ | 2,5-dimercapto-1,3,4-thiadiazole | I |
| TIU | Thiouracil | XII |
| ADE | Adenine | III |
| MP | 6-methoxypurine | II, III |
| DAP | 2,6-diaminopurine | II, III |
| Mpy | 2-mercaptopyridine | II |
| Hpy | 2-hydroxypyridine | II |
| Apy | 2-aminopyridine | II |
| DAPy | 2,6-diaminopyridine | II |
| DDT | 1-dodecanethiol | V |
| DT | 1-decanethiol | V |
| OT | 1-octanethiol | V |
| Cs | Cystine | IV, VII |
| CsT | Cysteine | IV |
| ME | Mercaptoethanol | IV |
| MPA | 3-mercaptopropionic acid | IV |
| TS | Thiosalicylic acid | IV |
| MBTz | 2-mercaptobenzothiazole | III |
| MBIz | 2-mercaptobenzoimidazole | III |
| MC | Mercaptosuccinic acid | IV |
| DSA | Dodecylbenzenesulfonic acid | V |
| POEL | Polyoxyethylene lauryl ether sulfate | V |
| LSA | Lauryl sulfoacetate | V |
| ANSA | Alkyl naphthalene sulfonic acid | V |
| DBNA | Dibutyl naphthalene sulfonic acid | V |
| ADPNA | Alkyl diphenyl ether disulfonic acid | V |
| DDNA | Dodecyl naphthalene sulfonic acid | V |
| LPS | Lauryl phosphoric acid | V |
| LPz | Lauryl pyridinium chloride | V |
| LTMA | Lauryl trimethyl ammonium | V |
| LDMAB | Lauryl dimethyl aminoacetic acid betaine | V |
| LCHIB | 2-lauryl-N-carboxymethyl-N-hydroxyethylimidazolinium betaine | V |
| DMLAo | Dimethyl laurylamine oxide | V |
| DAPAc | 3-dodecylaminopropionic acid | V |
| MSA | Methanesulfonic acid | V |
| Lau | Lauric acid | V |
| Cap | Capric acid | V |
| Nona | Nonanoic acid | V |
| Oc | Octanoic acid | V |
| Ac | Acetic acid | V |
| γ-H | γ-hexanolactone | VI, XIII |
| 1O2P | 1-n-octyl-2-pyrrolidone | VI, XIII |
| γ-U | γ-undecanolactone | VI, XIII |
| Ox | Oxalic acid | VII |
| SmO | Sorbitan acid ocrylate | V |
| SmL | Sorbitan acid laurate | V |
| Dec | Decanoic acid | V |
| PrP | Phosphoric acid | — |
| HBF4 | Tetrafluoroboric acid | — |
| PVP | Polyvinyl phosphonic acid | — |
| PnP | Phosphonic acid | — |
| OPnP | Octyl phosphonic acid | — |
| PPnP | Phenyl phosphonic acid | — |
| PPrP | Polyphosphoric acid | — |
| POAS | Polyoxyethylene alkyl ether sulfate | V |

The formulae only show representative examples.

Alkyl groups of ANSA and ADPNA are respectively an isopropyl group and a dodecyl group.

The number of carbon atoms of polypropylene glycol is 6 to 100.

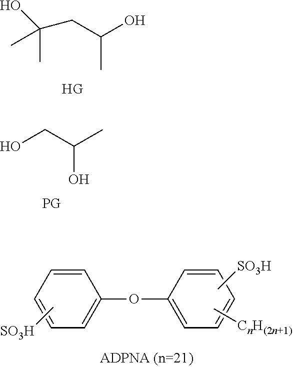

In test Nos. 201 to 206, 401 to 405, 501 and 502, and 601 to 605, the etching rate (ER) of SiGe was approximately 3 Å/min, the etching rate of Ge was approximately 5 Å/min, the etching rate of Ni was approximately 35 Å/min, the etching rate of Ti was approximately 1500 Å/min, and the etching rate of Co was approximately 100 Å/min.

In test Nos. 207 to 212, 406 to 410, 503 and 504, and 606 to 610, the etching rate (ER) of SiGe was approximately 10 Å/min to 20 Å/min, the etching rate of Ge was approximately 40 Å/min, the etching rate of NiPt was approximately 500 Å/min, the etching rate of Ni was approximately 650 Å/min, and the etching rate of Co was approximately 300 Å/min.

<Notes in Table>

Pt % of NiPt: content of Pt, % by mass

Ge concentration: content of Ge, % by mass

ER: etching rate (Å/min)

LPC: number of coarse particles having average particle diameter of 0.5 μm or greater (number/ml)

Nozzle movement speed: unit cm/s

Concentration of acid compound, oxidant, or specific compound (including other): % by mass

Washing with water: washing with water after treatment, Yes: present, No: absent

1 Å=0.1 nm

In the etching liquid, the remainder other than blending components in Table above is water (ultrapure water) (the same applies to other Tables).

According to the present invention, the second layer containing a specific metal can be selectively removed with respect to the first layer containing germanium. Further, it is understood that the selectivity is further improved by using the etching liquid containing a specific organic additive.

Moreover, the etching treatment was performed using a batch type device with respect to the test Nos. 101 and 109 and the results thereof were compared to each other. As the batch type treatment device, Wet Bench (trade name, manufactured by Seto Engineering Co., Ltd.) was used. The temperature of a treatment tank was set to 60° C. and a wafer was treated by being immersed for 1 minute.

As a result, the etching rate thereof was not nearly changed, but a significant difference in the in-plane uniformity was generated.

TABLE C

| Test No. | Acid compound | Oxidant | Device | In-plane uniformity |
|---|---|---|---|---|
| 101 | HF(1.0%) | — | Sheet type | AAA |
| 101a | HF(1.0%) | — | Batch type | A |
| 109 | HCl(1.0%) | HNO₃ | Sheet type | AA |
| 109a | HCl(1.0%) | HNO₃ | Batch type | B |

From the results described above, it is understood that the etching liquid and the etching method of the present invention are particularly suitable for the sheet type device and excellent etching characteristics are exhibited.

### Example 2

The evaluation of etching was performed in the same manner as in Example 1 described above except that compounds (acid compounds, oxidants, and specific compounds) to be used were changed as listed in Tables 14 to 19. Moreover, in the test results shown in Tables 14 and 15, the concentration of germanium in SiGe of the substrate was set to 55% by mass, the pH thereof was set to 4 in the test of Table 14 and set to 1 in the test of Table 15, the sheet type device was used as a device, the treatment temperature was set to 25° C., the treatment time was set to 60 seconds, washing with water was performed (Yes), and the nozzle movement speed was set to 7 cm/s. Other abbreviations, units of concentration, and the like are the same as those of Tables 1 to 13. In the etching liquid, the remainder other than blending components in Tables is water (ultrapure water).

TABLE 14

| | Acid | | Specific | | | | | | | | |
|---|---|---|---|---|---|---|---|---|---|---|---|
| | compound | Oxidant | compound | | In-plane | SiGe ER | Ge ER | NiPt ER | Ni ER | Ti ER | Co ER |
| | (concen- | (concen- | (concen- | | uniformity | (Å/ | (Å/ | (Å/ | (Å/ | (Å/ | (Å/ |
| Test | tration) | tration) | tration) | ClogP | (%) | min) | min) | min)*Pt % | min) | min) | min) |
| E01 | HF(1.0%) | | | — | AAA | 3 | 5 | — | 35 | 1500 | 100 |
| (B01) | | | | | | | | | | | |
| E02 | HF(1.0%) | | Sulfone (80%) | −0.78 | AAA | <1 | <1 | — | 19 | 521 | 38 |
| (B02) | | | | | | | | | | | |
| E03 | HF(1.0%) | | HG (80%) | 0.17 | AAA | <1 | <1 | — | 18 | 853 | 53 |
| E04 | HF(1.0%) | | MMB (80%) | 0.21 | AAA | <1 | <1 | — | 18 | 882 | 48 |
| E05 | HF(1.0%) | | MMBA (80%) | 0.44 | AAA | <1 | <1 | — | 20 | 812 | 45 |
| E06 | HF(1.0%) | | 13BD (80%) | −0.37 | AAA | <1 | <1 | — | 17 | 564 | 43 |
| E07 | HF(1.0%) | | 14BD (80%) | −0.23 | AAA | <1 | <1 | — | 25 | 768 | 42 |
| E08 | HF(1.0%) | | HG (60%) | 0.17 | AAA | <1 | <1 | — | 21 | 1053 | 65 |
| E09 | HF(1.0%) | | HG (90%) | 0.17 | AAA | <1 | <1 | — | 14 | 521 | 31 |
| E10 | HF(0.5%) | | HG (80%) | 0.17 | AAA | <1 | <1 | — | 11 | 485 | 27 |
| E11 | HF(1.5%) | | HG (80%) | 0.17 | AAA | <1 | <1 | — | 28 | 1113 | 53 |
| E12 | HF(2.0%) | | HG (80%) | 0.17 | AAA | <1 | <1 | — | 29 | 1459 | 87 |

| | | | AlOx ER | W ER | WOx ER | HfOx | HfSiOx | Value of |
|---|---|---|---|---|---|---|---|---|
| | TiN ER | Al ER | (Å/ | (Å/ | (Å/ | (Å/ | (Å/ | electrical |
| Test | (Å/min) | (Å/min) | min) | min) | min) | min) | min) | resistance |
| E01 | <1 | 215 | 297 | <1 | <1 | >30 | 12 | A |
| (B01) | | | | | | | | (D01) |
| E02 | <1 | 4 | 5 | <1 | <1 | 6 | <1 | AA |
| (B02) | | | | | | | | (D02) |
| E03 | <1 | 4 | 5 | <1 | <1 | 6 | <1 | AAA |
| E04 | <1 | 3 | 4 | <1 | <1 | 3 | <1 | AAA |
| E05 | <1 | 8 | 6 | <1 | <1 | 6 | <1 | AAA |
| E06 | <1 | 12 | 14 | <1 | <1 | 15 | <1 | AAA |
| E07 | <1 | 11 | 12 | <1 | <1 | 18 | <1 | AAA |
| E08 | <1 | 15 | 16 | <1 | <1 | 13 | <1 | AAA |
| E09 | <1 | 2 | 4 | <1 | <1 | 4 | <1 | AAA |
| E10 | <1 | 1 | 3 | <1 | <1 | 3 | <1 | AAA |
| E11 | <1 | 9 | 8 | <1 | <1 | 10 | 1.3 | AAA |
| E12 | <1 | 21 | 10 | <1 | <1 | 11 | 1.5 | AAA |

The blank spaces in the oxidant column mean that the oxidant was not used.
Value of electrical resistance: value of electrical resistance after treatment is performed on specific substrate.

The present Table shows the performance at the time when SiGe and Ge are NiPt-silicided.

From the results of the above Table, in a case of hydrofluoric acid-based (Ti or the like is a target to be removed), it is understood that a glycol-based solvent exhibits particularly excellent performance. In addition, it is understood that a hydroxy group-containing compound whose α-position does not have a hydroxy group (the number of carbon atoms between O—O is 2 or greater (preferably 3 or greater)) is preferable.

TABLE 15

| | Acid | | Specific | | | | | | | | |
|---|---|---|---|---|---|---|---|---|---|---|---|
| | compound | Oxidant | compound | Other | In-plane | SiGe ER | Ge ER | NiPt ER | Ni ER | Ti ER | Co ER |
| | (concen- | (concen- | (concen- | (concen- | unifor- | (Å/ | (Å/ | (Å/ | (Å/ | (Å/ | (Å/ |
| Test | tration) | tration) | tration) | tration) | mity | min) | min) | min)*Pt % | min) | min) | min) |
| F01 | HCl(1.0%) | HNO₃(1.0%) | | | AA | 16 | 37 | 486*10% | 652 | — | 293 |
| (C06) | | | | | | | | | | | |
| F02 | HCl(1.0%) | HNO₃(1.0%) | AMTAZ (0.1%) | MSA (70%) | AAA | <1 | 4 | 289*10% | 874 | — | 413 |
| (C12) | | | | | | | | | | | |
| F03 | HCl(1.0%) | HNO₃(1.0%) | DSA (0.1%) | MSA (70%) | AAA | <1 | 24 | 369*10% | 1053 | — | 486 |
| F04 | HCl(1.0%) | HNO₃(1.0%) | ADPNA (0.1%) | MSA (70%) | AAA | <1 | 7 | 359*10% | 995 | — | 453 |
| F05 | HCl(0.1%) | HNO₃(1.0%) | ADPNA (0.1%) | MSA (70%) | AAA | <1 | 12 | 322*10% | 651 | — | 432 |
| F06 | HCl(0.5%) | HNO₃(1.0%) | ADPNA (0.1%) | MSA (70%) | AAA | <1 | 9 | 345*10% | 789 | — | 456 |
| F07 | HCl(3.0%) | HNO₃(1.0%) | ADPNA (0.1%) | MSA (70%) | AAA | <1 | 4 | 351*10% | 1123 | — | 501 |
| F08 | HCl(1.0%) | HNO₃(0.5%) | ADPNA (0.1%) | MSA (70%) | AAA | <1 | 3 | 245*10% | 486 | — | 312 |
| F09 | HCl(1.0%) | HNO₃(2.0%) | ADPNA (0.1%) | MSA (70%) | AAA | <1 | 15 | 593*10% | 1368 | — | 591 |
| F10 | HCl(1.0%) | HNO₃(1.0%) | ADPNA (0.001%) | MSA (70%) | AAA | <1 | 11 | 381*10% | 1059 | — | 491 |
| F11 | HCl(1.0%) | HNO₃(1.0%) | ADPNA (0.01%) | MSA (70%) | AAA | <1 | 9 | 371*10% | 1053 | — | 489 |
| F12 | HCl(1.0%) | HNO₃(1.0%) | ADPNA (0.5%) | MSA (70%) | AAA | <1 | 3 | 361*10% | 1041 | — | 481 |

| | TiN ER | Al ER | AlOx ER | W ER | WOx ER | HfOx | HfSiOx | Value of |
|---|---|---|---|---|---|---|---|---|
| | (Å/ | (Å/ | (Å/ | (Å/ | (Å/ | (Å/ | (Å/ | electrical |
| Test | min) | min) | min) | min) | min) | min) | min) | resisstance |
| F01 | <1 | 152 | 215 | <1 | <1 | <1 | <1 | A |
| (C06) | | | | | | | | (D06) |
| F02 | <1 | 13 | 15 | <1 | <1 | <1 | <1 | AAA |
| (C12) | | | | | | | | (D12) |
| F03 | <1 | 8 | 10 | <1 | <1 | <1 | <1 | AAA |
| F04 | <1 | 7 | 9 | <1 | <1 | <1 | <1 | AAA |
| F05 | <1 | 5 | 6 | <1 | <1 | <1 | <1 | AAA |
| F06 | <1 | 6 | 7 | <1 | <1 | <1 | <1 | AAA |
| F07 | <1 | 11 | 10 | <1 | <1 | <1 | <1 | AAA |
| F08 | <1 | 4 | 6 | <1 | <1 | <1 | <1 | AAA |
| F09 | <1 | 12 | 13 | <1 | <1 | <1 | <1 | AAA |
| F10 | <1 | 16 | 16 | <1 | <1 | <1 | <1 | AAA |
| F11 | <1 | 12 | 14 | <1 | <1 | <1 | <1 | AAA |
| F12 | <1 | 7 | 8 | <1 | <1 | <1 | <1 | AAA |

Value of electrical resistance: value of electrical resistance after treatment is performed on specific substrate
“%” of NiPt ER indicates the content of Pt.

The present Table shows the performance at the time when SiGe and Ge are NiPt-silicided.

From the results of the above Table, it is understood that specific compounds (the first group and the second group) being used in combination is preferable when aqua regia (NiPt or the like is a target to be removed) is used. Among the compounds, it is preferable to select a thiadiazole-based compound (for example, AMTAZ) or a sulfonic acid compound (for example, DSA or ADPNA) from the second group because damage of Ge can be suppressed (see F02 to F12 in Table 15).

TABLE 16

| | | | | | | | | Test results |
|---|---|---|---|---|---|---|---|---|
| | Combination | | | | | | | Ti ER |
| | Acid | % by | Specific | % by | Specific | % by | Remain- | (Å/ |
| No. | compound | mass | compound 1 | mass | compound 2 | mass | der | min) |
| G01 | HF | 1.3 | HG | 68.7 | MSA | 15.0 | Water | 452.0 |
| G02 | HF | 1.3 | HG | 73.7 | MSA | 10.0 | Water | 723.0 |
| G03 | HF | 1.3 | HG | 63.7 | MSA | 20.0 | Water | 245.0 |
| G04 | HF | 1.3 | HG | 82.2 | DSA | 3.5 | Water | 1,265.2 |
| G05 | HF | 1.3 | HG | 83.7 | DSA | 2.0 | Water | 1,205.8 |
| G06 | HF | 1.3 | HG | 85.2 | DSA | 0.5 | Water | 1,188.2 |
| G07 | HF | 1.6 | 14BD | 68.7 | MSA | 15.0 | Water | 362.8 |
| G08 | HF | 1.7 | 3M1B | 68.7 | MSA | 15.0 | Water | 488.5 |
| G09 | HF | 1.0 | | | | | Water | 1,500.0 |
| G10 | HF | 1.3 | HG | 85.7 | | | Water | 1,153.5 |
| G11 | HF | 1.3 | PG | 85.7 | | | Water | 2.5 |
| G12 | HF | 1.3 | HG | 83.7 | Ac | 2.0 | Water | 1,298.4 |
| G13 | HF | 1.3 | HG | 83.7 | Lau | 2.0 | Water | 1,266.8 |

| | Test results | | | | | | |
|---|---|---|---|---|---|---|---|
| | Al ER | TiN ER | W ER | HfOx | HfSiOx | SiGe ER | Ge ER |
| | (Å/ | (Å/ | (Å/ | (Å/ | (Å/ | (Å/ | (Å/ |
| No. | min) | min) | min) | min) | min) | min) | min) |
| G01 | 0.5 | 1.5 | 0.2 | 0.8 | 1.2 | 2.5 | 1.2 |
| G02 | 5.8 | 1.2 | 0.1 | 0.9 | 1.4 | 2.8 | 1.3 |
| G03 | 0.1 | 1.7 | 0.2 | 0.5 | 1.1 | 2.2 | 1.2 |
| G04 | 2.7 | 1.1 | 0.2 | 0.3 | 0.9 | 1.2 | 0.8 |
| G05 | 5.8 | 1.1 | 0.2 | 0.2 | 1.0 | 1.5 | 1.0 |
| G06 | 20.8 | 0.9 | 0.2 | 0.3 | 1.0 | 1.6 | 1.1 |
| G07 | 0.3 | 0.9 | 0.3 | 0.9 | 1.1 | 1.9 | 1.1 |
| G08 | 0.3 | 1.3 | 0.2 | 0.7 | 1.0 | 1.8 | 1.2 |
| G09 | 1,530.0 | 1.2 | 0.3 | 8.5 | 21.4 | 3.0 | 5.0 |
| G10 | 296.1 | 1.2 | 0.3 | 0.8 | 1.3 | 2.6 | 1.1 |
| G11 | 1.8 | 1.2 | 0.2 | 0.9 | 1.1 | 1.9 | 0.9 |
| G12 | 96.5 | 1.2 | 0.2 | 0.9 | 1.1 | 1.9 | 0.9 |
| G13 | 50.8 | 1.8 | 0.4 | 0.4 | 0.8 | 1.3 | 0.3 |

TABLE 17

| | | | | | | | | | | Test results | | |
|---|---|---|---|---|---|---|---|---|---|---|---|---|
| | Combination | | | | | | | | | Ti ER | SiN | SiO CN |
| | Acid | % by | Specific | % by | Specific | % by | Specific | % by | Remain- | (Å/ | (Å/ | (Å/ |
| No. | compound | mass | compound 1 | mass | compound 2 | mass | compound 3 | mass | der | min) | min) | min) |
| H01 | HF | 1.3 | HG | 68.7 | MSA | 15.0 | Lau | 2.0 | Water | 279.1 | — | — |
| H02 | HF | 1.3 | HG | 68.7 | MSA | 15.0 | Cap | 2.0 | Water | 245.3 | — | — |
| H03 | HF | 1.3 | HG | 68.7 | MSA | 15.0 | Nona | 2.0 | Water | 206.4 | 1.6 | 3.2 |
| H04 | HF | 1.3 | HG | 68.7 | MSA | 15.0 | γ-H | 2.0 | Water | 155.2 | 3.0 | 5.7 |
| H05 | HF | 1.3 | HG | 68.7 | MSA | 15.0 | 1O2P | 2.0 | Water | 175.2 | 3.3 | 8.4 |
| H06 | HF | 1.3 | HG | 68.7 | MSA | 15.0 | γ-U | 2.0 | Water | 168.5 | 4.2 | 6.9 |
| H07 | HF | 1.3 | HG | 70.7 | MSA | 15.0 | | 2.0 | Water | 62.9 | 8.1 | 8.4 |

“-” in Table means that etching did not proceed.

TABLE 18

| | | | | | | | | | | Test results | |
|---|---|---|---|---|---|---|---|---|---|---|---|
| | Combination | | | | | | | | | Ti ER | Ge |
| | Acid | % by | Specific | % by | Specific | % by | Specific | % by | Remain- | (Å/ | (Å/ |
| No. | compound | mass | compound 1 | mass | compound 2 | mass | compound 3 | mass | der | min) | min) |
| I01 | HF | 1.3 | HG | 68.7 | MSA | 15.0 | Lau | 2.0 | Water | 279.1 | 0.4 |
| I02 | HF | 1.3 | HG | 68.7 | MSA | 15.0 | Cap | 2.0 | Water | 245.3 | 0.4 |
| I03 | HF | 1.3 | HG | 68.7 | MSA | 15.0 | Nona | 2.0 | Water | 206.4 | 0.9 |
| I04 | HF | 1.3 | HG | 68.7 | MSA | 15.0 | Oc | 2.0 | Water | 185.2 | 1.1 |
| I05 | HF | 1.3 | HG | 68.7 | MSA | 15.0 | Ac | 2.0 | Water | 1,188.2 | 1.2 |
| I06 | HF | 1.3 | HG | 68.7 | MSA | 15.0 | Cap | 1.0 | Water | 362.8 | 0.7 |
| I07 | HF | 1.3 | HG | 68.7 | MSA | 15.0 | Cap | 3.0 | Water | 362.8 | 0.3 |
| I08 | HF | 1.3 | HG | 77.1 | | | DSA | 1.6 | Water | 1,846.1 | 2.0 |
| I09 | HF | 1.3 | HG | 78.2 | | | MSA | 0.5 | Water | 1,704.8 | 2.4 |
| I10 | HF | 1.3 | HG | 77.7 | | | Cap | 1.0 | Water | 1,703.5 | 1.6 |
| I11 | HF | 1.3 | HG | 78.4 | | | Ac | 0.3 | Water | 2,088.1 | 2.3 |
| I12 | HF | 1.0 | | | | | | | Water | 1,500.0 | 3.7 |
| I13 | HF | 1.3 | HG | 70.7 | MSA | 15.0 | | | Water | 62.9 | 1.3 |
| I14 | HF | 1.3 | HG | 78.7 | | | | | Water | 1,569.5 | 2.3 |
| I15 | HF | 1.4 | HG | 78.0 | | | MTAZ | 0.8 | Water | 1,041.3 | 2.4 |
| I16 | HF | 1.3 | HG | 70.7 | | | DATZ | 0.7 | Water | 1,841.1 | 2.7 |

TABLE 19

| | Combination | | | | | | |
|---|---|---|---|---|---|---|---|
| | Acid | Specific | Specific | Specific | Specific | | |
| | compound | compound 1 | compound 2 | compound 3 | compound 4 | Water | |
| Test | (content) | (content) | (content) | (content) | (content) | (content) | pH |
| J01 | HF(1.5%) | DEGBE(87.0%) | MSA(2.3%) | Ox(2.5%) | SmL(0.3%) | Remainder | 1 |
| J02 | HF(1.5%) | DEGBE(87.0%) | MSA(2.3%) | Ox(2.5%) | SmO(0.3%) | Remainder | 1 |
| J03 | HF(1.5%) | DEGBE(87.0%) | MSA(2.3%) | Ox(2.5%) | Lau(0.3%) | Remainder | 1 |
| J04 | HF(1.5%) | DEGBE(87.0%) | MSA(2.3%) | Ox(2.5%) | | Remainder | 1 |
| J05 | HF(1.5%) | DEGBE(87.0%) | MSA(2.3%) | | | Remainder | 1 |
| J06 | HF(1.5%) | DEGBE(87.0%) | | Ox(2.5%) | | Remainder | 2 |
| J07 | HF(1.5%) | DEGBE(87.0%) | | | SmL(0.3%) | Remainder | 4 |
| J08 | HF(1.5%) | DEGBE(80.0%) | | | | Remainder | 4 |
| J09 | HF(1.5%) | | | | | Remainder | 4 |

| | In-plane | Ti ER | Al ER | TiN ER | W ER | SiGe ER | Ge ER |
|---|---|---|---|---|---|---|---|
| Test | uniformity | (Å/min) | (Å/min) | (Å/min) | (Å/min) | (Å/min) | (Å/min) |
| J01 | AAA | 252.8 | 0.5 | 1.5 | 0.2 | 2.5 | 1.2 |
| J02 | — | 262.8 | 1.1 | 1.6 | 0.4 | 2.2 | 0.8 |
| J03 | — | 271.5 | 1.4 | 1.8 | 0.5 | 1.8 | 0.9 |
| J04 | AAA | 220.4 | 1.8 | 1.5 | 1.1 | 1.5 | 1.1 |
| J05 | AAA | 197.2 | 12.5 | 1.1 | 0.5 | 1.5 | 1.8 |
| J06 | AAA | 201.5 | 24.5 | 1.4 | 0.3 | 1.1 | 0.7 |
| J07 | — | 70.5 | 86.4 | 1.2 | 0.4 | 1.5 | 0.5 |
| J08 | AAA | 1397.6 | 165.3 | 0.8 | 0.1 | 2.1 | 1.5 |
| J09 | AAA | 2840.5 | 1352.5 | 1.2 | 0.3 | 3 | 5 |

| | Combination | | | | | | |
|---|---|---|---|---|---|---|---|
| | Acid | Specific | Specific | Specific | Specific | | |
| | compound | compound 1 | compound 2 | compound 3 | compound 4 | Water | |
| Test | (content) | (content) | (content) | (content) | (content) | (content) | pH |
| J01 | HF(1.5%) | DEGBE(87.0%) | MSA(2.3%) | Ox(2.5%) | SmL(0.3%) | Remainder | 1 |
| J02 | HF(1.5%) | DEGBE(87.0%) | MSA(2.3%) | Ox(2.5%) | SmO(0.3%) | Remainder | 1 |
| J03 | HF(1.5%) | DEGBE(87.0%) | MSA(2.3%) | Ox(2.5%) | Lau(0.3%) | Remainder | 1 |
| J04 | HF(1.5%) | DEGBE(87.0%) | MSA(2.3%) | Ox(2.5%) | | Remainder | 1 |
| J05 | HF(1.5%) | DEGBE(87.0%) | MSA(2.3%) | | | Remainder | 1 |
| J06 | HF(1.5%) | DEGBE(87.0%) | | Ox(2.5%) | | Remainder | 2 |
| J07 | HF(1.5%) | DEGBE(87.0%) | | | SmL(0.3%) | Remainder | 4 |
| J08 | HF(1.5%) | DEGBE(80.0%) | | | | Remainder | 4 |
| J09 | HF(1.5%) | | | | | Remainder | 4 |

| | In-plane | HfOx | HfSiOx | SiOx | SiOCN | SiN | TiAlC |
|---|---|---|---|---|---|---|---|
| Test | uniformity | (Å/min) | (Å/min) | (Å/min) | (Å/min) | (Å/min) | (Å/min) |
| J01 | AAA | 0.2 | 0.6 | 0.1 | 1.2 | 1.2 | 2.8 |
| J02 | — | 0.9 | 1 | 0.9 | 1.9 | 2.1 | 3.9 |
| J03 | — | 0.9 | 1.1 | 1.2 | 1.8 | 1.9 | 2.9 |
| J04 | AAA | 2.1 | 1.8 | 1.8 | 4.8 | 6.2 | 5.8 |
| J05 | AAA | 4.2 | 5.8 | 6.2 | 8.9 | 7.8 | 10.5 |
| J06 | AAA | 2.8 | 3.4 | 2.8 | 6.8 | 6.4 | 6.8 |
| J07 | — | 3.1 | 4.2 | 3.2 | 3.4 | 2.8 | 8.2 |
| J08 | AAA | 2.4 | 3.2 | 4.2 | 7.2 | 6.5 | 12.8 |
| J09 | AAA | 8.5 | 21.42 | 45.2 | 29.1 | 27.5 | 21.42 |

TABLE 20

| | | | | | | TiSi | | TiSiGe | |
|---|---|---|---|---|---|---|---|---|---|
| Test | Etchant | Solvent | Inhibitor | Inhibitor | Ti ER | | Ratio of | | Ratio of |
| No. | (content) | (content) | (content) | (content) | (Å/min) | (Å/min) | Ti/TiSiGe | (Å/min) | Ti/TiSiGe |
| K01 | HF(1.0%) | HG(68.7%) | PrP(1%) | | 279.1 | 2.5 | 111.6 | 1.2 | 232.6 |
| K02 | HF(1.0%) | DEGBE(68.7%) | PVP(1%) | | 245.3 | 2.4 | 102.2 | 1.3 | 188.7 |
| K03 | HF(1.0%) | HG(68.7%) | ANSA(1%) | | 206.4 | 2.8 | 73.7 | 2.2 | 93.8 |
| K04 | HF(1.0%) | DEGBE(68.7%) | PVP(1%) | HBF₄(1%) | 224.8 | 1 | 224.8 | 0.8 | 281.0 |
| K05 | HF(1.0%) | 3M1B(68.7%) | OPnP(1%) | PnP(1%) | 365.2 | 1.8 | 202.9 | 1.2 | 304.3 |
| K06 | HF(1.0%) | HG(68.7%) | DBNA(1%) | | 284.2 | 3 | 94.7 | 3.1 | 91.7 |
| K07 | HF(1.0%) | HG(68.7%) | ADPNA(1%) | | 221.2 | 4.2 | 52.7 | 2.5 | 88.5 |
| K08 | HF(1.0%) | 1,4-BD(77.07%) | DDNA(1%) | | 265.3 | 3.5 | 75.8 | 2.8 | 94.8 |
| K09 | HF(1.0%) | HG(78.22%) | LPS(1%) | | 220.1 | 3.4 | 64.7 | 2.5 | 88.0 |
| K10 | HF(1.0%) | DEGBE(77.70%) | PrP(1%) | | 240.2 | 1.5 | 160.1 | 1.5 | 160.1 |
| K11 | HF(1.0%) | HG(78.40%) | PVP(1%) | PrP(1%) | 320.5 | 1.4 | 228.9 | 0.9 | 356.1 |
| K12 | HF(1.0%) | 1,4-BD(77.07%) | OPnP(1%) | | 260.5 | 2.6 | 100.2 | 1.8 | 144.7 |
| K13 | HF(1.0%) | HG(78.22%) | PnP(1%) | | 200.2 | 2.7 | 74.1 | 1.6 | 125.1 |
| K14 | HF(1.0%) | DEGBE(77.70%) | PPnP(1%) | | 231.5 | 3.2 | 72.3 | 2 | 115.8 |
| K15 | HF(1.0%) | HG(78.40%) | ANSA(1%) | HBF₄(1%) | 360.1 | 4.2 | 85.7 | 3.4 | 105.9 |
| K16 | HF(1.0%) | 1,4-BD(77.07%) | PPrP(1%) | | 240.2 | 3.4 | 70.6 | 1.7 | 141.3 |
| K17 | HF(1.0%) | HG(78.22%) | POAS(1%) | | 220.6 | 2.4 | 91.9 | 1.5 | 147.1 |
| K18 | HF(1.0%) | DEGBE(77.70%) | ADPNA(1%) | PnP(1%) | 301.2 | 2.8 | 107.6 | 2.4 | 125.5 |
| K19 | HF(1.0%) | HG(78.40%) | POAS(1%) | HBF₄(1%) | 290.5 | 1.2 | 242.1 | 0.8 | 363.1 |
| K20 | HF(1.0%) | | | | 1500 | 340.1 | 4.4 | 150.3 | 10.0 |
| K21 | HF(1.3%) | HG(85.7%) | | | 1153.5 | 41.5 | 27.8 | 36.2 | 31.9 |
| K22 | HF(1.3%) | DEGBE(78.7%) | | | 1569.5 | 120.58 | 13.0 | 60.2 | 26.1 |

The present Table shows that TiSi and TiSiGe respectively represent titanium silicide of Si and SiGe.

From the results of the above Table, it is understood that excellent selectivity of etching can be obtained even in a compound to which a sulfonic acid compound (third group) is added. Further, it is confirmed that a carboxylic acid compound, an ester compound, a pyrrolidone compound, a lactone compound, a phosphoric acid compound, a phosphonic acid compound, and a boron-containing acid compound exhibit the effects as the compounds of the second group.

### Example 3

### Preparation of Test Substrate

Ge was epitaxially grown to be formed to have a film thickness of 500 Å on a commercially available silicon substrate (diameter: 12 inches). In the same manner, a blank wafer in which a Pt/Ni (10/90 [mass]) film was created by CVD or the like was prepared next to a Ge film.

(Etching Test)

The etching was performed under the following conditions in a sheet type device (POLOS (trade name), manufactured by SPS-Europe B. V.) with respect to the blank wafer and the substrate for a test and an evaluation test was carried out.
Treatment temperature: listed in Tables
Ejection amount: 1 L/min.
Wafer rotation speed: 500 rpm
Nozzle movement speed: 7 cm/S

Further, the etching liquid was supplied by being separated into two liquids as described below to be line mixed (see FIG. 3). A supply line fc was heated such that the temperature thereof was adjusted. It does not take much time from the mixture of two liquids to provision of the mixed solution for the substrate and this means that the mixed solution iss provided for the substrate immediately after the mixing.

First liquid (A): nitric and water

Second liquid (B): other components and water as needed

The ratio of the first liquid to the second liquid was set such that the amounts thereof were substantially the same as each other in terms of the volume. According to the formulation, the amount was suitably adjusted or supply was performed only with one liquid.

(Method of Measuring Treatment Temperature)

A radiation thermometer IT-550F (trade name, manufactured by HORIBA, Ltd.) was fixed to a position having a height of 30 cm on a wafer in the sheet type device. The thermometer was directed to the surface of the wafer outside from the center thereof by a distance of 2 cm and the temperature was measured while circulating a liquid chemical. The temperature was continuously recorded using a computer through digital output from the radiation thermometer. Among these, a value obtained by averaging the recorded values of the temperature for 10 seconds at the time when the temperature thereof was stabilized was set as a temperature on the wafer.

(Etching Rate)

The etching rate (ER) was calculated by measuring the film thickness before or after the etching treatment using Ellipsometry (VASE Spectroscopic ellipsometer was used, J. A. Woollam, Japan). The average value of five points was adopted (measurement condition measurement range: 1.2 eV to 2.5 eV, measuring angles: 70 degrees and 75 degrees).

TABLE 21

| | Components of liquid chemical | | | | | | | | | |
|---|---|---|---|---|---|---|---|---|---|---|
| | Component 1 | | Component 2 | | Component 3 | | Nitric acid | | Sulfonic acid 1 | |
| | | % by | | % by | | % by | | % by | | % by |
| No. | Compound | mass | Compound | mass | Compound | mass | Compound | mass | Compound | mass |
| 101 | TMACl | 3.4 | — | — | — | — | HNO₃ | 6.5 | MSA | 51.0 |
| 102 | HCl | 0.5 | — | — | — | — | TMA-NO₃ | 15.5 | MSA | 52.1 |
| 103 | TEACI | 4.4 | — | — | — | — | HNO₃ | 7.2 | MSA | 40.7 |
| 104 | TBACI | 6.5 | — | — | — | — | HNO₃ | 9.2 | MSA | 56.1 |
| 105 | HBr | 0.1 | HCl | 0.5 | a-5 | 0.05 | HNO₃ | 7.1 | MSA | 60.0 |
| 106 | TMABr | 4.1 | HCl | 0.2 | — | — | HNO₃ | 6.0 | MSA | 58.0 |
| 107 | TEABr | 3.1 | HCl | 0.1 | — | — | HNO₃ | 8.2 | MSA | 61.6 |
| 108 | TPABr | 4.6 | HCl | 0.1 | — | — | HNO₃ | 6.4 | MSA | 51.2 |
| 109 | TBABr | 8.2 | HCl | 0.1 | — | — | HNO₃ | 5.4 | MSA | 40.5 |
| 110 | TBABr | 9.5 | — | — | — | — | HNO₃ | 6.4 | MSA | 58.2 |
| 111 | TPABr | 7.2 | — | — | — | — | HNO₃ | 5.4 | MSA | 55.1 |
| 112 | TPACl | 5.0 | — | — | — | — | HNO₃ | 8.4 | MSA | 63.5 |
| 113 | HCl | 0.7 | — | — | a-1 | 0.10 | HNO₃ | 8.7 | MSA | 59.4 |
| 114 | HCl | 0.6 | — | — | a-2 | 0.05 | HNO₃ | 7.8 | MSA | 50.1 |
| 115 | HCl | 0.8 | — | — | a-3 | 0.02 | HNO₃ | 7.4 | MSA | 62.5 |
| 116 | HCl | 0.5 | — | — | a-4 | 0.05 | HNO₃ | 8.6 | MSA | 50.8 |
| 117 | HCl | 0.8 | — | — | a-5 | 0.04 | HNO₃ | 7.5 | MSA | 52.4 |
| 118 | HCl | 1.0 | — | — | a-6 | 0.06 | HNO₃ | 7.9 | MSA | 58.4 |
| 119 | HCl | 0.9 | — | — | a-7 | 0.02 | HNO₃ | 8.4 | MSA | 51.5 |
| 120 | HCl | 0.9 | — | — | a-8 | 0.05 | HNO₃ | 8.8 | MSA | 60.1 |
| 121 | HCl | 0.7 | — | — | a-9 | 0.10 | HNO₃ | 9.2 | MSA | 48.5 |
| 122 | HCl | 0.6 | — | — | a-10 | 0.08 | HNO₃ | 8.9 | MSA | 62.4 |
| 123 | HCl | 0.8 | — | — | a-11 | 0.12 | HNO₃ | 8.5 | MSA | 61.4 |
| 124 | HCl | 0.5 | — | — | a-12 | 0.20 | HNO₃ | 7.8 | MSA | 58.7 |
| 125 | HBr | 0.6 | — | — | a-2 | 0.07 | HNO₃ | 8.4 | MSA | 58.7 |
| 126 | TMACl | 0.7 | — | — | a-8 | 0.30 | HNO₃ | 8.5 | MSA | 56.7 |
| 127 | HCl | 0.9 | — | — | a-3 | 0.05 | HNO₃ | 6.9 | PTSA | 50.4 |
| 128 | HCl | 1.2 | — | — | a-12 | 0.07 | HNO₃ | 7.4 | MSA | 60.0 |
| 129 | TMBzCl | 5.2 | — | — | — | — | HNO₃ | 5.1 | MSA | 59.7 |
| 130 | TMBzBr | 4.1 | — | — | — | — | HNO₃ | 4.5 | MSA | 62.4 |
| 131 | HCl | 0.4 | — | — | a-10 | 0.05 | HNO₃ | 6.1 | MSA | 62.4 |
| 132 | HCl | 0.5 | HBr | 0.4 | a-6 | 0.05 | HNO₃ | 8.6 | MSA | 65.4 |
| 133 | HCl | 0.3 | — | — | a-10 | 0.04 | HNO₃ | 8.5 | MSA | 70.2 |
| 134 | HCl | 0.6 | TBABr | 0.5 | a-4 | 0.05 | HNO₃ | 8.7 | MSA | 58.3 |

| | Components of liquid chemical | | | | | | | |
|---|---|---|---|---|---|---|---|---|
| | Sulfonic | | Concen- | | | Evaluation results | | |
| | acid 2 | | tration | Water | | NiPt ER | Ge ER | Selection |
| | | % by | of cation | % by | Treatment | (Å/ | (Å/ | ratio of |
| No. | Compound | mass | mol/L | mass | conditions | min) | min) | NiPt/Ge ER |
| 101 | — | — | 3.1E−02 | Remainder | 30° C./5 min. | 280 | 21 | 13.3 |
| 102 | — | — | 1.1E−01 | Remainder | 30° C./5 min. | 240 | 20 | 12.0 |
| 103 | — | — | 3.9E−02 | | 30° C./5 min. | 321 | 8 | 40.1 |
| 104 | — | — | 2.3E−02 | Remainder | 30° C./5 min. | 281 | 0.9 | 312.2 |
| 105 | — | — | 1.4E−04 | Remainder | 30° C./5 min. | 305 | 0.5 | 610.0 |
| 106 | — | — | 2.7E−02 | Remainder | 30° C./5 min. | 330 | 17 | 19.4 |
| 107 | — | — | 1.5E−02 | Remainder | 30° C./5 min. | 290 | 6 | 48.3 |
| 108 | — | — | 1.7E−02 | Remainder | 30° C./5 min. | 345 | 1.1 | 313.6 |
| 109 | — | — | 2.5E−02 | Remainder | 30° C./5 min. | 350 | 0.8 | 437.5 |
| 110 | — | — | 2.9E−02 | Remainder | 30° C./5 min. | 192 | 0.5 | 384.0 |
| 111 | — | — | 2.7E−02 | Remainder | 30° C./5 min. | 221 | 0.4 | 552.5 |
| 112 | — | — | 2.3E−02 | Remainder | 30° C./5 min. | 264 | 1.2 | 220.0 |
| 113 | — | — | 3.5E−04 | Remainder | 30° C./5 min. | 298 | 0.6 | 496.7 |
| 114 | — | — | 1.5E−04 | Remainder | 30° C./5 min. | 302 | 0.7 | 431.4 |
| 115 | — | — | 7.6E−05 | Remainder | 30° C./5 min. | 341 | 0.9 | 378.9 |
| 116 | — | — | 1.6E−04 | Remainder | 30° C./5 min. | 284 | 0.5 | 568.0 |
| 117 | — | — | 1.1E−04 | Remainder | 30° C./5 min. | 246 | 1.2 | 205.0 |
| 118 | — | — | 1.7E−04 | Remainder | 30° C./5 min. | 256 | 0.9 | 284.4 |
| 119 | — | — | 4.8E−05 | Remainder | 30° C./5 min. | 286 | 1.5 | 190.7 |
| 120 | — | — | 8.8E−05 | Remainder | 30° C./5 min. | 264 | 1.1 | 240.0 |
| 121 | — | — | 1.7E−04 | Remainder | 30° C./5 min. | 291 | 1.4 | 207.9 |
| 122 | — | — | 2.4E−04 | Remainder | 30° C./5 min. | 302 | 1.3 | 232.3 |
| 123 | — | — | 2.6E−04 | Remainder | 30° C./5 min. | 287 | 0.8 | 358.8 |
| 124 | — | — | 6.3E−04 | Remainder | 30° C./5 min. | 291 | 0.9 | 323.3 |
| 125 | — | — | 2.1E−04 | Remainder | 30° C./5 min. | 302 | 1.4 | 215.7 |
| 126 | — | — | 6.9E−03 | Remainder | 30° C./5 min. | 315 | 0.6 | 525.0 |
| 127 | — | — | 1.9E−04 | Remainder | 30° C./5 min. | 320 | 1.2 | 266.7 |
| 128 | PTSA | 5.0 | 2.2E−04 | Remainder | 30° C./5 min. | 287 | 0.5 | 574.0 |
| 129 | — | — | 2.8E−02 | Remainder | 30° C./5 min. | 302 | 0.9 | 335.6 |
| 130 | — | — | 1.8E−02 | Remainder | 30° C./5 min. | 332 | 1.1 | 301.8 |
| 131 | — | — | 1.5E−04 | Remainder | 30° C./5 min. | 540 | 10.2 | 52.9 |
| 132 | — | — | 1.4E−04 | Remainder | 30° C./5 min. | 320 | 0.9 | 355.6 |
| 133 | — | — | 1.2E−04 | Remainder | 30° C./5 min. | 462 | 1.2 | 385.0 |
| 134 | — | — | 1.7E−03 | Remainder | 30° C./5 min. | 311 | 1.5 | 207.3 |

<Notes of in Table>
HCl: hydrochloric acid
TMACl: tetramethyl ammonium chloride
TEACl: tetraethyl ammonium chloride
TPACl: tetrapropyl ammonium chloride
TBACl: tetrabutyl ammonium chloride
HBr: hydrobromic acid
TMABr: tetramethyl ammonium bromide
TEABr: tetraethyl ammonium bromide
TPABr: tetrapropyl ammonium bromide
TEABr: tetraethyl ammonium bromide
TBABr: tetrabutyl ammonium bromide
TMBzCl: trimethyl benzyl ammonium chloride
TMBzBr: trimethyl benzyl ammonium bromide
HNO₃: nitric acid
TMA-NO₃: tetramethyl ammonium nitrate
MSA: methanesulfonic acid
PTSA: p-toluenesulfonic acid
a-1: lauryl pyridinium chloride
a-2: cetyl pyridinium chloride
a-3: lauryl trimethyl ammonium chloride
a-4: hexadecyl trimethyl ammonium chloride
a-5: octadecyl trimethyl ammonium chloride
a-6: didecyl dimethyl ammonium chloride
a-7: dilauryl dimethyl ammonium chloride
a-8: distearyl dimethyl ammonium chloride
a-9: dioleyl dimethyl ammonium chloride
a-10: lauryl dimethyl benzyl ammonium chloride
a-11: cetyl trimethyl ammonium saccharin
a-12: cetyl trimethyl ammonium chloride

Test No. 101 and the like which are the same as in Table 21 are also present in Table 1, but these are distinguished from each other as individual tests for each of Examples. The same applies to Table 22 below.

From the results described above, it is understood that excellent selectivity of etching with respect to the metal layer, in which damage of the Ge-containing layer is suppressed, and can be obtained by adding a small amount of organic cation to the etching liquid containing a halogen ion, nitric acid, and a sulfonic acid compound. Further, when an organic cation having 5 or more carbon atoms or an organic cation having 8 or more carbon atoms is used, the selectivity is remarkably improved.

In addition, a Pt/Ni (10/90 [mass]) layer was formed on the Ge epitaxial layer. The formed layer was annealed at 800° C. for 10 seconds and a Ge silicide layer (NiPtGe) was formed to be used as a test substrate. The thickness of the annealed silicide layer was 15 nm and the thickness of the metal layer was 5 nm.

When the liquid chemicals Nos. 101 to 134 were used for the test substrate, it was confirmed that excellent etching properties of the metal layer and protection of the Ge silicide layer were realized.

### Example 4 and Comparative Example 2

### Preparation of Test Substrate

SiGe was epitaxially grown to be formed to have a film thickness of 500 Å on a commercially available silicon substrate (diameter: 12 inches). In the same manner, blank wafers created by CVD or the like were prepared for other films. At this time, the SiGe epitaxial layer contained 50% by mass to 60% by mass of germanium. In test results shown in Tables below, the etching rates of respective layers were calculated using these blank wafers.

Further, a layer of Ti was formed on the SiGe epitaxial layer. The layer was annealed at 800° C. for 10 seconds and a silicide layer was formed to be used as a test substrate. The thickness of the annealed silicide layer was 15 nm and the thickness of the metal layer was 5 nm.

(Etching Test)

The etching was performed under the following conditions in a sheet type device (POLOS (trade name), manufactured by SPS-Europe B. V.) with respect to the blank wafer and the substrate for a test and an evaluation test was carried out.
Treatment temperature: 24° C. room temperature
Ejection amount: 1 L/min.
Wafer rotation speed: 500 rpm
Nozzle movement speed: 7 cm/S

Further, the etching liquid was supplied with one liquid (using only A-line in FIG. 3). Respective treatment tests were performed immediately after the liquid preparation.

(Method of Measuring Treatment Temperature)

A radiation thermometer IT-550F (trade name, manufactured by HORIBA, Ltd.) was fixed to a position having a height of 30 cm on a wafer in the sheet type device. The thermometer was directed to the surface of the wafer outside from the center thereof by a distance of 2 cm and the temperature was measured while circulating a liquid chemical. The temperature was continuously recorded using a computer through digital output from the radiation thermometer. Among these, a value obtained by averaging the recorded values of the temperature for 10 seconds at the time when the temperature thereof was stabilized was set as a temperature on the wafer.

(Etching Rate [ER])

The etching rate (ER) was calculated by measuring the film thickness before or after the etching treatment using Ellipsometry (VASE Spectroscopic ellipsometer was used, J. A. Woollam, Japan). The average value of five points was adopted (measurement condition measurement range: 1.2 eV to 2.5 eV, measuring angles: 70 degrees and 75 degrees).

(Damage of TiSiGe)

The level of damage of the germanium silicide layer (TiSiGe) was determined from the amount of change in the sheet resistance before or after the etching treatment and the thickness of TiSiGe in etching ESCA. Evaluations A to E were defined using the following formula depending on the percentage of the thickness of the TiSiGe layer in ESCA that was lost compared to the initial state of the layer.

TiSiGe damage (%)=(TiSiGe thickness after treatment of liquid chemical/thickness of TiSiGe before treatment of liquid chemical)×100

A: greater than 80 to 100

B: greater than 60 to 80

C: greater than 40 to 60

D: greater than 20 to 40

E: greater than 0 to 20

Further, A⁻ was evaluated as A, but slightly worse.

TABLE 22

| | | | | | | | | Etching rate (Å/min) | | | | | | | TiSiGe |
|---|---|---|---|---|---|---|---|---|---|---|---|---|---|---|---|
| No. | (A) | (B) | (C) | (D) | (E) | (F) | (G) | TiER | AlER | SiO₂ER | SiNER | SiOCER | HfO₂ER | TiAlCER | damage |
| 101 | HF | H₂O | DEGBE | HBF₄ | Oxalic acid | SA | | 225.8 | 0.8 | 0.9 | 0.8 | 1 | 0.7 | 1.9 | A |
| | 1.3 | 7 | 87.2 | 1.8 | 2.5 | 0.2 | | | | | | | | | |
| 102 | HF | H₂O | DEGBE | HBF₄ | Oxalic acid | LA | | 220.8 | 1.2 | 0.5 | 0.96 | 1 | 1 | 2.8 | A |
| | 1.3 | 15 | 79.2 | 1.8 | 2.5 | 0.2 | | | | | | | | | |
| 103 | HF | H₂O | DEGBE | HBF₄ | Oxalic acid | DHC | | 210.8 | 0.8 | 0.3 | 3.8 | 2.8 | 0.8 | 3.6 | A |
| | 1.3 | 7 | 87.2 | 1.8 | 2.5 | 0.2 | | | | | | | | | |
| 104 | HF | H₂O | DEGBE | HBF₄ | Oxalic acid | Lib | | 238.5 | 1.5 | 0.8 | 3.2 | 4.1 | 6.8 | 8.8 | A |
| | 1.3 | 7 | 87.2 | 1.8 | 2.5 | 0.2 | | | | | | | | | |
| 105 | HF | H₂O | DEGBE | HBF₄ | Oxalic acid | DHC | Stearic acid | 248.2 | 0.8 | 0.1 | 0.8 | 0.5 | 0.8 | 0.9 | A |
| | 1.3 | 7 | 87.1 | 1.8 | 2.5 | 0.2 | 0.1 | | | | | | | | |
| 106 | HF | H₂O | DEGBE | HBF₄ | Oxalic acid | | | 308.5 | 1.2 | 2.2 | 2.8 | 2.9 | 1.2 | 7.4 | A⁻ |
| | 1.3 | 7 | 87.4 | 1.8 | 2.5 | | | | | | | | | | |
| 107 | HF | H₂O | DEGBE | HBr | Oxalic acid | | | 273.5 | 10.8 | 3.2 | 6.2 | 7.4 | 1.1 | 10.2 | B |
| | 1.3 | 7 | 86.7 | 2.5 | 2.5 | | | | | | | | | | |
| 108 | HF | H₂O | DEGBE | HBr | Oxalic acid | HBF₄ | | 305.2 | 0.5 | 1.8 | 2.2 | 2.85 | 1 | 8.6 | A |
| | 1.3 | 7 | 86.2 | 2.5 | 2.5 | 0.5 | | | | | | | | | |
| 109 | HF | H₂O | DEGBE | HBr | Oxalic acid | HBF₄ | PAA | 280.5 | 0.5 | 0.8 | 0.9 | 0.8 | 0.7 | 5.4 | A |
| | 1.3 | 7 | 86 | 2.5 | 2.5 | 0.5 | 0.2 | | | | | | | | |
| 110 | HF | H₂O | DEGBE | HCl | Oxalic acid | | | 304.5 | 18.5 | 3.5 | 5.8 | 5.5 | 1.6 | 12.5 | C |
| | 1.3 | 7 | 88.4 | 0.8 | 2.5 | | | | | | | | | | |
| 111 | HF | H₂O | DEGBE | HCl | Oxalic acid | HBF₄ | | 325.2 | 1.8 | 1.6 | 2.8 | 3.1 | 1.2 | 10.5 | B |
| | 1.3 | 7 | 87.9 | 0.8 | 2.5 | 0.5 | | | | | | | | | |
| c01 | HF | H₂O | DEGBE | | Oxalic acid | | | 324.5 | 105.2 | 5.1 | 8.6 | 12.5 | 4.8 | 15.8 | E |
| | 1 | 15 | 81.5 | | 2.5 | | | | | | | | | | |

<Notes in Table>
DHC: dehydrochloic acid
LA: lauric acid
SA: stearic acid
Lib: ribose
DEGBE: diethylene glycol monobutyl ether

Lower stages of respective components show blending amounts (% by mass).

A component having a negative etching rate was not etched and appeared to be thicker.

As understood from the results of the above Table, according to the etching liquid of the present invention, it is confirmed that the etching rate of Ti is high and thus Ti can be selectively etched by suppressing the etching rates of Al, SiO₂, SiN, SiOC, HfO₂, and TiAlC to be low. Further, it is understood that the etching liquid of the present invention can contribute to improvement of the performance of a device because damage of TiSiGe can be suppressed.

Moreover, the results of Table 20 above are significant as the results of Example 4. That is, it is understood that a phosphoric acid compound, a boron-containing acid compound, or a phosphonic acid compound is effective as an acid assistant. Further, it is understood that excellent effects are shown in various kinds of organic solvents.

### EXPLANATION OF REFERENCES

1: metal layer (second layer)
2: germanium-containing layer (first layer)
3: germanium silicide layer (third layer)
11: treatment container (treatment tank)
12: rotary table
13: ejection opening
14: junction point
S: substrate
21: silicon substrate
22: gate insulating film
23: gate electrode
25: side wall
26: source electrode
27: drain electrode
28: NiPt film
90A, 90B: replacement gate stack
92A, 92B: well
94A, 94B: source/drain extension region
96A, 96B: source/drain region
91A, 91B: metal semiconductor alloy portion
95A, 95B: gate spacer
97A, 97B: gate insulting film
81: first work function material layer
82A, 82B: second work function material layer
83A, 83B: metal portion
93: trench structure portion
99: flattened dielectric layer

The present invention has been described with reference to the embodiments, but the detailed description of the invention is not limited unless otherwise noted and the present invention should be broadly interpreted without departing from the spirit and the scope described in the aspects of the invention.

What is claimed is:

1. An etching method of a semiconductor substrate that includes a first layer containing germanium and a second layer containing at least one metal selected from nickel platinum, titanium, nickel, and cobalt, the method comprising:
bringing an etching liquid which contains the following acid compounds into contact with the second layer and selectively removing the second layer.
Acid compounds: at least one compound selected from halogen acid and a salt thereof; hexafluorosilicic acid and a salt thereof; tetrafluoroboric acid and a salt thereof, and hexafluorophosphoric acid and a salt thereof

2. The etching method according to claim 1, wherein the concentration of germanium of the first layer is 40% by mass or greater.

3. The etching method according to claim 1, further comprising:
applying a heat treatment to at least one of the first layer and the second layer before or after etching with the etching liquid.

4. The etching method according to claim 1, wherein the second layer is selectively removed with respect to the first layer and the following third layer.
Third layer: layer containing germanium interposed between the first layer and the second layer and component metals of the second layer

5. The etching method according to claim 1,
wherein the semiconductor substrate further includes a fourth layer containing at least one of TiN, Al, AlO, W, WOx, HfOx, HfSiOx, SiN, SiOCN, and TiAlC, and
the second layer is selectively removed also with respect to the fourth layer.

6. The etching method according to claim 1, wherein, with respect to removal components of the second layer, a removal aspect I which singly uses the acid compounds and a removal aspect II which combines the acid compounds and an oxidant and uses the combination are selectively used.

7. The etching method according to claim 1, wherein the temperature of the etching liquid at the time of being brought into contact with the second layer is in the range of 10° C. to 80° C.

8. The etching method according to claim 1, wherein the time required for etching one substrate is in the range of 10 seconds to 300 seconds.

9. The etching method according to claim 1, further comprising:
a step of washing the semiconductor substrate with water at least before or after the etching.

10. The etching method according to claim 1,
wherein the etching liquid further contains an oxidant, and
a first liquid which does not contain the oxidant and a second liquid which contains the oxidant are divided from each other and then stored.

11. The etching method according to claim 10, wherein the first liquid and the second liquid are mixed with each other at a suitable time when the semiconductor substrate is etched.

12. The etching method according to claim 1, wherein the etching liquid further contains the following organic additive.
Organic additive: an additive formed of an organic compound which contains a nitrogen atom, a sulfur atom, a phosphorous atom, or an oxygen atom

13. The etching method according to claim 12, wherein the organic additive is formed of a compound represented by any of the following Formulae (I) to (XIII), a phosphoric acid compound, a boron-containing acid compound, or a phosphonic acid compound. 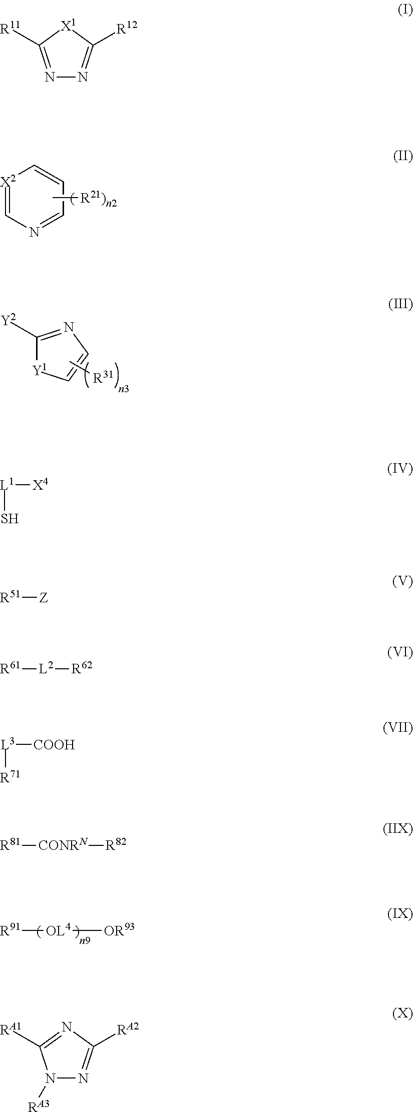 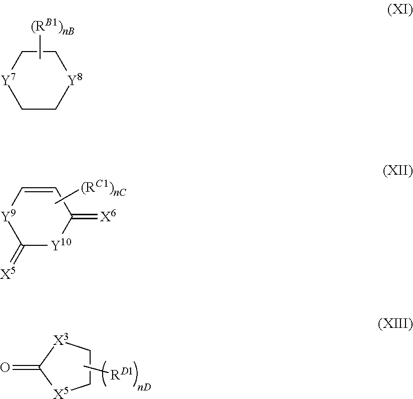
Formula (I): R¹¹ and R¹² each independently represent a hydrogen atom, an alkyl group, an alkenyl group, an alkynyl group, an aryl group, an aralkyl group, a sulfanyl group, a hydroxy group, or an amino group. X¹ represents a methylene group, a sulfur atom, or an oxygen atom.
Formula (II): X² represents a methine group or a nitrogen atom. R²¹ represents a substituent. n2 represents an integer of 0 to 4. When a plurality of R²¹'s are present, R²¹'s may be the same as or different from each other and may be bonded or condensed to each other to form a ring.
Formula (III): Y¹ represents a methylene group, an imino group, or a sulfur atom. Y² represents a hydrogen atom, an alkyl group, an alkenyl group, an alkynyl group, an aryl group, an aralkyl group, an amino group, a hydroxy group, or a sulfanyl group. R³¹ represents a substituent. n3 represents an integer of 0 to 2. When a plurality of R³¹'s are present, R³¹'s may be the same as or different from each other and may be bonded or condensed to each other to form a ring.
Formula (IV): L¹ represents an alkylene group, an alkynylene group, an alkenylene group, an arylene group, or an aralkylene group. X⁴ represents a carboxyl group or a hydroxy group.
Formula (V): R⁵¹ represents an alkyl group, an alkenyl group, an alkynyl group, an aryl group, or an aralkyl group. Z represents an amino group, a sulfonic acid group, a sulfuric acid group, a phosphoric acid group, a carboxyl group, a hydroxy group, a sulfanyl group, an onium group, an acyloxy group, or an amine oxide group.
Formula (VI): R⁶¹ and R⁶² each independently represent an alkyl group, an aryl group, an alkoxy group, or an alkylamino group. R⁶¹ and R⁶² may be bonded or condensed to each other to form a ring. L² represents a carbonyl group, a sulfinyl group, or a sulfonyl group.
Formula (VII): R⁷¹ represents an amino group, an ammonium group, or a carboxyl group. L³ represents a hydrogen atom or the same group as that for L¹.
Formula (IIX): R⁸¹ and R⁸² each independently represent an alkyl group, an alkenyl group, an alkynyl group, an aryl group, or an aralkyl group. R^{N} represents a hydrogen atom or a substituent.
Formula (IX): L⁴ represents the same group as that for L¹. R⁹¹ and R⁹³ each independently represent a hydrogen atom, an alkyl group, an alkenyl group, an alkynyl group, an aryl group, an acyl group, or an aralkyl group. n9 represents an integer of 0 to 15. In this case, when n9 represents 0, both of R⁹¹ and R⁹³ do not represent a hydrogen atom.
Formula (X): R^{A3} has the same definition as that for R^{N}. R^{A1} and R^{A2} each independently represent a hydrogen atom, an alkyl group, an alkenyl group, an alkynyl group, an aryl group, an aralkyl group, a sulfanyl group, a hydroxy group, or an amino group.
Formula (XI): Y⁷ and Y⁸ each independently represent an oxygen atom, a sulfur atom, a methylene group, an imino group, or a carbonyl group. R^{B1} represents a substituent. nB represents an integer of 0 to 8.
Formula (XII): Y⁹ and Y¹⁰ each independently represent an oxygen atom, a sulfur atom, a methylene group, an imino group, or a carbonyl group. X⁵ and X⁶ each independently represent a sulfur atom or an oxygen atom. The broken line means that the bond may be a single bond or a double bond. R^{C1} represents a substituent. nC represents an integer of 0 to 2.
Formula (XIII): X³ represents an oxygen atom, a sulfur atom, or an imino group. X⁵ represents an oxygen atom, a sulfur atom, an imino group, or a methylene group. R^{D1} represents a substituent. nD represents an integer of 0 to 4.

14. The etching method according to claim 6, wherein an organic additive selected from Formulae (V) to (IX), (XI), and (XIII), a phosphoric acid compound, a boron-containing acid compound, or a phosphonic acid compound formulae is used in the case of the removal aspect I and an organic additive selected from Formula (I) to (VII), (X), and (XIII) is used in the case of the removal aspect II.

15. An etching liquid of a semiconductor substrate that includes a first layer containing germanium and a second layer containing metals other than germanium,
wherein the etching liquid is for selectively removing the second layer, and
the second layer is removed by bringing the etching liquid containing the following acid compounds and the following organic additive into contact with the second layer.
Acid compounds: at least one compound selected from halogen acid and a salt thereof; hexafluorosilicic acid and a salt thereof; tetrafluoroboric acid and a salt thereof, and hexafluorophosphoric acid and a salt thereof
Organic additive: an additive formed of an organic compound which contains a nitrogen atom, a sulfur atom, a phosphorous atom, or an oxygen atom

16. The etching liquid according to claim 15, wherein the second layer contains at least one metal selected from nickel platinum, titanium, nickel, and cobalt.

17. The etching liquid according to claim 15, wherein the concentration of the acid compound is in the range of 0.01% by mass to 10% by mass.

18. The etching liquid according to claim 15, wherein the organic additive is formed of a compound represented by any of the following Formulae (I) to (XIII), a phosphoric acid compound, a boron-containing acid compound, or a phosphonic acid compound. 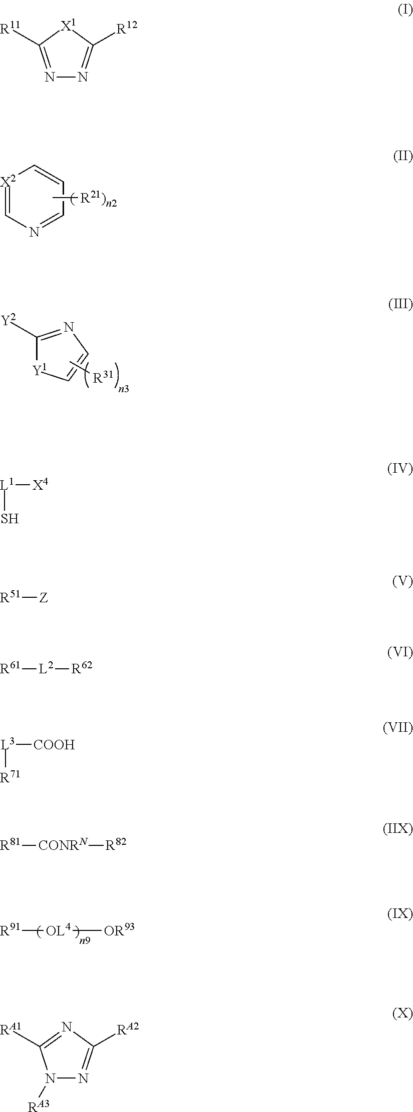 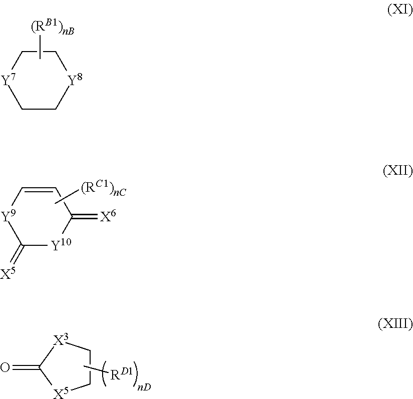
Formula (I): R¹¹ and R¹² each independently represent a hydrogen atom, an alkyl group, an alkenyl group, an alkynyl group, an aryl group, an aralkyl group, a sulfanyl group, a hydroxy group, or an amino group. X¹ represents a methylene group, a sulfur atom, or an oxygen atom.
Formula (II): X² represents a methine group or a nitrogen atom. R²¹ represents a substituent. n2 represents an integer of 0 to 4. When a plurality of R²¹'s are present, R²¹'s may be the same as or different from each other and may be bonded or condensed to each other to form a ring.
Formula (III): Y¹ represents a methylene group, an imino group, or a sulfur atom. Y² represents a hydrogen atom, an alkyl group, an alkenyl group, an alkynyl group, an aryl group, an aralkyl group, an amino group, a hydroxy group, or a sulfanyl group. R³¹ represents a substituent. n3 represents an integer of 0 to 2. When a plurality of R³¹'s are present, R³¹'s may be the same as or different from each other and may be bonded or condensed to each other to form a ring.
Formula (IV): L¹ represents an alkylene group, an alkynylene group, an alkenylene group, an arylene group, or an aralkylene group. X⁴ represents a carboxyl group or a hydroxy group.
Formula (V): R⁵¹ represents an alkyl group, an alkenyl group, an alkynyl group, an aryl group, or an aralkyl group. Z represents an amino group, a sulfonic acid group, a sulfuric acid group, a phosphoric acid group, a carboxyl group, a hydroxy group, a sulfanyl group, an onium group, an acyloxy group, or an amine oxide group.
Formula (VI): R⁶¹ and R⁶² each independently represent an alkyl group, an aryl group, an alkoxy group, or an alkylamino group. R⁶¹ and R⁶² may be bonded or condensed to each other to form a ring. L² represents a carbonyl group, a sulfinyl group, or a sulfonyl group.
Formula (VII): R⁷¹ represents an amino group, an ammonium group, or a carboxyl group. L³ represents a hydrogen atom or the same group as that for L¹.
Formula (IIX): R⁸¹ and R⁸² each independently represent an alkyl group, an alkenyl group, an alkynyl group, an aryl group, or an aralkyl group. R^{N} represents a hydrogen atom or a substituent.
Formula (IX): L⁴ represents the same group as that for L¹. R⁹¹ and R⁹³ each independently represent a hydrogen atom, an alkyl group, an alkenyl group, an alkynyl group, an aryl group, an acyl group, or an aralkyl group. n9 represents an integer of 0 to 15. In this case, when n9 represents 0, both of R⁹¹ and R⁹³ do not represent a hydrogen atom.
Formula (X): R^{A3} has the same definition as that for R^{N}. R^{A1} and R^{A2} each independently represent a hydrogen atom, an alkyl group, an alkenyl group, an alkynyl group, an aryl group, an aralkyl group, a sulfanyl group, a hydroxy group, or an amino group.
Formula (XI): Y⁷ and Y⁸ each independently represent an oxygen atom, a sulfur atom, a methylene group, an imino group, or a carbonyl group. R^{B1} represents a substituent. nB represents an integer of 0 to 8.
Formula (XII): Y⁹ and Y¹⁰ each independently represent an oxygen atom, a sulfur atom, a methylene group, an imino group, or a carbonyl group. X⁵ and X⁶ each independently represent a sulfur atom or an oxygen atom. The broken line means that the bond may be a single bond or a double bond. R^{C1} represents a substituent. nC represents an integer of 0 to 2.
Formula (XIII): X³ represents an oxygen atom, a sulfur atom, or an imino group. X⁵ represents an oxygen atom, a sulfur atom, an imino group, or a methylene group. R^{D1} represents a substituent. nD represents an integer of 0 to 4.

19. The etching liquid according to claim 15, wherein, with respect to removal components of the second layer, a removal aspect I which singly uses the acid compounds and a removal aspect II which combines the acid compounds and an oxidant and uses the combination are selectively used.

20. The etching liquid according to claim 19, wherein an organic additive selected from Formulae (V) to (IX), (XI), and (XIII), a phosphoric acid compound, a boron-containing acid compound, or a phosphonic acid compound formulae is used in the case of the removal aspect I and an organic additive selected from Formulae (I) to (VII), (X), and (XIII) is used in the case of the removal aspect II.

21. The etching liquid according to claim 15, wherein the organic additive is formed of a compound selected from the following first group or second group.
TABLE A
First group

| | |
|---|---|
| Sulfolane | Sulfolane |
| DMSO | Dimethyl sulfoxide |
| XAN | Cyclohexanone |
| MEK | Methyl ethyl ketone |
| DEGDM | Diethylene glycol dimethyl ether |
| DEGDE | Diethylene glycol diethyl ether |
| ACE | Ethyl acetate |
| MPM | Methyl 3-methoxypropionate |
| γ-BL | γ butyrolactone |
| NMP | N-methylpyrrolidone |
| DMAA | NN-dimethylacetamide |
| DIO | 1,4-dioxane |
| EC | Ethylene carbonate |
| PC | Propylene carbonate |
| MSA | Methanesulfonic acid |
| PPG | Polypropylene glycol |
| HG | Hexylene glycol |
| 13BD | 1,3-butanediol |
| 14BD | 1,4-butanediol |
| MMB | 3-methoxy-3 methyl-1-butanol |
| MMBA | 3-methoxy-3 methyl-butyl acetate |
| 3M1B | 3-methyl-1-butanol |
| PG | Propylene glycol |

TABLE B
Second group

| | |
|---|---|
| AMTAZ | 2-amino-5-mercapto-1,3,4-thiadiazole |
| MTZ | 3-mercapto-1,2,4-triazole |
| AMTZ | 3-amino-5-mercapto-1,2,4-triazole |
| DATZ | 3,5-diamino-1,2,4-triazole |
| MTAZ | 2-mercapto-1,3,4-thiadiazole |
| DMTAZ | 2,5-dimercapto-1,3,4-thiadiazole |
| TIU | Thiouracil |
| ADE | Adenine |
| MP | 6-methoxypurine |
| DAP | 2,6-diaminopurine |
| Mpy | 2-mercaptopyridine |
| Hpy | 2-hydroxypyridine |
| Apy | 2-aminopyridine |
| DAPy | 2,6-diaminopyridine |
| DDT | 1-dodecanethiol |
| DT | 1-decanethiol |
| OT | 1-octanethiol |
| Cs | Cystine |
| CsT | Cysteine |
| ME | Mercaptoethanol |
| MPA | 3-mercaptopropionic acid |
| TS | Thiosalicylic acid |
| MBTz | 2-mercaptobenzothiazole |
| MBIz | 2-mercaptobenzoimidazole |
| MC | Mercaptosuccinic acid |
| DSA | Dodecylbenzenesulfonic acid |
| POEL | Polyoxyethylene lauryl ether sulfate |
| LSA | Lauryl sulfoacetate |
| ANSA | Alkyl naphthalene sulfonic acid |
| DBNA | Dibutyl naphthalene sulfonic acid |
| ADPNA | Alkyl diphenyl ether disulfonic acid |
| DDNA | Dodecyl naphthalene sulfonic acid |
| LPS | Lauryl phosphoric acid |
| LPz | Lauryl pyridinium chloride |
| LTMA | Lauryl trimethyl ammonium |
| LDMAB | Lauryl dimethyl aminoacetic acid betaine |
| LCHIB | 2-lauryl-N-carboxymethyl-N-hydroxyethylimidazolinium |
| | betaine |
| DMLAo | Dimethyl laurylamine oxide |
| DAPAc | 3-dodecylaminopropionic acid |
| MSA | Methanesulfonic acid |
| Lau | Lauric acid |
| Cap | Capric acid |
| Nona | Nonanoic acid |
| Oc | Octanoic acid |
| Ac | Acetic acid |
| γ-H | γ-hexanolactone |
| 1O2P | 1-n-octyl-2-pyrrolidone |
| γ-U | γ-undecanolactone |
| Ox | Oxalic acid |
| SmO | Sorbitan acid ocrylate |
| SmL | Sorbitan acid laurate |
| Dec | Decanoic acid |
| PrP | Phosphoric acid |
| HBF4 | Tetrafluoroboric acid |
| PVP | Polyvinyl phosphonic acid |
| PnP | Phosphonic acid |
| OPnP | Octyl phosphonic acid |
| PPnP | Phenyl phosphonic acid |
| PPrP | Polyphosphoric acid |
| POAS | Polyoxyethylene alkyl ether sulfate |

The formulae only show representative examples.

22. The etching liquid according to claim 21,
wherein the concentration of the organic additive in the etching liquid is in the range of 50% by mass to 99% by mass when the organic additive is included in the first group, and
the concentration of the organic additive is in the range of 0.005% by mass to 10% by mass when the organic additive is included in the second group.

23. The etching liquid according to claim 15, wherein the pH of the etching liquid is 5 or less.

24. The etching liquid according to claim 15, wherein the ion concentration of Na, K, and Ca in the etching liquid is in the range of 1 ppt to 1 ppm.

25. The etching liquid according to claim 15, wherein the number of coarse particles whose average particle diameter is 0.5 μm or greater is 100/cm³ or less.

26. An etching liquid kit of a semiconductor substrate that includes a first layer containing germanium and a second layer containing metals other than germanium, which is for selectively removing the second layer with respect to a first layer, the etching liquid kit being formed by combining an oxidant, the following acid compounds, and the following organic additive, and comprising:
a first liquid which contains at least the oxidant; and
a second liquid which does not contain the oxidant.
Acid compounds: at least one compound selected from halogen acid and a salt thereof; hexafluorosilicic acid and a salt thereof; tetrafluoroboric acid and a salt thereof, and hexafluorophosphoric acid and a salt thereof
Organic additive: an additive formed of an organic compound which contains a nitrogen atom, a sulfur atom, a phosphorous atom, or an oxygen atom

27. A semiconductor substrate product manufacturing method that includes a first layer containing germanium, comprising:
a step of forming at least the first layer and a second layer containing at least one metal selected from nickel platinum, titanium, nickel, and cobalt on the semiconductor substrate;
a step of forming a third layer containing components of both layers between the first layer and the second layer by heating the semiconductor substrate;
a step of preparing an etching liquid containing the following acid compounds; and
a step of bringing the etching liquid into contact with the second layer and selectively removing the second layer with respect to the first layer and the third layer.
Acid compounds: at least one compound selected from halogen acid and a salt thereof; hexafluorosilicic acid and a salt thereof; tetrafluoroboric acid and a salt thereof, and hexafluorophosphoric acid and a salt thereof

28. An etching liquid which is used for a semiconductor process, containing fluorine ions and an acid assistant.

29. The etching liquid according to claim 28, further containing an organic solvent and water.

30. The etching liquid according to claim 28, wherein the acid assistant is a boron-containing acid compound, a phosphoric acid compound, a phosphonic acid compound, HBr, or HCl.

31. The etching liquid according to claim 28, wherein the pKa of the acid assistant is 4 or less.

32. The etching liquid according to claim 29, wherein the organic solvent is a protonic polar organic solvent.

33. The etching liquid according to claim 28, wherein the concentration of the fluorine ion is in the range of 0.1% by mass to 20% by mass.

34. The etching liquid according to claim 29, wherein the concentration of water is in the range of 0.1% by mass to 50% by mass.

35. The etching liquid according to claim 28, wherein the concentration of the acid assistant is in the range of 0.1% by mass to 20% by mass.

36. The etching liquid according to claim 29, wherein the concentration of the organic solvent is in the range of 50% by mass to 98% by mass.

37. The etching liquid according to claim 28, further containing a carboxylic acid compound.

38. The etching liquid according to claim 28, which is used for a semiconductor substrate that includes a third layer containing silicon or silicide of germanium and a second layer containing metals other than germanium.

39. The etching liquid according to claim 38, wherein the second layer is a layer containing titanium.

40. An etching method, wherein an etching liquid containing fluorine ions and an acid assistant is used for a semiconductor substrate.

41. The etching method according to claim 40, which is used for a semiconductor substrate that includes a third layer containing silicon or silicide of germanium and a second layer containing metals other than germanium.

42. The etching method according to claim 40, wherein the second layer is a layer containing titanium.

43. A semiconductor substrate product manufacturing method, wherein a semiconductor substrate product is manufactured through the etching method according to claim 40.
